(19) United States
(12) Patent Application Publication
(10) Pub. No.: US 2026/0251975 A9
(43) Pub. Date: Aug. 27, 2026

(54) PHOTOSENSITIVE RESIN COMPOSITION, CURED SUBSTANCE, LAMINATE, MANUFACTURING METHOD FOR CURED SUBSTANCE, MANUFACTURING METHOD FOR LAMINATE, MANUFACTURING METHOD FOR SEMICONDUCTOR DEVICE, AND SEMICONDUCTOR DEVICE

(71) Applicant: FUJIFILM Corporation, Tokyo (JP)

(72) Inventors: Atsuyasu Nozaki, Shizuoka (JP); Kazuya Oota, Shizuoka (JP); Yuta Yamakawa, Shizuoka (JP)

(73) Assignee: FUJIFILM Corporation, Tokyo (JP)

(21) Appl. No.: 19/320,385

(22) Filed: Sep. 5, 2025

Related U.S. Application Data
(63) Continuation of application No. PCT/JP2024/009325, filed on Mar. 11, 2024.

(30) Foreign Application Priority Data
Mar. 15, 2023 (JP) 2023-040796

(51) Int. Cl. G03F 7/038; G03F 7/004; G03F 7/16; G03F 7/38; G03F 7/40; H10P 76/20

(52) U.S. Cl. CPC G03F 7/038; G03F 7/0045; G03F 7/0048; G03F 7/168; G03F 7/38; G03F 7/40; H10P 76/2042

(57) ABSTRACT

A photosensitive resin composition including a resin having a repeating unit represented by Formula (1-1) and a photosensitizing agent, a cured substance obtained by curing the resin composition, a laminate including the cured substance, a manufacturing method for the cured substance, a manufacturing method for a laminate, a manufacturing method for a semiconductor device including the manufacturing method for the cured substance, and a semiconductor device including the cured substance.

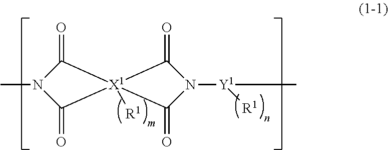

In Formula (1-1), X¹ represents an organic group including a structure obtained by removing two or more hydrogen atoms from a specific structure, Y¹ represents an organic group including a structure obtained by removing two or more hydrogen atoms from a specific structure, R¹'s each independently represent an organic group having a polymerizable group, m represents an integer of 0 to 4, and n represents an integer of 1 or more.

### CROSS-REFERENCE TO RELATED APPLICATIONS

This application is a Continuation of PCT International Application No. PCT/JP2024/009325 filed on Mar. 11, 2024, which claims priority under 35 U.S.C § 119(a) to Japanese Patent Application No. 2023-040796 filed on Mar. 15, 2023. Each of the above application(s) is hereby expressly incorporated by reference, in its entirety, into the present application.

### BACKGROUND OF THE INVENTION

### 1. Field of the Invention

The present invention relates to a photosensitive resin composition, a cured substance, a laminate, a manufacturing method for a cured substance, a manufacturing method for a laminate, a manufacturing method for a semiconductor device, and a semiconductor device.

### 2. Description of the Related Art

In recent years, a resin material that has been produced from a resin composition containing a resin has been utilized in various fields.

For example, use applications of the above-described resin material are not particularly limited, and examples thereof in a semiconductor device for mounting include the use as a material of an insulating film or sealing material, or as a protective film. In addition, such a resin can also be used as a base film, a cover lay, or the like for a flexible substrate.

Since the resin composition can be applied by a publicly known coating method or the like, it can be said that the resin composition is excellent in the manufacturing adaptability, for example, a high degree of freedom in designing the shape, size, application position of the resin composition to be applied during application. From the viewpoint of such excellent manufacturing adaptability, the industrial application and development of the above-described resin composition are expected increasingly.

For example, WO2020/255859A describes a curable resin composition containing at least one resin selected from the group consisting of a polyimide and a polyimide precursor, which has a polyalkyleneoxy group and a polymerizable group, a polymerization initiator, a polymerizable compound, and a solvent.

WO2021/039782A describes a curable resin composition containing a resin having a repeating unit with a specific structure and a solvent.

### SUMMARY OF THE INVENTION

In recent years, it has been more and more important to increase the signal speed of the inter-chip wiring, and the miniaturization of the re-distribution wiring for connecting the chips has progressed. Therefore, even in a cured substance of a photosensitive resin composition used for forming a pattern for the purpose of forming a re-distribution line, insulating, or the like, there is an increasing demand for further resolution.

An object of the present invention is to provide a photosensitive resin composition having excellent resolution in a case of forming a pattern of a cured substance, a cured substance obtained by curing the composition, a laminate including the cured substance, a manufacturing method for a cured substance, a manufacturing method for a laminate, a manufacturing method for a semiconductor device including a manufacturing method for a cured substance, and a semiconductor device including a cured substance.

Examples of representative embodiments according to the present invention are described below.

<1> A photosensitive resin composition comprising:
a resin having a repeating unit represented by Formula (1-1); and
a photosensitizing agent,

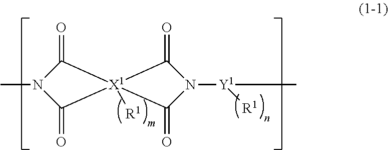

in Formula (1-1), X¹ represents an organic group including a structure obtained by removing two or more hydrogen atoms from a structure represented by any of Formula (V-1) to Formula (V-10), Y¹ represents an organic group including a structure obtained by removing two or more hydrogen atoms from a structure represented by any of Formula (V-1) to Formula (V-6) and Formula (V-8), R¹'s each independently represent an organic group having a polymerizable group, m represents an integer of 0 to 4, and n represents an integer of 1 or more,

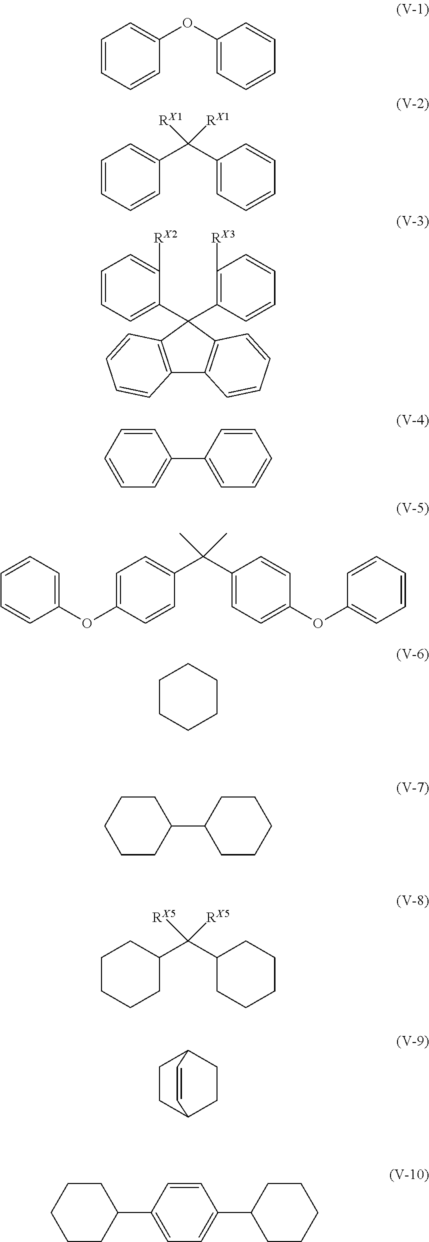

in Formula (V-2), R^{X1}'s each independently represent a hydrogen atom, an alkyl group, or a halogenated alkyl group,
in Formula (V-3), R^{X2} and R^{X3} each independently represent a hydrogen atom or a substituent, and R^{X2} and R^{X3} may be bonded to each other to form a ring structure,
in Formula (V-8), R^{X5}'s each independently represent a hydrogen atom, an alkyl group, or a halogenated alkyl group.

<2> The photosensitive resin composition according to <1>,
in which X¹ is an organic group having no ester bond.

<3> The photosensitive resin composition according to <1> or <2>,
in which the photosensitive resin composition has 50% by mass or more of the repeating unit represented by Formula (1-1) with respect to a total mass of the resin.

<4> A photosensitive resin composition comprising:
at least one resin selected from the group consisting of a polyimide and a precursor of the polyimide; and
a photosensitizing agent,
in which the photosensitive resin composition is applied, at a film thickness in which a distance from a base material to a film surface is 20 μm, to a silicon wafer on which a copper wire having a 1:1 line-and-space pattern with a height of 15 μm, a width of 20 μm, and a taper angle of 85 degrees is formed, and a maximum value of a difference in the distance from the base material to the film surface of a cured substance obtained by heating at 230° C. for 3 hours is less than 30%, and
the photosensitive resin composition is applied to the silicon wafer to form a film at a thickness of 15 μm, and a change rate in thickness of the cured substance obtained by heating at 230° C. for 3 hours after entire surface exposure with respect to a thickness of 15 μm of the cured substance before the exposure is less than 15%.

<5> The photosensitive resin composition according to <4>,
in which the polyimide is at least one resin selected from the group consisting of polyimide, polyamideimide, and polyesterimide.

<6> The photosensitive resin composition according to any one of <1> to <5>,
in which a film in a case where the photosensitive resin composition is applied onto a silicon wafer satisfies Condition (1),

Condition (1): The dissolution rate of the film in cyclopentanone is 0.1 μm/sec or more and less than 0.6 μm/sec.

<7> The photosensitive resin composition according to any one of <1> to <6>,
in which a cured substance obtained by heating the photosensitive resin composition at 230° C. for 3 hours satisfies Condition (2),

Condition (2): a change rate in film thickness before and after immersion is less than 20% after the cured substance is immersed at 75° C. for 15 minutes in a mixture of dimethyl sulfoxide and a 25% by mass aqueous tetramethylammonium hydroxide solution in 90:10 (mass ratio).

<8> The photosensitive resin composition according to any one of <1> to <7>,
in which a pH of the photosensitive resin composition is 6.0 to 9.0.

<9> The photosensitive resin composition according to any one of <1> to <8>,
in which a weight-average molecular weight of the resin is 5,000 to 25,000.

<10> The photosensitive resin composition according to any one of <1> to <9>,
in which a dispersity of a molecular weight of the resin is 1.8 to 3.0.

<11> The photosensitive resin composition according to any one of <1> to <10>,
in which a cured substance obtained by heating the resin composition at 230° C. for 3 hours satisfies Condition (3),

Condition (3): a coefficient of thermal expansion of the cured substance in a temperature range of 25° C. to 125° C. is more than 20 ppm/° C. and 75 ppm/° C. or less.

<12> The photosensitive resin composition according to any one of <1> to <11>, further comprising:
a naphthoquinone diazide compound.

<13> The photosensitive resin composition according to <4> or <5>,
in which the resin has a repeating unit represented by Formula (1-1),

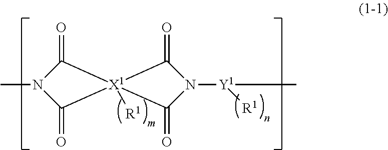

in Formula (1-1), X¹ represents an organic group including a structure obtained by removing two or more hydrogen atoms from a structure represented by any of Formula (V-1) to Formula (V-10), Y¹ represents an organic group including a structure obtained by removing two or more hydrogen atoms from a structure represented by any of Formula (V-1) to Formula (V-6) and Formula (V-8), R¹'s each independently represent an organic group having a polymerizable group, m represents an integer of 0 to 4, and n represents an integer of 1 or more,

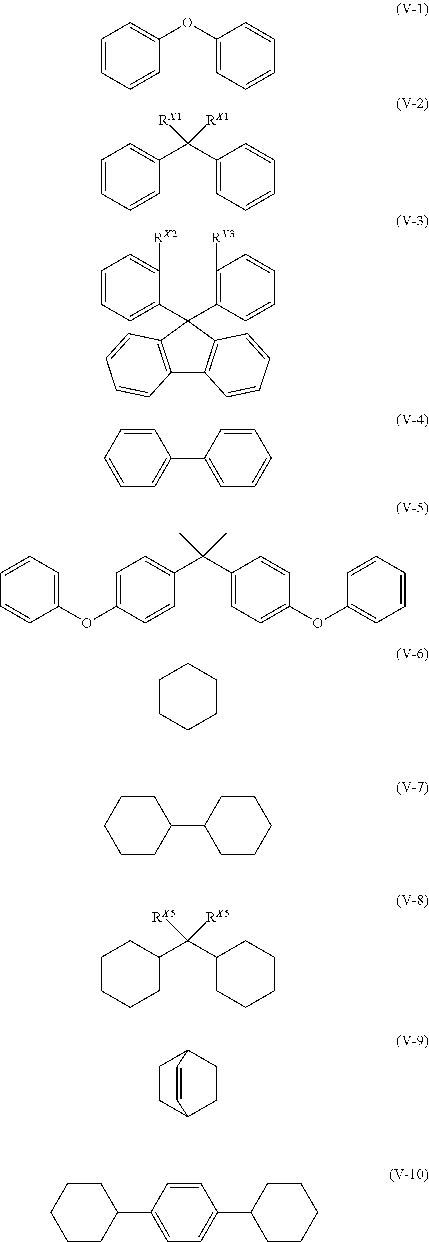

in Formula (V-2), R^{X}i's each independently represent a hydrogen atom, an alkyl group, or a halogenated alkyl group,
in Formula (V-3), R^{X2} and R^{X3} each independently represent a hydrogen atom or a substituent, and R^{X2} and R^{X3} may be bonded to each other to form a ring structure,
in Formula (V-8), R^{X5}'s each independently represent a hydrogen atom, an alkyl group, or a halogenated alkyl group.

<14> The photosensitive resin composition according to <13>,
in which R¹ in Formula (1-1) includes a ring structure with 5 or more ring members.

<15> The photosensitive resin composition according to any one of <1> to <14>,
in which a content of the resin with respect to a total solid content of the photosensitive resin composition is 60% by mass or more.

<16> The photosensitive resin composition according to any one of <1> to <15>,
in which the photosensitive resin composition contains a photopolymerization initiator as the photosensitizing agent, and
the photosensitive resin composition contains a polymerizable compound.

<17> The photosensitive resin composition according to <16>,
in which a melting point of the polymerizable compound is 25° C. or lower.

<18> The photosensitive resin composition according to <17>,
in which a content of the polymerizable compound with respect to a total solid content of the photosensitive resin composition is 10% by mass or more.

<19> The photosensitive resin composition according to any one of <1> to <18>,
in which the photosensitive resin composition is used for forming an insulating member.

<20> The photosensitive resin composition according to any one of <1> to <19>,
in which the photosensitive resin composition is used for forming an interlayer insulating film for a re-distribution layer.

<21> A cured substance obtained by curing the photosensitive resin composition according to any one of <1> to <20>.

<22> A laminate comprising:
two or more layers consisting of the cured substance according to <21>; and
a metal layer provided between any of the layers consisting of the cured substance.

<23> A manufacturing method for a cured substance, further comprising:
a film forming step of applying the photosensitive resin composition according to any one of <1> to <20> onto a base material to form a film.

<24> The manufacturing method for a cured substance according to <23>, further comprising:
an exposure step of selectively exposing the film; and
a development step of developing the film using a developer to form a pattern.

<25> The manufacturing method for a cured substance according to <23> or <24>, further comprising:
a heating step of heating the film at 50° C. to 450° C.

<26> A manufacturing method for a laminate, comprising:
the manufacturing method for a cured substance according to any one of <23> to <25>.

<27> A manufacturing method for a semiconductor device, comprising:
the manufacturing method for a cured substance according to any one of <23> to <25>.

<28> A semiconductor device comprising:
the cured substance according to <21>.

According to the present invention, there are provided a photosensitive resin composition having excellent resolution in a case of forming a pattern of a cured substance, a cured substance obtained by curing the composition, a laminate including the cured substance, a manufacturing method for a cured substance, a manufacturing method for a laminate, a manufacturing method for a semiconductor device including a manufacturing method for a cured substance, and a semiconductor device including a cured substance.

### BRIEF DESCRIPTION OF THE DRAWINGS

FIG. 1 is a schematic cross-sectional view of a state where a cured substance is formed on a silicon wafer on which a copper wire is formed.

### DESCRIPTION OF THE PREFERRED EMBODIMENTS

Hereinafter, the main embodiments according to the present invention will be described. However, the present invention is not limited to the specified embodiments.

In the present specification, a numerical value range described by using “to” means a range including numerical values described before and after the preposition “to” as a lower limit value and an upper limit value, respectively.

In the present specification, the term “step” means not only an independent step but also a step that cannot be clearly distinguished from other steps as long as the desired action of the step can be achieved.

In describing a group (an atomic group) in the present specification, in a case where a description of substitution and unsubstitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

In the present specification, the “exposure” includes not only exposure using light but also exposure using corpuscular beams such as an electron beam and an ion beam, unless otherwise specified. In addition, examples of the light that is used for exposure include an actinic ray such as a bright line spectrum of a mercury lamp, a far ultraviolet ray represented by an excimer laser, an extreme ultraviolet ray (EUV light), an X-ray, or an electron beam, and a radioactive ray.

In the present specification, “(meth)acrylate” means one or both of “acrylate” and “methacrylate”, “(meth)acryl” means one or both of “acryl” and “methacryl”, and “(meth)acryloyl” means one or both of “acryloyl” and “methacryloyl”.

In the structural formulae of the present specification, Me represents a methyl group, Et represents an ethyl group, Bu represents a butyl group, and Ph represents a phenyl group.

In the present specification, the total solid content refers to the total mass of components excluding a solvent from the entire components of the composition. In addition, in the present specification, the concentration of solid contents is a mass percentage of other components excluding a solvent with respect to the total mass of the composition.

In the present specification, weight-average molecular weight (Mw) and number-average molecular weight (Mn) are each a value measured using gel permeation chromatography (GPC) unless otherwise specified, which are defined as a polystyrene equivalent value. In the present specification, the weight-average molecular weight (Mw) and the number-average molecular weight (Mn) can be determined, for example, by using HLC-8220 GPC (manufactured by Tosoh Corporation) and using GUARD COLUMN HZ-L, TSKgel Super HZM-M, TSK gel Super HZ4000, TSK gel Super HZ3000, and TSK gel Super HZ2000 (all of which are manufactured by Tosoh Corporation) as a column connected in series. The measurements of the above molecular weights are carried out using tetrahydrofuran (THF) as an eluent unless otherwise specified. However, N-methyl-2-pyrrolidone (NMP) can also be used in a case where THF is not suitable as the eluent, for example, in a case where the solubility is low. In addition, the detection in GPC measurement is carried out using a detector with an ultraviolet ray (a UV ray) of a wavelength of 254 nm unless otherwise specified.

In the present specification, in a case where the positional relationship of respective layers constituting the laminate is described as “upper” or “lower”, it suffices that another layer is on the upper side or the lower side of the reference layer among the plurality of layers of interest. That is, a third layer or element may be further interposed between the reference layer and the other layer, and the reference layer and the other layer need not be in contact with each other. Unless otherwise specified, the direction in which the layers are laminated on the base material is referred to as “upward”, or in a case where a resin composition layer is present, the direction from the base material to the resin composition layer is referred to as “upper”. The opposite direction thereof is referred to as “downward”. Furthermore, such a setting of upward and downward directions is for convenience in the present specification, and in a practical aspect, the “upward” direction in the present specification may be different from a vertically upward direction.

In the present specification, a composition may contain, as each component contained in the composition, two or more compounds corresponding to the component unless otherwise specified. The content of each component in the composition means the total content of all the compounds corresponding to the component unless otherwise specified.

In the present specification, unless otherwise specified, the temperature is 23° C., the atmospheric pressure is 101,325 Pa (1 atm), and the relative humidity is 50% RH. In addition, in the present specification, a combination of preferred aspects is a more preferred aspect. [0012](Photosensitive resin composition) A photosensitive resin composition according to a first aspect of the present invention (hereinafter, also simply referred to as a “first resin composition”) includes a resin having a repeating unit represented by Formula (1-1) and a photosensitizing agent.

A photosensitive resin composition according to a second aspect of the present invention (hereinafter, also simply referred to as a “second resin composition”) is a photosensitive resin composition including at least one resin selected from the group consisting of a polyimide and a precursor of the polyimide, and a photosensitizing agent, in which the photosensitive resin composition is applied to a silicon wafer on which a copper wire having a height of 15 μm, a width of 20 μm, and a taper angle of 85 degrees is formed in a 1:1 line-and-space pattern, with a film thickness such that a distance from a base material to a film surface is 20 μm, and a maximum value of a difference in the distance from the base material to the film surface of a cured substance obtained by heating at 230° C. for 3 hours is less than 30%, the photosensitive resin composition is applied to the silicon wafer to form a film having a thickness of 15 μm, and a change rate in thickness of the cured substance obtained by heating at 230° C. for 3 hours after entire surface exposure with respect to a thickness of 15 μm of the cured substance before exposure is less than 15%.

Hereinafter, the first resin composition and the second resin composition are simply referred to as a “resin composition”.

Hereinafter, the resin having a repeating unit represented by Formula (1-1), which is contained in the first resin composition, is also referred to as a “first specific resin”. Hereinafter, at least one resin selected from the group consisting of a polyimide and a precursor of the polyimide, which is contained in the second resin composition, is also referred to as a “second specific resin”.

Hereinafter, in a case where the term “specific resin” is simply described, it refers to all of the first specific resin and the second specific resin.

The resin composition according to the embodiment of the present invention is preferably used for forming a photosensitive film that is subjected to exposure and development, and more preferably used for forming a film that is subjected to exposure and development using a developer containing an organic solvent.

The resin composition according to the embodiment of the present invention can be used, for example, for forming an insulating film of a semiconductor device, an interlayer insulating film for a re-distribution layer, a stress buffer film, or the like, and it is preferably used for forming an interlayer insulating film for an insulating member.

The insulating member is a member formed for the purpose of insulating members intended for conduction, such as wiring lines. The volume resistivity of the insulating member is preferably 1×10⁸ Ω·cm or more, more preferably 1×10¹⁰ Ω·cm or more, and still more preferably 1×10¹² Ω·cm or more.

In particular, one of the preferred aspects of the present invention is that the resin composition according to the embodiment of the present invention is used for forming an interlayer insulating film for a re-distribution layer.

In addition, the resin composition according to the embodiment of the present invention is preferably used for forming a photosensitive film that is subjected to negative-tone development.

In the present invention, the negative-tone development refers to development in which, in exposure and development, a non-exposed portion is removed by the development, and the positive-tone development means a development in which an exposed portion is removed by the development.

As the exposure method, the developer, and the development method, for example, the following ones in the description of the manufacturing method for a cured substance, which will be described later, are used: an exposure method to be described in the exposure step, and a developer and a development method to be described in the development step.

The resin composition according to the embodiment of the present invention has excellent resolution in a case of forming a pattern of a cured substance.

Although the mechanism by which the above effect is obtained is not revealed, it is presumed as follows.

The photosensitive resin composition according to the first aspect of the present invention includes a resin having a repeating unit represented by Formula (1-1) and a photosensitizing agent.

A photosensitive resin composition according to a second aspect of the present invention is a photosensitive resin composition including at least one resin selected from the group consisting of a polyimide and a precursor of the polyimide, and a photosensitizing agent, in which the photosensitive resin composition is applied to a silicon wafer on which a copper wire having a height of 15 μm, a width of 20 μm, and a taper angle of 85 degrees is formed in a 1:1 line-and-space pattern, with a film thickness such that a distance from a base material to a film surface is 20 μm, and a maximum value of a difference in the distance from the base material to the film surface of a cured substance obtained by heating at 230° C. for 3 hours (hereinafter, also referred to as “flatness”) is less than 30%, the photosensitive resin composition is applied to the silicon wafer to form a film having a thickness of 15 am, and a change rate in thickness of the cured substance obtained by heating at 230° C. for 3 hours after entire surface exposure with respect to a thickness of 15 μm of the cured substance before exposure (hereinafter, also referred to as “shrinkage ratio”) is less than 15%.

It has been found that the photosensitive resin composition as described above has excellent resolution of a pattern obtained by exposure and development.

In a case where a film having a large surface roughness and a large shrinkage ratio after curing in the related art is cured to form a pattern, it is necessary to apply the composition thickly to a base material in consideration of the thickness of the formed pattern.

Since the exposure and the development are performed before curing, a film that is thickly applied remains thick even during the exposure and the development, and in a case where an attempt is made to remove the thick film up to the surface of the base material, the side surface of the pattern is also removed during the removal, or the thick film cannot be completely removed up to the surface of the base material, and thus the resolution is considered to be deteriorated.

In the photosensitive resin composition according to the first aspect of the present invention, it is considered that the amount of decomposition products decomposed from the resin by exposure, development, and heating is small, and the resin itself has a relatively rigid structure, and thus both the roughness and the shrinkage ratio after curing are small.

In the photosensitive resin composition according to the second aspect of the present invention, both the roughness and the shrinkage ratio after curing are small.

Therefore, in a case where these photosensitive resin compositions are used, it is considered that the composition can be applied in a thin manner even in consideration of the thickness of the pattern formed after curing, and thus the resolution is excellent.

Here, JP2020-255859A and JP2021/039782A do not disclose a resin composition corresponding to the resin composition according to the embodiment of the present invention.

### <Physical Properties of Cured Substance of Resin Composition>

### [Flatness]

The flatness of the first resin composition according to the embodiment of the present invention is preferably less than 30%, more preferably less than 20%, and still more preferably less than 15%.

The flatness of the second resin composition according to the embodiment of the present invention is less than 30%, preferably less than 20%, and more preferably less than 15%.

The flatness is calculated as the maximum value of the difference in the distance from the base material to the film surface of a cured substance obtained by applying a resin composition to a silicon wafer on which a copper wire having 1:1 line-and-space pattern with a height of 15 μm and a width of 20 μm and a taper angle of 85 degrees is formed and heating the silicon wafer at 230° C. for 3 hours, where the film thickness is such that the distance from the base material to the film surface is 20 μm.

The distance from the base material of the cured substance to the film surface is measured as a film thickness of a film consisting of the resin composition in the space portion of the copper wire.

Here, the method of applying the resin composition is not particularly limited, and any method may be used as long as the distance from the base material to the film surface is 20 μm. However, a spin coating method can be used. In addition, in a case where it is difficult to form a film having the above-described distance of 20 μm by the spin coating method once, the spin coating method may be performed a plurality of times. In addition, even in this case, in a case where it is difficult to form a film having a distance of 20 μm by a spin coating method, an application method may be appropriately selected from known methods such as a dip coating method, an air knife coating method, a curtain coating method, a wire bar coating method, a gravure coating method, an extrusion coating method, a spray coating method, a slit coating method, and an ink jet method.

In a case where the resin composition contains a solvent, it is preferable to carry out drying after the above-described application. In that case, the distance from the base material to the film surface after drying is 20 μm.

It is preferable that the drying is carried out until the amount of the solvent in the film is 0.5% by mass or less.

The drying conditions are not particularly limited, but can be carried out by drying with heating. In addition, in a case where it is difficult to sufficiently dry the composition only by heating, the pressure may be further reduced.

The drying can be carried out in the atmosphere. However, in a case where the resin composition contains a component or the like that is likely to be modified by oxygen, the treatment can also be carried out under an inert gas replacement such as nitrogen, under vacuum, or the like.

The drying means is not particularly limited, and examples thereof include a hot plate. However, in a case where the above-described pressure reduction, inert gas replacement, and the like are required, an oven with a pressure reduction function, an oven with a gas replacement function, or the like can also be used.

In a case of carrying out drying by heating, the heating temperature (drying temperature) can be set to, for example, 100° C. However, in a case where it is difficult to dry at 100° C., the drying temperature may be appropriately changed to 70° C. to 130° C., preferably 90° C. to 120° C., depending on the kind or the like of the solvent contained in the resin composition.

In a case where the drying is performed by heating, the drying time (the time during which the heating is performed at the above-described heating temperature) can be, for example, 5 minutes. However, in a case where it is difficult to carry out drying for 5 minutes, the drying time may be appropriately changed to 30 seconds to 20 minutes, and preferably 1 minute to 10 minutes, depending on the kind or the like of the solvent contained in the resin composition.

In a case where the drying is performed by heating, the temperature rising rate during heating is not particularly limited, and for example, it can be set to 5° C./min. In a case where the drying at the above-described temperature rising rate is difficult, the temperature rising rate may be appropriately changed to 1 to 12° C./min or 2 to 10° C./min depending on the kind or the like of the solvent contained in the resin composition.

The film of the resin composition obtained by the above-described application is heated at 230° C. for 3 hours to obtain a cured substance.

The film of the resin composition obtained by the application is subjected to heating while being exposed as little as possible. In addition, contact with a solvent such as a developer can also be avoided as much as possible.

The heating can be carried out in an oven under a nitrogen atmosphere.

The pressure in the heating is set to 1 atm (101,325 Pa).

The temperature rising rate in the heating can be, for example, 10° C./min. In a case where the drying at the above-described temperature rising rate is difficult, the temperature rising rate may be appropriately changed to 1 to 12° C./min or 2 to 10° C./min depending on the kind or the like of the solvent contained in the resin composition.

The heating time (time exposed to 230° C.) in the above-described heating is set to 3 hours.

The film thickness of the cured substance is measured after cooling the cured substance to 25° C.

Specifically, the flatness can be measured by a method described in Examples described later.

The dissolution rate of the cured substance can be adjusted by the structure, the content, and the like of the specific resin, the polymerizable compound, and the like contained in the resin composition.

### [Shrinkage Ratio]

The shrinkage ratio of the first resin composition according to the embodiment of the present invention is preferably less than 15%, more preferably less than 12%, and still more preferably less than 10%.

The shrinkage ratio of the second resin composition according to the embodiment of the present invention is less than 15%, preferably less than 12%, and more preferably less than 10%.

The shrinkage ratio is calculated as a change rate in thickness of a cured substance obtained by applying the resin composition to a silicon wafer to form a film having a film thickness of 15 μm, exposing the film over the entire surface, and heating the film at 230° C. for 3 hours, with respect to a thickness of 15 μm before the exposure.

Specifically, the shrinkage ratio is calculated by the following calculation formula in a case where the film thickness of the cured substance is denoted by film thickness B.

$$Calculation formula : shrink ratio ( \% ) = 100 - ( film thickness B \div 15 \times 100 )$$

Examples of the method of applying the resin composition to the silicon wafer include the application methods described in the above description of the flatness, except that the thickness is set to 15 μm.

In addition, in a case where the resin composition contains a solvent, it is preferable to carry out drying after the above-described application. In that case, the distance from the base material to the film surface after drying is 15 μm.

Examples of the method of performing the above-described drying include the drying method described in the above-described description of the flatness, except that the thickness is set to 15 μm.

The entire surface exposure is performed by a method of exposing the entire surface with i-rays at an exposure energy of 500 mJ/cm² using a stepper (for example, Nikon NSR 2005 i9C). However, in a case where the photosensitizing agent does not respond to exposure due to the exposure wavelength and the exposure sensitivity in the above-described exposure, the exposure wavelength and the exposure sensitivity can be appropriately changed. Specifically, in a case where 50 mol % or more of the photosensitizing agent does not respond to exposure, the exposure wavelength and the exposure sensitivity are changed. Whether or not the photosensitizing agent responds to exposure can be determined by a change in the structure of the photosensitizing agent.

The film of the resin composition after the entire surface exposure is heated at 230° C. for 3 hours to obtain a cured substance.

Examples of the method of performing the above-described heating include the heating method described in the above-described description of the flatness.

The above-described shrinkage ratio can be adjusted by the structure, the content, and the like of the specific resin, the polymerizable compound, and the like contained in the resin composition.

The film thickness of the cured substance is measured after cooling the cured substance to 25° C.

### [Dissolution Rate]

It is preferable that the film in a case where the resin composition is applied onto a silicon wafer satisfies the following condition (1).

Condition (1): the dissolution rate of the film in cyclopentanone is 0.1 μm/sec or more and less than 0.6 μm/sec.

The lower limit of the dissolution rate of the film is preferably 0.05 μm/sec or more and more preferably 0.10 to 0.2 μm/sec or more.

The upper limit of the dissolution rate of the film is preferably 1.2 μm/sec or less and more preferably 0.6 to 1.0 μm/sec or less.

Examples of the method of applying the resin composition to the silicon wafer include the application methods described in the description of the flatness above.

In addition, in a case where the resin composition contains a solvent, it is preferable to carry out drying after the above-described application.

Examples of the method of performing the above-described drying include the drying methods described in the above-described description of the flatness.

The dissolution rate of the film in cyclopentanone can be calculated by immersing a silicon wafer on which the film is formed in cyclopentanone for 30 seconds and measuring the film thickness of the film before and after immersion with an ellipsometer.

The film is immersed in cyclopentanone in a state in which the film is not subjected to heating other than the drying.

The amount of cyclopentanone used for the immersion is preferably 1000 times the volume of the film.

The temperatures of the cyclopentanone, the film, and the silicon wafer during the immersion are set to 23° C.

In a case where the film is completely dissolved or the film thickness does not change at all after the immersion for 30 seconds, the immersion time may be appropriately changed to calculate the dissolution rate.

The dissolution rate of the film can be adjusted by the structure, the content, and the like of the specific resin, the polymerizable compound, and the like contained in the resin composition.

### [Chemical Resistance]

It is preferable that a cured substance obtained by heating the resin composition at 230° C. for 3 hours satisfies the following condition (2).

Condition (2): a change rate in film thickness before and after immersion is less than 20% after the cured substance is immersed at 75° C. for 15 minutes in a mixture of dimethyl sulfoxide and a 25% by mass aqueous tetramethylammonium hydroxide solution in 90:10 (mass ratio).

The above-described change rate in film thickness is preferably less than 15% and more preferably less than 10%.

The change rate in film thickness in the condition (2) can be calculated as 100−(film thickness after immersion/film thickness before immersion×100) (%).

The cured substance is obtained by applying the resin composition onto a silicon wafer to form a film and then heating the film at 230° C. for 3 hours.

Examples of the method of applying the resin composition to the silicon wafer include the application methods described in the description of the flatness above.

In addition, in a case where the resin composition contains a solvent, it is preferable to carry out drying after the above-described application.

Examples of the method of performing the above-described drying include the drying methods described in the above-described description of the flatness.

The film thickness of the film formed by the application (in a case where the film is dried, the film thickness after drying) is not particularly limited, but can be, for example, 15 μm.

The film formed by the above-described application (in a case of performing drying, the film after drying) is heated at 230° C. for 3 hours to obtain a cured substance.

Examples of the method of performing the above-described heating include the heating method described in the above-described description of the flatness.

Specifically, the change rate in film thickness can be measured by a method described in Examples described later.

The above-described change rate in film thickness can be adjusted by the structure, the content, and the like of the specific resin, the polymerizable compound, and the like contained in the resin composition.

### [Coefficient of Thermal Expansion]

It is preferable that a cured substance obtained by heating the resin composition at 230° C. for 3 hours satisfies the following condition (3).

Condition (3): a coefficient of thermal expansion of the cured substance in a temperature range of 25° C. to 125° C. is more than 20 ppm/° C. and 75 ppm/° C. or less.

The smaller the coefficient of thermal expansion is, the more preferable it is, as long as the coefficient of thermal expansion is 20 ppm or more.

The coefficient of thermal expansion is preferably 60 ppm/° C. or less and more preferably 50 ppm/° C. or less.

The cured substance is obtained by the same method as the method described in the above-described description of the chemical resistance.

The coefficient of thermal expansion is calculated as a value obtained by subjecting the cured substance to the temperature rising and falling conditions shown in the following (1) to (4) and dividing the elongation (displacement) of the sample at 25° C. and 125° C. in the process (3) by the temperature difference.

(1) The temperature is raised from room temperature to 130° C. at a temperature rising rate of 5° C./min.

(2) The temperature is lowered from 130° C. to 10° C. at a temperature lowering rate of 5° C./min.

(3) The temperature is raised from 10° C. to 220° C. at a temperature rising rate of 5° C./min.

(4) The sample is naturally cooled to room temperature.

In the above-described temperature rising and falling processes (1) to (4), the elongation (displacement) of the specimen was measured, and a calculation was carried out to determine a value obtained by dividing the elongation (displacement) of the specimen at 25° C. and 125° C. in the process (3) by the temperature difference (100° C.), where the value was defined as the coefficient of thermal expansion.

Specifically, the coefficient of thermal expansion of the film can be measured by a method described in Examples described later.

The coefficient of thermal expansion can be adjusted by the structure, the content, and the like of the specific resin, the polymerizable compound, and the like contained in the resin composition.

The pH of the resin composition is preferably 3.0 to 11.0, more preferably 4.0 to 9.0, and still more preferably 4.0 to 8.0.

The pH can be measured using a pH meter.

Specifically, for example, HM-42 (manufactured by DKK-TOA CORPORATION) is used as a pH meter, GST-58415 (manufactured by DKK-TOA CORPORATION) is used as an electrode, a 3.3 mol/L potassium chloride aqueous solution (manufactured by FUJIFILM Wako Pure Chemical Corporation) is used as an internal liquid of the electrode, and the measurement can be performed by bringing the electrode into direct contact with the resin composition.

Hereinafter, the components contained in the resin composition according to the embodiment of the present invention will be described in detail.

### <Specific Resin>

The second specific resin is preferably at least one resin selected from the group consisting of polyimide and a precursor of the polyimide, and more preferably polyimide.

The polyimide precursor refers to a resin which is polyimide due to a change in molecular structure caused by an external stimulus, and a resin which is polyimide due to a change in molecular structure caused by heat is preferable, and a resin which is polyimide due to a ring closure reaction caused by heat to form a ring structure is more preferable.

The polyimide is preferably at least one resin selected from the group consisting of polyimide, polyamideimide, and polyesterimide.

For example, the polyimide is preferably at least one resin selected from the group consisting of a polyimide having a repeating unit represented by Formula (1-1) which will be described later, a polyimide (polyamideimide) having a repeating unit represented by Formula (1-3) which will be described later, and a polyimide (polyesterimide) having a repeating unit represented by Formula (1-5) which will be described later.

The second specific resin preferably has a polymerizable group.

The polymerizable group may be a cationically polymerizable group, but is preferably a radically polymerizable group.

Examples of the polymerizable group include an epoxy group, an oxetanyl group, an alkoxymethyl group, an acyloxymethyl group, a methylol group, a blocked isocyanate group, and a group containing an ethylenically unsaturated bond, but a group containing an ethylenically unsaturated bond is preferable.

The group having an ethylenically unsaturated bond is preferably a radically polymerizable group.

In addition, examples of the group containing an ethylenically unsaturated bond include a vinyl group, a vinyl ether group, an allyl group, an isoallyl group, a 2-methylallyl group, a (meth)acrylamide group, and a (meth)acryloyloxy group, and from the viewpoint of reducing the polarity and reducing the dielectric constant of the obtained cured substance, a vinyl group or a vinyl ether group is preferable. Here, the vinyl group is preferably directly bonded to an aromatic ring structure.

In the present invention, the direct bonding of a certain structure A and another structure B means that the structure A and the structure B are directly bonded by a single bond without a linking group being interposed therebetween.

The second specific resin is preferably a resin having a ring structure with 5 or more ring members in a side chain.

In the present invention, a main chain of the resin indicates the relatively longest bonding chain in the resin molecule. In addition, in a case where the ring structure is included in the main chain, an atom included as a ring member in the ring structure is an atom included in the main chain.

In the present invention, the side chain of the resin refers to a molecular chain bonded to the main chain, and the molecular chain may or may not have a repeating unit. That is, the molecular chain may or may not include a repeating structure. In addition, the molecular chain is preferably a molecular chain composed of 6 or more atoms, more preferably a molecular chain composed of 10 or more atoms, and still more preferably a molecular chain composed of 15 or more atoms. An upper limit of the number of atoms included in the molecular chain is not particularly limited, but is, for example, preferably 1,000 or less and more preferably 500 or less.

Here, the side chain in the second specific resin is preferably bonded to a carbon atom included in the main chain, and in a case where the side chain is represented by R, the side chain R is preferably bonded to a carbon atom C of the main chain as C-R. That is, it is preferable that there is only one bond to the main chain in one side chain.

The ring structure with 5 or more ring members is preferably a ring structure with 5 to 20 ring members, and more preferably a ring structure with 5 to 12 ring members.

The ring structure with 5 or more ring members may be any of an aromatic ring or an aliphatic ring, and is preferably an aromatic ring or an aliphatic hydrocarbon ring and more preferably an aromatic ring.

The aromatic ring may be any of an aromatic hydrocarbon ring or a heteroaromatic ring, but is preferably an aromatic hydrocarbon ring or a heteroaromatic ring containing a nitrogen atom as a ring member.

The aromatic hydrocarbon ring is preferably an aromatic hydrocarbon ring having 6 to 20 carbon atoms, more preferably an aromatic hydrocarbon ring having 6 to 10 carbon atoms, and still more preferably a benzene ring.

Examples of the heteroaromatic ring include a furan ring, a benzofuran ring, a thiophene ring, a benzothiophene ring, a pyrrole ring, an imidazole ring, a triazole ring, a tetrazole ring, an oxazole ring, a pyridine ring, a pyridazine ring, a pyrazine ring, a triazine ring, an indole ring, an indazole ring, a benzimidazole ring, and a purine ring.

Examples of the aliphatic ring include an aliphatic hydrocarbon ring having 5 to 20 carbon atoms, a pyrrolidine ring, a pyrroline ring, a pyrazolidine ring, an imidazolidine ring, a tetrahydrofuran ring, a tetrahydrothiophene ring, a piperidine ring, a piperazine ring, a tetrahydropyran ring, a dioxane ring, and a morpholine ring.

Among these, as the ring structure with 5 or more ring members, a benzene ring, a cyclohexane ring, or an adamantane ring is preferable, and a benzene ring is more preferable.

In the ring structure with 5 or more ring members, a hydrogen atom that is bonded to the ring member by a single bond without a linking group being interposed therebetween may be substituted. Examples of the substituent include an alkyl group, an aryl group, a halogen atom, and a polymerizable group described later.

The content of the ring structure with 5 or more ring members in the second specific resin is preferably 0.01 to 5.0 mmol/g, more preferably 0.1 to 4.0 mmol/g, and still more preferably 0.5 to 2.5 mmol/g with respect to 1 g of the specific resin.

The second specific resin preferably has a structure represented by Formula (A-1).

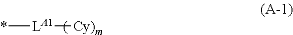

In Formula (A-1), L^{A1} represents a single bond or an (m+1)-valent linking group, Cy's each independently represent a ring structure with 5 or more ring members, which may have a substituent, m represents an integer of 1 or more, and * represents a bonding site to another structure.

In Formula (A-1), L^{A1} is preferably an (m+1)-valent linking group. A preferred aspect of L^{A1} is the same as a preferred aspect of L¹ in Formula (R-1) described later.

In Formula (A-1), a preferred aspect of Cy is the same as the preferred aspect of the ring structure with 5 or more ring members described above.

In addition, it is also preferable that Cy is directly bonded to a polymerizable group described later.

In Formula (A-1), * represents a bonding site to another structure, and it preferably represents a bonding site to an atom included in the main chain of the resin, and more preferably represents a bonding site to a carbon atom included in the main chain. The carbon atom is preferably a tertiary carbon atom or a quaternary carbon atom.

It is preferable that the structure represented by Formula (A-1) is not included in the main chain.

In addition, the structure represented by Formula (A-1) is also a structure represented by Formula (R-1) described later, which is one of the preferred aspects of the present invention.

The content of the structure represented by Formula (A-1) in the second specific resin is preferably 0.01 to 5.0 mmol/g, more preferably 0.1 to 4.0 mmol/g, and still more preferably 0.5 to 2.5 mmol/g with respect to 1 g of the specific resin.

### [Repeating Unit Represented by Formula (1-1)]

The first specific resin has a repeating unit represented by Formula (1-1).

The second specific resin preferably has a repeating unit represented by Formula

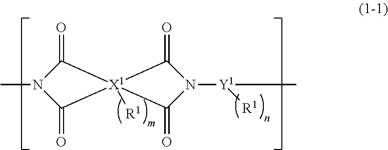

In Formula (1-1), X¹ represents an organic group including a structure obtained by removing two or more hydrogen atoms from a structure represented by any of Formula (V-1) to Formula (V-10), Y¹ represents an organic group including a structure obtained by removing two or more hydrogen atoms from a structure represented by any of Formula (V-1) to Formula (V-6) and Formula (V-8), R¹'s each independently represent an organic group having a polymerizable group, m represents an integer of 0 to 4, and n represents an integer of 1 or more.

### —R¹—

R¹'s each independently represent an organic group having a polymerizable group. The preferred aspect of the polymerizable group is the same as the preferred aspect of the polymerizable group described above regarding the second specific resin.

Here, it is preferable that R¹ includes the above-described ring structure with 5 or more ring members.

In addition, R¹ is preferably a structure represented by Formula (R-1).

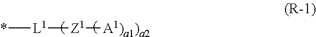

In Formula (R-1), L¹ represents an (a2+1)-valent linking group, Z¹ represents an aromatic group or a cyclic aliphatic group, A¹ represents a polymerizable group, a1 represents an integer of 0 or more and equal to or less than a maximum number of substituents of Z¹, a2 represents an integer of 1 or more, and * represents a bonding site to X¹ or Y¹ in Formula (1-1).

In Formula (R-1), L¹ is preferably a group represented by Formula (L-1).

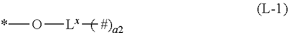

In Formula (L-1), L^{x} represents an (a2+1)-valent linking group, a2 represents an integer of 1 or more, * represents a bonding site to X¹ or Y¹ in Formula (1-1), and #represents a bonding site to Z¹ in Formula (R-1).

L^{x} is preferably an alkylene group, more preferably an alkylene group having 1 to 10 carbon atoms, still more preferably an alkylene group having 1 to 4 carbon atoms, and particularly preferably a methylene group.

The preferred aspect of a2 in Formula (L-1) is the same as the preferred aspect of a2 in Formula (R-1).

Z¹ in Formula (R-1) represents an aromatic group or a cyclic aliphatic group. The preferred aspect of these groups is the same as a preferred aspect of the ring structure with 5 or more ring members in the above-described first specific resin.

A¹ in Formula (R-1) represents a polymerizable group, and the preferred aspect of the polymerizable group is the same as the preferred aspect of the polymerizable group in the first specific resin and the second specific resin described above.

Among these, at least one of A¹'s in Formula (R-1) included in Formula (1-1) is preferably a vinyl group, a (meth)acryloxy group, a vinyl ether group, an allyl group, an epoxy group, or a group including these groups, and more preferably a vinyl group or a vinyl ether group.

In Formula (R-1), a1 is preferably an integer of 0 to 2, and more preferably 0 or 1. In addition, an aspect in which a1 is 1 or 2 is also one of the preferred aspects of the present invention.

In Formula (R-1), a2 represents an integer of 1 or more, and is preferably 1 or 2 and more preferably 1.

In addition, the number of ester bonds included in Formula (R-1) is preferably 1 or 0.

### —X¹—

In Formula (1-1), X¹ represents an organic group including a structure obtained by removing two or more hydrogen atoms from a structure represented by any of Formulae (V-1) to (V-10).

The resolution is improved by being an organic group including a structure obtained by removing two or more hydrogen atoms from a structure represented by any one of Formulae (V-1) to Formula (V-10).

Here, the organic group is an organic group including a structure obtained by removing two or more hydrogen atoms from a structure represented by any of Formula (V-1) to Formula (V-5), and thus, effects such as suppression of generation of development residues, reduction of the dielectric constant of the cured substance, and reduction of the coefficient of thermal expansion can also be obtained.

Here, since the organic group is an organic group including a structure obtained by removing two or more hydrogen atoms from a structure represented by any of Formula (V-6) to Formula (V-10), effects such as that the pattern is less likely to be tapered due to improvement in the transmittance of ultraviolet light and that the tolerance to the exposure amount is wide can also be obtained.

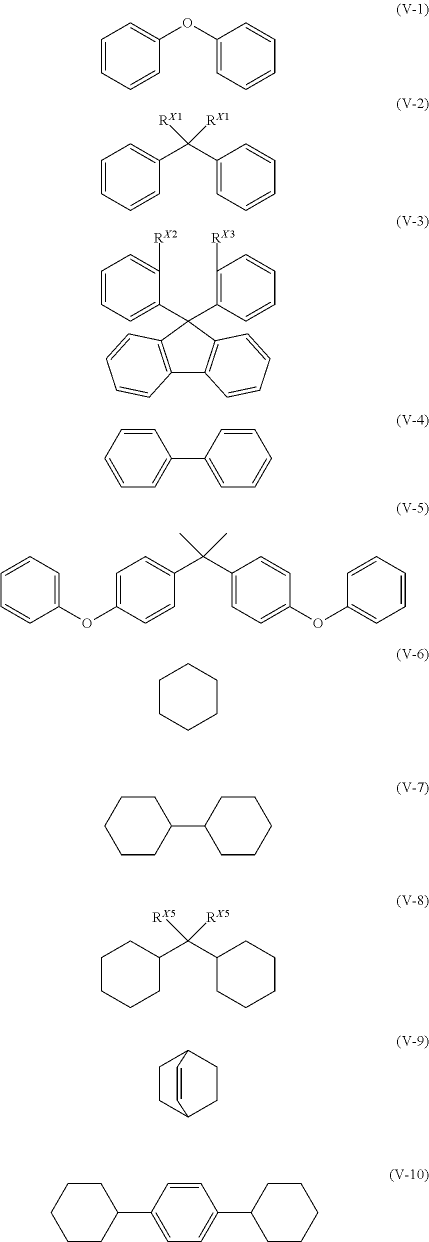

In Formula (V-2), R^{X1}'s each independently represent a hydrogen atom, an alkyl group, or a halogenated alkyl group.

In Formula (V-3), R^{X2} and R^{X3} each independently represent a hydrogen atom or a substituent, and R^{X2} and R^{X3} may be bonded to each other to form a ring structure.

In Formula (V-8), R^{X5}'s each independently represent a hydrogen atom, an alkyl group, or a halogenated alkyl group.

In Formula (V-2), R^{X1}'s are each independently preferably an alkyl group or a halogenated alkyl group, more preferably an alkyl group having 1 to 4 carbon atoms or a halogenated alkyl group having 1 to 4 carbon atoms, and still more preferably a methyl group or a trifluoromethyl group. The halogenated alkyl group refers to a group in which at least one hydrogen atom of an alkyl group is substituted with a halogen atom. As the halogen atom, F or Cl is preferable, and F is more preferable.

In Formula (V-3), R^{X2} and R^{X3} are each independently preferably a hydrogen atom.

In a case where R^{X2} and R^{X3} are bonded to each other to form a ring structure, the structure formed by the bonding of R^{X2} and R^{X3} is preferably a single bond, —O—, or —CR₂—, more preferably —O— or —C(R)₂—, and still more preferably —O—. R represents a hydrogen atom or a monovalent organic group, preferably a hydrogen atom, an alkyl group, or an aryl group, and more preferably a hydrogen atom.

In Formula (V-8), R^{X5}'s are each independently preferably an alkyl group or a halogenated alkyl group, more preferably an alkyl group having 1 to 4 carbon atoms or a halogenated alkyl group having 1 to 4 carbon atoms, and still more preferably a methyl group or a trifluoromethyl group. The halogenated alkyl group refers to a group in which at least one hydrogen atom of an alkyl group is substituted with a halogen atom. As the halogen atom, F or Cl is preferable, and F is more preferable.

In a case where X¹ is a group including a structure obtained by removing two or more hydrogen atoms from a structure represented by Formula (V-1), X¹ is preferably a group represented by Formula (V-1-1). In the following Formula, * represents a bonding site to four carbonyl groups to which X¹ in Formula (1-1) is bonded, and n1 represents an integer of 0 to 5, and it is also preferable that n1 is an integer of 1 to 5. In addition, the hydrogen atom in the following structure may be further substituted with a known substituent such as a hydroxy group or a hydrocarbon group. In addition, in a case where m in Formula (1-1) is an integer of 1 to 4, it is preferable that m hydrogen atoms are substituted with R¹ in Formula (1-1).

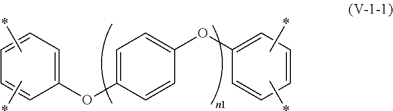

In a case where X¹ is a group including a structure obtained by removing two or more hydrogen atoms from a structure represented by Formula (V-2), X¹ is preferably a group represented by Formula (V-2-1) or Formula (V-2-2), and from the viewpoint of reducing the amine value in the resin, X¹ is preferably a group represented by Formula (V-2-2). In the present specification, a bond that intersects with a side of a ring structure means that any hydrogen atom in the ring structure is substituted. In the following Formula, L^{X1} represents a single bond or —O—, and * represents a bonding site to four carbonyl groups to which X¹ in Formula (1-1) is bonded. In addition, the definition and preferred aspect of R^{X1} are as described above. In addition, the hydrogen atom in these structures may be further substituted with a known substituent such as a hydroxy group or a hydrocarbon group. In addition, in a case where m in Formula (1-1) is an integer of 1 to 4, it is preferable that m hydrogen atoms are substituted with R¹ in Formula (1-1).

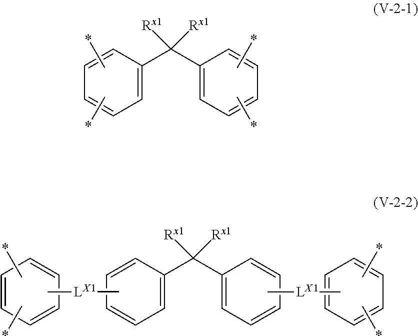

In a case where X¹ is a group including a structure obtained by removing two or more hydrogen atoms from a structure represented by Formula (V-3), X¹ is preferably a group represented by Formula (V-3-1) or Formula (V-3-2), and from the viewpoint of reducing the dielectric constant of the cured substance or the like, X¹ is preferably a group represented by Formula (V-3-2). In the following Formula, * represents a bonding site to four carbonyl groups to which X¹ in Formula (1-1) is bonded. In addition, the definitions and preferred aspects of R^{X2} and R^{X3} are as described above. In addition, the hydrogen atom in these structures may be further substituted with a known substituent such as a hydroxy group or a hydrocarbon group. In addition, in a case where m in Formula (1-1) is an integer of 1 to 4, it is preferable that m hydrogen atoms are substituted with R¹ in Formula (1-1).

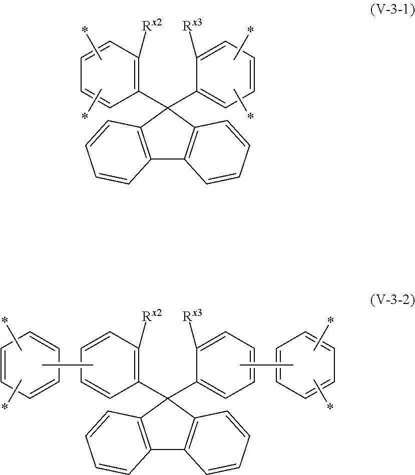

In a case where X¹ is a group including a structure obtained by removing two or more hydrogen atoms from a structure represented by Formula (V-4), X¹ is preferably a group represented by Formula (V-4-1). In the following Formula, * represents a bonding site to four carbonyl groups to which X¹ in Formula (1-1) is bonded, and n1 represents an integer of 0 to 5. In addition, the hydrogen atom in the following structure may be further substituted with a known substituent such as a hydroxy group or a hydrocarbon group. In addition, in a case where m in Formula (1-1) is an integer of 1 to 4, it is preferable that m hydrogen atoms are substituted with R¹ in Formula (1-1). However, it is also preferable that none of the hydrogen atoms in the structure represented by (V-4-1) are substituted.

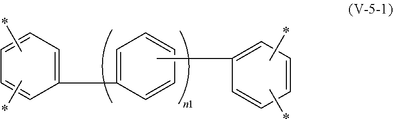

In a case where X¹ is a group including a structure obtained by removing two or more hydrogen atoms from a structure represented by Formula (V-5), X¹ is preferably a group represented by Formula (V-5-1). In the following Formula, * represents a bonding site to four carbonyl groups to which X¹ in Formula (1-1) is bonded. In addition, the hydrogen atom in the following structure may be further substituted with a known substituent such as a hydroxy group or a hydrocarbon group. In addition, in a case where m in Formula (1-1) is an integer of 1 to 4, it is preferable that m hydrogen atoms are substituted with R¹ in Formula (1-1).

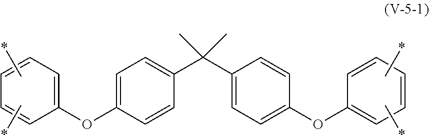

In a case where X¹ is a group including a structure obtained by removing two or more hydrogen atoms from a structure represented by Formula (V-6), X¹ is preferably a group represented by Formula (V-6-1). In the following Formula, * represents a bonding site to four carbonyl groups to which X¹ in Formula (1-1) is bonded. In addition, the hydrogen atom in the following structure may be further substituted with a known substituent such as a hydroxy group or a hydrocarbon group. In addition, in a case where m in Formula (1-1) is an integer of 1 to 4, it is preferable that m hydrogen atoms are substituted with R¹ in Formula (1-1).

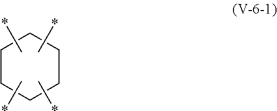

In a case where X¹ is a group including a structure obtained by removing two or more hydrogen atoms from a structure represented by Formula (V-7), X¹ is preferably a group represented by Formula (V-7-1). In the following Formula, * represents a bonding site to four carbonyl groups to which X¹ in Formula (1-1) is bonded. In addition, the hydrogen atom in the following structure may be further substituted with a known substituent such as a hydroxy group or a hydrocarbon group. In addition, in a case where m in Formula (1-1) is an integer of 1 to 4, it is preferable that m hydrogen atoms are substituted with R¹ in Formula (1-1).

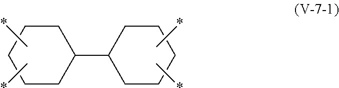

In a case where X¹ is a group including a structure obtained by removing two or more hydrogen atoms from a structure represented by Formula (V-8), X¹ is preferably a group represented by Formula (V-8-1). In the following Formula, * represents a bonding site to four carbonyl groups to which X¹ in Formula (1-1) is bonded. In addition, the hydrogen atom in the following structure may be further substituted with a known substituent such as a hydroxy group or a hydrocarbon group. In addition, in a case where m in Formula (1-1) is an integer of 1 to 4, it is preferable that m hydrogen atoms are substituted with R¹ in Formula (1-1).

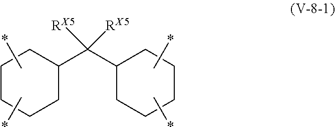

In a case where X¹ is a group including a structure obtained by removing two or more hydrogen atoms from a structure represented by Formula (V-9), X¹ is preferably a group represented by Formula (V-9-1). In the following Formula, * represents a bonding site to four carbonyl groups to which X¹ in Formula (1-1) is bonded. In addition, the hydrogen atom in the following structure may be further substituted with a known substituent such as a hydroxy group or a hydrocarbon group. In addition, in a case where m in Formula (1-1) is an integer of 1 to 4, it is preferable that m hydrogen atoms are substituted with R¹ in Formula (1-1).

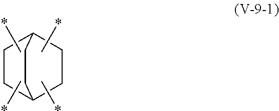

In a case where X¹ is a group including a structure obtained by removing two or more hydrogen atoms from a structure represented by Formula (V-10), X¹ is preferably a group represented by Formula (V-10-1). In the following Formula, * represents a bonding site to four carbonyl groups to which X¹ in Formula (1-1) is bonded. In addition, the hydrogen atom in the following structure may be further substituted with a known substituent such as a hydroxy group or a hydrocarbon group. In addition, in a case where m in Formula (1-1) is an integer of 1 to 4, it is preferable that m hydrogen atoms are substituted with R¹ in Formula (1-1).

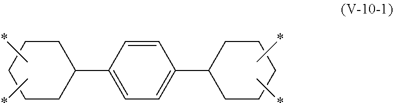

In addition, X¹ may be a group obtained by removing m hydrogen atoms from a group represented by R¹³² in Formula (4) described later.

In addition, it is preferable that X¹ does not contain an imide structure in the structure.

In the present invention, the imide structure is a structure represented by —C(═O)N(—*)C(=O)—. * represents a bonding site to another structure.

In addition, it is preferable that X¹ does not contain a urethane bond, a urea bond, and an amide bond in the structure.

In the present invention, the urethane bond is a bond represented by *—O—C(═O)—NR^{N}—*, where R^{N} represents a hydrogen atom or a monovalent organic group, and *'s each represent a bonding site to a carbon atom. R^{N} is preferably a hydrogen atom, an alkyl group, or an aryl group, and more preferably a hydrogen atom.

In the present invention, the urea bond is a bond represented by *—NR^{N}—C(═O)—NR^{N}*, where R^{N}'s each independently represent a hydrogen atom or a monovalent organic group, and *'s each represent a bonding site to a carbon atom. The preferred aspect of R^{N} is as described above.

In the present invention, the amide bond is a bond represented by *—NR^{N}—C(=O)—*, where R^{N} represents a hydrogen atom or a monovalent organic group, and *'s each represent a bonding site to a carbon atom. The preferred aspect of R^{N} is as described above.

Furthermore, it is preferable that X¹ does not contain an ester bond in the structure.

In the present invention, the ester bond is a bond represented by *—O—C(═O)—*.

Among these, it is preferable that X¹ does not contain an imide structure, a urethane bond, a urea bond, and an amide bond, and it is preferable that X¹ does not contain an imide structure, a urethane bond, a urea bond, an amide bond, and an ester bond.

### —Y¹—

In Formula (1-1), Y¹ is preferably a group including a structure obtained by removing two or more hydrogen atoms from the structures represented by any of Formulae (V-1) to (V-6) and (V-8) described above.

The resolution is improved by being an organic group including a structure obtained by removing two or more hydrogen atoms from a structure represented by any one of Formulae (V-1) to Formula (V-6), or Formula (V-8).

Here, the organic group is an organic group including a structure obtained by removing two or more hydrogen atoms from a structure represented by any of Formula (V-1) to Formula (V-5), and thus, effects such as suppression of generation of development residues, reduction of the dielectric constant of the cured substance, and reduction of the coefficient of thermal expansion can also be obtained.

Here, since the organic group is an organic group including a structure obtained by removing two or more hydrogen atoms from a structure represented by any of Formula (V-6) to Formula (V-8), effects such as that the pattern is less likely to be tapered due to improvement in the transmittance of ultraviolet light and that the tolerance to the exposure amount is wide can also be obtained.

In a case where Y¹ is a group including a structure obtained by removing two or more hydrogen atoms from a structure represented by Formula (V-1), Y¹ is preferably a group obtained by removing n hydrogen atoms from a group represented by Formula (V-1-2). In the following Formula, * represents a bonding site to two nitrogen atoms to which Y¹ in Formula (1-1) is bonded, and n1 represents an integer of 1 to 5. n hydrogen atoms in the following structure are substituted with R¹ in Formula (1-1). n has the same meaning as n in Formula (1-1). In addition, the hydrogen atom in the following structure may be further substituted with a known substituent such as a hydroxy group or a hydrocarbon group.

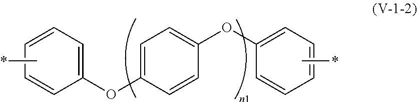

In a case where Y¹ is a group including a structure obtained by removing two or more hydrogen atoms from a structure represented by Formula (V-2), Y¹ is preferably a group represented by Formula (V-2-3) or Formula (V-2-4), and from the viewpoint of reducing the dielectric constant of the cured substance or the like, Y¹ is preferably a group represented by Formula (V-2-4). In the following Formula, L^{X1} represents a single bond or —O—, and * represents a bonding site to two nitrogen atoms to which Y¹ in Formula (1-1) is bonded. In addition, the preferred aspect of R^{X1} is as described above. n hydrogen atoms in the following structure are substituted with R¹ in Formula (1-1). n has the same meaning as n in Formula (1-1). In addition, the hydrogen atom in these structures may be further substituted with a known substituent such as a hydroxy group or a hydrocarbon group.

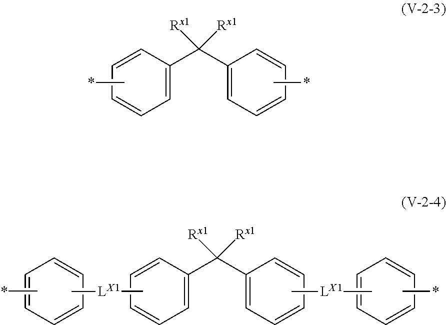

In a case where Y¹ is a group including a structure obtained by removing two or more hydrogen atoms from a structure represented by Formula (V-3), Y¹ is preferably a group represented by Formula (V-3-3) or Formula (V-3-4), and from the viewpoint of reducing the dielectric constant of the cured substance or the like, Y¹ is preferably a group represented by Formula (V-3-3). In the following Formula, * represents a bonding site to two nitrogen atoms to which Y¹ in Formula (1-1) is bonded. In addition, the preferred aspects of R^{X2} and R^{X3} are as described above. n hydrogen atoms in the following structure are substituted with R¹ in Formula (1-1). n has the same meaning as n in Formula (1-1). In addition, the hydrogen atom in these structures may be further substituted with a known substituent such as a hydroxy group or a hydrocarbon group.

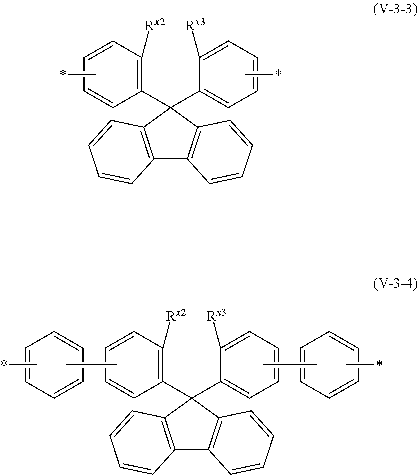

In a case where Y¹ is a group including a structure obtained by removing two or more hydrogen atoms from a structure represented by Formula (V-4), Y¹ is preferably a group represented by Formula (V-4-2). In the following Formula, * represents a bonding site to two nitrogen atoms to which Y¹ in Formula (1-1) is bonded, and n1 represents an integer of 0 to 5. In addition, an aspect in which n1 is 0 is also one of the preferred aspects of the present invention. n hydrogen atoms in the following structure are substituted with R¹ in Formula (1-1). n has the same meaning as n in Formula (1-1). In addition, the hydrogen atom in the following structure may be further substituted with a known substituent such as a hydroxy group or a hydrocarbon group.

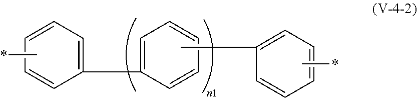

In a case where Y¹ is a group including a structure obtained by removing two or more hydrogen atoms from a structure represented by Formula (V-5), Y¹ is preferably a group represented by Formula (V-5-2). In the following Formula, * represents a bonding site to two nitrogen atoms to which Y¹ in Formula (1-1) is bonded. n hydrogen atoms in the following structure are substituted with R¹ in Formula (1-1). n has the same meaning as n in Formula (1-1). In addition, the hydrogen atom in the following structure may be further substituted with a known substituent such as a hydroxy group or a hydrocarbon group.

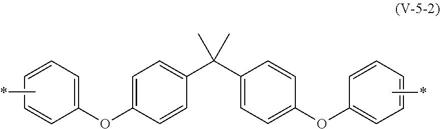

In a case where Y¹ is a group including a structure obtained by removing two or more hydrogen atoms from a structure represented by Formula (V-6), Y¹ is preferably a group represented by Formula (V-6-2). In the following Formula, * represents a bonding site to two nitrogen atoms to which Y¹ in Formula (1-1) is bonded. n hydrogen atoms in the following structure are substituted with R¹ in Formula (1-1). n has the same meaning as n in Formula (1-1). In addition, the hydrogen atom in the following structure may be further substituted with a known substituent such as a hydroxy group or a hydrocarbon group.

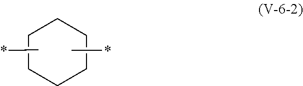

In a case where Y¹ is a group including a structure obtained by removing two or more hydrogen atoms from a structure represented by Formula (V-8), Y¹ is preferably a group represented by Formula (V-8-2). In the following Formula, * represents a bonding site to two nitrogen atoms to which Y¹ in Formula (1-1) is bonded. n hydrogen atoms in the following structure are substituted with R¹ in Formula (1-1). n has the same meaning as n in Formula (1-1). In addition, the hydrogen atom in the following structure may be further substituted with a known substituent such as a hydroxy group or a hydrocarbon group.

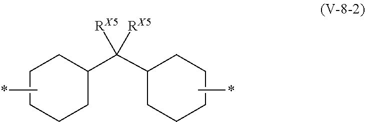

In addition, Y¹ may be a group obtained by removing n hydrogen atoms from a group represented by R¹³¹ in Formula (4) described later.

In addition, it is preferable that Y¹ does not contain an imide structure in the structure.

In addition, it is preferable that Y¹ does not contain a urethane bond, a urea bond, and an amide bond in the structure.

Furthermore, it is preferable that Y¹ does not contain an ester bond in the structure.

Among these, it is preferable that Y¹ does not contain an imide structure, a urethane bond, a urea bond, and an amide bond, and it is preferable that Y¹ does not contain an imide structure, a urethane bond, a urea bond, an amide bond, and an ester bond.

Among these, it is preferable that X¹ and Y¹ in Formula (1-1) each include a structure obtained by removing two or more hydrogen atoms from a structure represented by any one of Formulae (V-1) to (V-4).

In Formula (1-1), m is preferably an integer of 0 to 2, and more preferably 0 or 1. In addition, an aspect in which m is 0 is also one of the preferred aspects of the present invention.

In Formula (1-1), n is preferably 1 or 2, and more preferably 2.

The first specific resin may include a repeating unit represented by Formula (1-1) in addition to the repeating unit represented by Formula (1-2).

It is also preferable that the second specific resin includes a repeating unit represented by Formula (1-2).

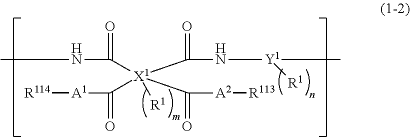

In Formula (1-2), A¹ and A² each independently represent an oxygen atom or —NR^{z}—, X¹ represents an organic group having 4 or more carbon atoms, Y¹ represents an organic group having 4 or more carbon atoms, R¹'s each independently represent a group having a polymerizable group, R¹¹³ and R¹¹⁴ each independently represent a hydrogen atom or a monovalent organic group, R^{Z} represents a hydrogen atom or a monovalent organic group, m represents an integer of 0 to 4, and n represents an integer of 1 or more.

Preferred aspects of X¹, Y¹, R¹, n, and m in Formula (1-2) are the same as the preferred aspects of X¹, Y¹, R¹, n, and m in Formula (1-1) described above.

Preferred aspects of A¹, A², R¹¹³, and R¹¹⁴ in Formula (1-2) are the same as the preferred aspects of A¹, A², R¹¹³, and R¹¹⁴ in Formula (2) described later.

The first specific resin may include a repeating unit represented by Formula (1-1) in addition to the repeating unit represented by Formula (1-3).

It is also preferable that the second specific resin includes a repeating unit represented by Formula (1-3).

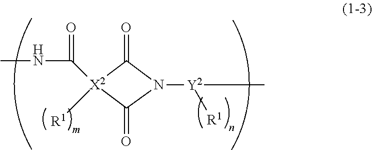

In Formula (1-3), X² represents a (3+m)-valent linking group, Y² represents a (2+n)-valent linking group, R¹'s each independently represent an organic group having a polymerizable group, m represents an integer of 0 to 4, and n represents an integer of 1 or more.

In Formula (1-3), examples of X² include a linear or branched aliphatic group, a cyclic aliphatic group, an aromatic group, and a group obtained by linking two or more of these groups through a single bond or a linking group, where X² is preferably a linear aliphatic group having 2 to 20 carbon atoms, a branched aliphatic group having 3 to 20 carbon atoms, a cyclic aliphatic group having 3 to 20 carbon atoms, an aromatic group having 6 to 20 carbon atoms, or a group obtained by combining two or more of these groups through a single bond or a linking group, and X² is more preferably an aromatic group having 6 to 20 carbon atoms or a group obtained by combining two or more aromatic groups having 6 to 20 carbon atoms through a single bond or a linking group.

The linking group is preferably —O—, —S—, —C(═O)—, —S(═O)₂—, an alkylene group, a halogenated alkylene group, an arylene group, or a linking group obtained by bonding two or more these, and it is more preferably —O—, —S—, an alkylene group, a halogenated alkylene group, an arylene group, or a linking group obtained by bonding two or more these.

The alkylene group is preferably an alkylene group having 1 to 20 carbon atoms, more preferably an alkylene group having 1 to 10 carbon atoms, and still more preferably an alkylene group having 1 to 4 carbon atoms.

The halogenated alkylene group is preferably a halogenated alkylene group having 1 to 20 carbon atoms, more preferably a halogenated alkylene group having 1 to 10 carbon atoms, and still more preferably a halogenated alkylene group having 1 to 4 carbon atoms. In addition, examples of the halogen atom in the halogenated alkylene group include a fluorine atom, a chlorine atom, a bromine atom, and an iodine atom, where a fluorine atom is preferable. The halogenated alkylene group may have a hydrogen atom, or all hydrogen atoms in the halogenated alkylene group may be substituted with a halogen atom. However, it is preferable that all hydrogen atoms are substituted with a halogen atom. Examples of the preferred halogenated alkylene group include a (ditrifluoromethyl)methylene group.

The arylene group is preferably a phenylene group or a naphthylene group, more preferably a phenylene group, and still more preferably a 1,3-phenylene group or a 1,4-phenylene group.

In addition, X² is preferably derived from a tricarboxylic acid compound in which at least one carboxy group may be subjected to halogenation. Here, the halogenation is preferably chlorination.

In the present invention, a compound having three carboxy groups is referred to as a tricarboxylic acid compound.

Two carboxy groups of the three carboxy groups of the tricarboxylic acid compound may be subjected to acid anhydrization.

Examples of the tricarboxylic acid compound which may be halogenated, which is used in the production of the polyamideimide precursor, include a branched aliphatic, cyclic aliphatic, or aromatic tricarboxylic acid compound.

One kind of these tricarboxylic acid compounds may be used alone, or two or more kinds thereof may be used.

In addition, it is preferable that X² does not contain an imide structure in the structure.

In addition, it is preferable that X² does not contain a urethane bond, a urea bond, and an amide bond in the structure.

Furthermore, it is preferable that X² does not contain an ester bond in the structure.

Among these, it is preferable that X¹ does not contain an imide structure, a urethane bond, a urea bond, and an amide bond, and it is preferable that X¹ does not contain an imide structure, a urethane bond, a urea bond, an amide bond, and an ester bond.

Specifically, the tricarboxylic acid compound is preferably a tricarboxylic acid compound containing a linear aliphatic group having 2 to 20 carbon atoms, a branched aliphatic group having 3 to 20 carbon atoms, a cyclic aliphatic group having 3 to 20 carbon atoms, an aromatic group having 6 to 20 carbon atoms, or a group obtained by combining two or more of these groups through a single bond or a linking group, and more preferably a tricarboxylic acid compound containing an aromatic group having 6 to 20 carbon atoms or a group obtained by combining two or more aromatic groups having 6 to 20 carbon atoms through a single bond or a linking group.

Specific examples of the tricarboxylic acid compound include 1,2,3-propanetricarboxylic acid, 1,3,5-pentanetricarboxylic acid, citric acid, trimellitic acid, 2,3,6-naphthalenetricarboxylic acid, and a compound in which phthalic acid (or phthalic anhydride) and benzoic acid are linked through a single bond, —O—, —CH₂—, —C(CH₃)₂—, —C(CF₃)₂—, —SO₂—, or a phenylene group.

These compounds may be a compound (for example, a trimellitic acid anhydride) in which two carboxy groups have been subjected to anhydrization or may be a compound (for example, trimellitic anhydride chloride) in which at least one carboxy group has been halogenated.

In Formula (1-3), Y², R¹, n, and m respectively have the same meanings as Y¹, R¹, n, and m in Formula (1-1) described above, and preferred aspects thereof are also the same.

In a case where the specific resin includes a repeating unit represented by Formula (1-3), it is preferable that the specific resin includes a repeating unit represented by Formula (1-3-2).

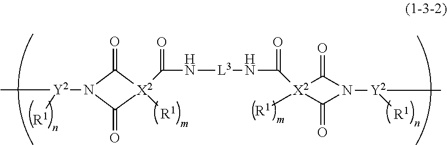

In Formula (1-3-2), X²'s each independently represent a (3+m)-valent linking group, Y²'s each independently represent a (2+n)-valent linking group, R¹'s each independently represent an organic group having a polymerizable group, m's each independently represent an integer of 0 to 4, n's each independently represent an integer of 1 or more, and L³ represents a divalent linking group.

In Formula (1-3-2), the preferred aspects of X², Y², R¹, m, and n are the same as the preferred aspects of X², Y², R¹, m, and n in Formula (1-3) described above.

In Formula (1-3-2), examples of L³ include a linear or branched aliphatic group, a cyclic aliphatic group, an aromatic group, and a group obtained by linking two or more of these groups through a single bond or a linking group, where L³ is preferably a linear aliphatic group having 2 to 20 carbon atoms, a branched aliphatic group having 3 to 20 carbon atoms, a cyclic aliphatic group having 3 to 20 carbon atoms, an aromatic group having 6 to 20 carbon atoms, or a group obtained by combining two or more of these groups through a single bond or a linking group, and L³ is more preferably an aromatic group having 6 to 20 carbon atoms or a group obtained by combining two or more aromatic groups having 6 to 20 carbon atoms through a single bond or a linking group.

The linking group is preferably —O—, —S—, —C(═O)—, —S(═O)₂—, an alkylene group, a halogenated alkylene group, an arylene group, or a linking group obtained by bonding two or more these, and it is more preferably —O—, —S—, an alkylene group, a halogenated alkylene group, an arylene group, or a linking group obtained by bonding two or more these.

The alkylene group is preferably an alkylene group having 1 to 20 carbon atoms, more preferably an alkylene group having 1 to 10 carbon atoms, and still more preferably an alkylene group having 1 to 4 carbon atoms.

The halogenated alkylene group is preferably a halogenated alkylene group having 1 to 20 carbon atoms, more preferably a halogenated alkylene group having 1 to 10 carbon atoms, and still more preferably a halogenated alkylene group having 1 to 4 carbon atoms. In addition, examples of the halogen atom in the halogenated alkylene group include a fluorine atom, a chlorine atom, a bromine atom, and an iodine atom, where a fluorine atom is preferable. The halogenated alkylene group may have a hydrogen atom, or all hydrogen atoms in the halogenated alkylene group may be substituted with a halogen atom. However, it is preferable that all hydrogen atoms are substituted with a halogen atom. Examples of the preferred halogenated alkylene group include a (ditrifluoromethyl)methylene group.

The arylene group is preferably a phenylene group or a naphthylene group, more preferably a phenylene group, and still more preferably a 1,3-phenylene group or a 1,4-phenylene group.

The first specific resin may include a repeating unit represented by Formula (1-1) in addition to the repeating unit represented by Formula (1-4).

It is also preferable that the second specific resin includes a repeating unit represented by Formula (1-4).

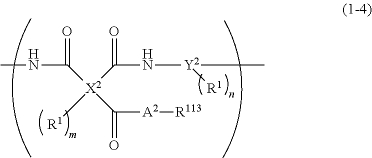

In Formula (1-4), X² represents a (3+m)-valent linking group, Y² represents a (2+n)-valent linking group, R¹'s are each independently an organic group having a polymerizable group, m represents an integer of 0 to 4, n represents an integer of 1 or more, A² represents an oxygen atom or —NR^{z}—, R^{z} represents a hydrogen atom or a monovalent organic group, and R¹¹³ represents a hydrogen atom or a monovalent organic group.

Preferred aspects of X², Y², R¹, n, and m in Formula (1-4) are the same as the preferred aspects of X², Y², R¹, n, and m in Formula (1-3) described above.

Preferred aspects of A² and R¹¹³ in Formula (1-4) are the same as the preferred aspects of A² and R¹¹³ in Formula (2) described later.

In a case where the specific resin includes a repeating unit represented by Formula (1-4), it is preferable that the specific resin includes a repeating unit represented by Formula (1-4-2).

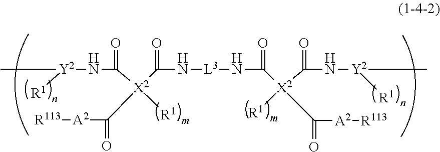

In Formula (1-4-2), X²'s each independently represent a (3+m)-valent linking group, Y²'s each independently represent a (2+n)-valent linking group, R¹'s each independently represent an organic group having a polymerizable group, m's each independently represent an integer of 0 to 4, n's each independently represent an integer of 1 or more, A²'s each independently represent an oxygen atom or —NR^{z}—, R^{z}'s each independently represent a hydrogen atom or a monovalent organic group, R¹¹³'s each independently represent a hydrogen atom or a monovalent organic group, and L³ represents a divalent linking group.

In Formula (1-4-2), preferred aspects of X², Y², R¹, m, n, A², and R¹¹³ are the same as the preferred aspects of X², Y², R¹, m, n, A², and R¹¹³ in Formula (1-4) described above.

In Formula (1-4-2), a preferred aspect of L³ is the same as the preferred aspect of L³ in Formula (1-3-2) described above.

The first specific resin may include a repeating unit represented by Formula (1-1) in addition to the repeating unit represented by Formula (1-5).

It is also preferable that the second specific resin includes a repeating unit represented by Formula (1-5).

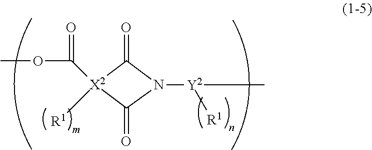

In Formula (1-5), X² represents a (3+m)-valent linking group, Y² represents a (2+n)-valent linking group, R¹'s each independently represent an organic group having a polymerizable group, m represents an integer of 0 to 4, and n represents an integer of 1 or more.

In Formula (1-5), preferred aspects of X², Y², R¹, m, and n are respectively the same as the preferred aspects of X², Y², R¹, m, and n in Formula (1-3).

In a case where the specific resin includes a repeating unit represented by Formula (1-5), it is preferable that the specific resin includes a repeating unit represented by Formula (1-5-2).

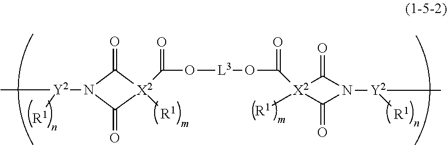

In Formula (1-5-2), X²'s each independently represent a (3+m)-valent linking group, Y²'s each independently represent a (2+n)-valent linking group, R¹'s each independently represent an organic group having a polymerizable group, m's each independently represent an integer of 0 to 4, n's each independently represent an integer of 1 or more, and L³ represents a divalent linking group.

In Formula (1-5-2), the preferred aspects of X², Y², R¹, m, n, and L³ are the same as the preferred aspects of X², Y², R¹, m, n, and L³ in Formula (1-3-2) described above.

The first specific resin may include a repeating unit represented by Formula (1-1) in addition to the repeating unit represented by Formula (1-6).

It is also preferable that the second specific resin includes a repeating unit represented by Formula (1-6).

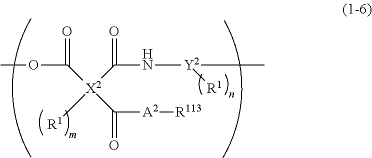

In Formula (1-6), X² represents a (3+m)-valent linking group, Y² represents a (2+n)-valent linking group, R¹'s are each independently an organic group having a polymerizable group, m represents an integer of 0 to 4, n represents an integer of 1 or more, A² represents an oxygen atom or —NR^{z}—, R^{z} represents a hydrogen atom or a monovalent organic group, and R¹¹³ represents a hydrogen atom or a monovalent organic group.

Preferred aspects of X², Y², R¹, n, and m in Formula (1-6) are the same as the preferred aspects of X², Y², R¹, n, and m in Formula (1-5) described above.

Preferred aspects of A² and R¹¹³ in Formula (1-6) are the same as the preferred aspects of A² and R¹¹³ in Formula (2) described later.

In a case where the specific resin includes a repeating unit represented by Formula (1-6), it is preferable that the specific resin includes a repeating unit represented by Formula (1-6-2).

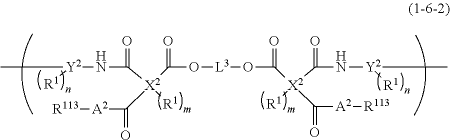

In Formula (1-6-2), X²'s each independently represent a (3+m)-valent linking group, Y²'s each independently represent a (2+n)-valent linking group, R¹'s each independently represent an organic group having a polymerizable group, m's each independently represent an integer of 0 to 4, n's each independently represent an integer of 1 or more, A²'s each independently represent an oxygen atom or —NR^{z}—, R^{z}'s each independently represent a hydrogen atom or a monovalent organic group, R¹¹³'s each independently represent a hydrogen atom or a monovalent organic group, and L³ represents a divalent linking group.

In Formula (1-6-2), preferred aspects of X², Y², R¹, m, n, A², and R¹¹³ are the same as the preferred aspects of X², Y², R¹, m, n, A², and R¹¹³ in Formula (1-6) described above.

In Formula (1-6-2), a preferred aspect of L³ is the same as the preferred aspect of L³ in Formula (1-3-2) described above.

The specific resin may include a repeating unit represented by Formula (2).

The repeating unit corresponding to the repeating unit represented by Formula (1-2) does not correspond to the repeating unit represented by Formula (2).

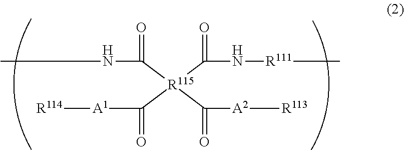

In Formula (2), A¹ and A² each independently represent an oxygen atom or —NR^{z}—, R¹¹¹ represents a divalent organic group, R¹¹⁵ represents a tetravalent organic group, R¹¹³ and R¹¹⁴ each independently represent a hydrogen atom or a monovalent organic group, and R^{Z} represents a hydrogen atom or a monovalent organic group.

A¹ and A² in Formula (2) each independently represent an oxygen atom or —NR^{Z}—, and an oxygen atom is preferable.

R^{Z} represents a hydrogen atom or a monovalent organic group, and a hydrogen atom is preferable.

R¹¹¹ in Formula (2) represents a divalent organic group. Examples of R¹¹¹ include groups described in paragraphs 0042 to 0053 of JP2023-003421A. These descriptions are incorporated into the present specification.

In addition, R¹¹¹ is also preferably a group including a structure obtained by removing two or more hydrogen atoms from the structure represented by any one of Formula (V-1) to Formula (V-10) described above, the group having no bonding site to R¹ described above. A preferred aspect of such a group is the same as the preferred aspect of the group including a structure obtained by removing two or more hydrogen atoms from the structure represented by any one of Formulae (V-1) to (V-10) in Y¹ included in Formula (1-2), except that the group does not have a bonding site to R¹.

Specific examples of R¹¹⁵ include a tetracarboxylic acid residue that remains after the removal of the anhydride group from the tetracarboxylic acid dianhydride. The specific resin may contain only one kind of tetracarboxylic acid dianhydride residue or may contain two or more kinds thereof, as a structure corresponding to R¹¹⁵.

Examples of the tetracarboxylic acid dianhydride include the compounds described in paragraphs 0055 to 0057 of JP2023-003421A. These descriptions are incorporated into the present specification.

In addition, R¹¹¹ is also preferably a group including a structure obtained by removing two or more hydrogen atoms from the structure represented by any one of Formula (V-1) to Formula (V-10) described above, the group having no bonding site to R¹ described above. A preferred aspect of such a group is the same as the preferred aspect of the group including a structure obtained by removing two or more hydrogen atoms from the structure represented by any one of Formulae (V-1) to (V-10) included in X¹ in Formula (1-2), except that the group does not have a bonding site to R¹.

In Formula (2), it is also possible that at least one of R¹¹¹ or R¹¹⁵ has an OH group. More specifically, examples of R¹¹¹ include a residue of a bisaminophenol derivative.

R¹¹³ and R¹¹⁴ in Formula (2) each independently represent a hydrogen atom or a monovalent organic group. Examples of R¹¹³ and R¹¹⁴ include groups described in paragraphs 0058 to 0063 of JP2023-003421A. These descriptions are incorporated into the present specification.

The first specific resin and the second specific resin may include a repeating unit represented by Formula (4).

The repeating unit corresponding to the repeating unit represented by Formula (1-1) does not correspond to the repeating unit represented by Formula (4).

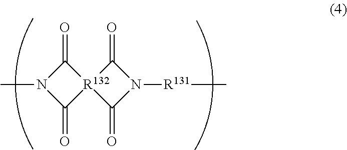

In Formula (4), R¹³¹ represents a divalent organic group, and R¹³² represents a tetravalent organic group.

R¹³¹ represents a divalent organic group. Examples of the divalent organic group include the same one as R¹¹¹ in Formula (2), and the same applies to the preferred range thereof.

Examples of R¹³¹ include a diamine residue that remains after the removal of an amino group of a diamine. Examples of the diamine include an aliphatic, a cyclic aliphatic, and an aromatic diamine. Specific examples thereof include the example of R¹¹¹ in Formula (2) which is contained in the polyimide precursor.

It is preferable that R¹³¹ is a diamine residue having at least two alkylene glycol units in the main chain from the viewpoint of more effectively suppressing the occurrence of warping during baking. It is more preferably a diamine residue containing, in one molecule, a total of two or more chains of any one or both of the ethylene glycol chain and the propylene glycol chain, and it is still more preferably the above-described diamine which is a diamine residue containing no aromatic ring.

Examples of the diamine containing, in one molecule, a total of two or more chains of any one or both of the ethylene glycol chain and the propylene glycol chain include JEFFAMINE (registered trade name) KH-511, ED-600, ED-900, ED-2003, EDR-148, EDR-176, D-200, D-400, D-2000, D-4000 (all product names, manufactured by HUNTSMAN Corporation), 1-(2-(2-(2-aminopropoxy)ethoxy)propoxy)propane-2-amine, and 1-(1-(1-(2-aminopropoxy)propan-2-yl)oxy)propane-2-amine, which are not limited thereto.

R¹³² represents a tetravalent organic group. Examples of the tetravalent organic group include the same one as R¹¹⁵ in Formula (2), and the same applies to the preferred range thereof.

For example, four bonding partners of the tetravalent organic group exemplified as R¹¹⁵ are bonded to four —C(═O)—moieties in Formula (4) to form a fused ring.

Examples of R¹³² include a tetracarboxylic acid residue that remains after the removal of the anhydride group from the tetracarboxylic acid dianhydride. Specific examples thereof include the example of R¹¹⁵ in Formula (2) which is contained in the polyimide precursor. From the viewpoint of the hardness of the organic film, R¹³² is preferably an aromatic diamine residue having 1 to 4 aromatic rings.

It is also preferable that an OH group is contained in at least one of R¹³¹ or R¹³². More specifically, preferred examples of R¹³¹ include 2,2-bis(3-hydroxy-4-aminophenyl)propane, 2,2-bis(3-hydroxy-4-aminophenyl)hexafluoropropane, 2,2-bis(3-amino-4-hydroxyphenyl)propane, 2,2-bis(3-amino-4-hydroxyphenyl)hexafluoropropane, and the above (DA-1) to (DA-18), and more preferred examples of R¹³² include the above (DAA-1) to (DAA-5).

The first specific resin and the second specific resin may include a repeating unit represented by Formula (PAI-2).

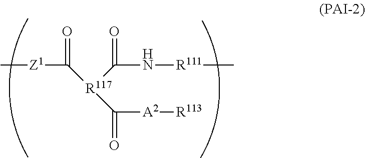

In Formula (PAI-2), R¹¹⁷ represents a trivalent organic group, R¹¹¹ represents a divalent organic group, A² represents an oxygen atom or —NH—, Z¹ represents an oxygen atom or —NH—, and R¹¹³ represents a hydrogen atom or a monovalent organic group.

In Formula (PAI-2), examples of R¹¹⁷ include a linear or branched aliphatic group, a cyclic aliphatic group, an aromatic group, a heteroaromatic group, and a group obtained by linking two or more of these groups through a single bond or a linking group, where R¹¹⁷ is preferably a linear aliphatic group having 2 to 20 carbon atoms, a branched aliphatic group having 3 to 20 carbon atoms, a cyclic aliphatic group having 3 to 20 carbon atoms, an aromatic group having 6 to 20 carbon atoms, or a group obtained by combining two or more of these groups through a single bond or a linking group, and R¹¹⁷ is more preferably an aromatic group having 6 to 20 carbon atoms or a group obtained by combining two or more aromatic groups having 6 to 20 carbon atoms through a single bond or a linking group.

The linking group is preferably —O—, —S—, —C(═O)—, —S(═O)₂—, an alkylene group, a halogenated alkylene group, an arylene group, or a linking group obtained by bonding two or more these, and it is more preferably —O—, —S—, an alkylene group, a halogenated alkylene group, an arylene group, or a linking group obtained by bonding two or more these.

The alkylene group is preferably an alkylene group having 1 to 20 carbon atoms, more preferably an alkylene group having 1 to 10 carbon atoms, and still more preferably an alkylene group having 1 to 4 carbon atoms.

The halogenated alkylene group is preferably a halogenated alkylene group having 1 to 20 carbon atoms, more preferably a halogenated alkylene group having 1 to 10 carbon atoms, and still more preferably a halogenated alkylene group having 1 to 4 carbon atoms. In addition, examples of the halogen atom in the halogenated alkylene group include a fluorine atom, a chlorine atom, a bromine atom, and an iodine atom, where a fluorine atom is preferable. The halogenated alkylene group may have a hydrogen atom, or all hydrogen atoms in the halogenated alkylene group may be substituted with a halogen atom. However, it is preferable that all hydrogen atoms are substituted with a halogen atom. Examples of the preferred halogenated alkylene group include a (ditrifluoromethyl)methylene group.

The arylene group is preferably a phenylene group or a naphthylene group, more preferably a phenylene group, and still more preferably a 1,3-phenylene group or a 1,4-phenylene group.

In addition, R¹¹⁷ is preferably derived from a tricarboxylic acid compound in which at least one carboxy group may be subjected to halogenation. Here, the halogenation is preferably chlorination.

In the present invention, a compound having three carboxy groups is referred to as a tricarboxylic acid compound.

Two carboxy groups of the three carboxy groups of the tricarboxylic acid compound may be subjected to acid anhydrization.

Examples of the tricarboxylic acid compound include a branched aliphatic, cyclic aliphatic, or aromatic tricarboxylic acid compound.

One kind of these tricarboxylic acid compounds may be used alone, or two or more kinds thereof may be used.

Specifically, the tricarboxylic acid compound is preferably a tricarboxylic acid compound containing a linear aliphatic group having 2 to 20 carbon atoms, a branched aliphatic group having 3 to 20 carbon atoms, a cyclic aliphatic group having 3 to 20 carbon atoms, an aromatic group having 6 to 20 carbon atoms, or a group obtained by combining two or more of these groups through a single bond or a linking group, and more preferably a tricarboxylic acid compound containing an aromatic group having 6 to 20 carbon atoms or a group obtained by combining two or more aromatic groups having 6 to 20 carbon atoms through a single bond or a linking group.

Specific examples of the tricarboxylic acid compound include 1,2,3-propanetricarboxylic acid, 1,3,5-pentanetricarboxylic acid, citric acid, trimellitic acid, 2,3,6-naphthalenetricarboxylic acid, and a compound in which phthalic acid (or phthalic anhydride) and benzoic acid are linked through a single bond, —O—, —CH₂—, —C(CH₃)₂—, —C(CF₃)₂—, —SO₂—, or a phenylene group.

These compounds may be a compound (for example, a trimellitic acid anhydride) in which two carboxy groups have been subjected to anhydrization or may be a compound (for example, trimellitic anhydride chloride) in which at least one carboxy group has been halogenated.

In Formula (PAI-2), R¹¹¹, A², and R¹¹³ respectively have the same meanings as R¹¹¹, A², and R¹¹³ in Formula (2) described above, and the same applies to the preferred aspects thereof.

The specific resin may include a repeating unit represented by Formula (PAI-1).

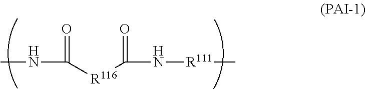

In Formula (PAI-1), R¹¹⁶ represents a divalent organic group, and R¹¹¹ represents a divalent organic group.

In Formula (PAI-1), examples of R¹¹⁶ include a linear or branched aliphatic group, a cyclic aliphatic group, an aromatic group, a heteroaromatic group, and a group obtained by linking two or more of these groups through a single bond or a linking group, where R¹¹⁶ is preferably a linear aliphatic group having 2 to 20 carbon atoms, a branched aliphatic group having 3 to 20 carbon atoms, a cyclic aliphatic group having 3 to 20 carbon atoms, an aromatic group having 6 to 20 carbon atoms, or a group obtained by combining two or more of these groups through a single bond or a linking group, and R¹¹⁶ is more preferably an aromatic group having 6 to 20 carbon atoms or a group obtained by combining two or more aromatic groups having 6 to 20 carbon atoms through a single bond or a linking group.

The linking group is preferably —O—, —S—, —C(═O)—, —S(═O)₂—, an alkylene group, a halogenated alkylene group, an arylene group, or a linking group obtained by bonding two or more these, and it is more preferably —O—, —S—, an alkylene group, a halogenated alkylene group, an arylene group, or a linking group obtained by bonding two or more these.

The alkylene group is preferably an alkylene group having 1 to 20 carbon atoms, more preferably an alkylene group having 1 to 10 carbon atoms, and still more preferably an alkylene group having 1 to 4 carbon atoms.

The halogenated alkylene group is preferably a halogenated alkylene group having 1 to 20 carbon atoms, more preferably a halogenated alkylene group having 1 to 10 carbon atoms, and still more preferably a halogenated alkylene group having 1 to 4 carbon atoms. In addition, examples of the halogen atom in the halogenated alkylene group include a fluorine atom, a chlorine atom, a bromine atom, and an iodine atom, where a fluorine atom is preferable. The halogenated alkylene group may have a hydrogen atom, or all hydrogen atoms in the halogenated alkylene group may be substituted with a halogen atom. However, it is preferable that all hydrogen atoms are substituted with a halogen atom. Examples of the preferred halogenated alkylene group include a (ditrifluoromethyl)methylene group.

The arylene group is preferably a phenylene group or a naphthylene group, more preferably a phenylene group, and still more preferably a 1,3-phenylene group or a 1,4-phenylene group.

In addition, R¹¹⁶ is preferably derived from a dicarboxylic acid compound or a dicarboxylic acid dihalide compound.

In the present invention, a compound having two carboxy groups is referred to as a dicarboxylic acid compound, and a compound having two halogenated carboxy groups is referred to as a dicarboxylic acid dihalide compound.

The carboxy group in the dicarboxylic acid dihalide compound may be halogenated; however, it is, for example, preferably chlorinated. That is, the dicarboxylic acid dihalide compound is preferably a dicarboxylic acid dichloride compound.

Examples of the dicarboxylic acid compound which may be halogenated or the dicarboxylic acid dihalide compound include a linear or branched aliphatic, cyclic aliphatic, or aromatic dicarboxylic acid compound, and a dicarboxylic acid dihalide compound.

One kind of these dicarboxylic acid compounds or dicarboxylic acid dihalide compounds may be used alone, or two or more kinds thereof may be used.

Specifically, the dicarboxylic acid compound or the dicarboxylic acid dihalide compound is preferably a dicarboxylic acid compound or dicarboxylic acid dihalide compound containing a linear aliphatic group having 2 to 20 carbon atoms, a branched aliphatic group having 3 to 20 carbon atoms, a cyclic aliphatic group having 3 to 20 carbon atoms, an aromatic group having 6 to 20 carbon atoms, or a group obtained by combining two or more of these groups through a single bond or a linking group, and more preferably a dicarboxylic acid compound or dicarboxylic acid dihalide compound containing an aromatic group having 6 to 20 carbon atoms or a group obtained by combining two or more aromatic groups having 6 to 20 carbon atoms through a single bond or a linking group.

In addition, specific example of the dicarboxylic acid compound include malonic acid, dimethylmalonic acid, ethylmalonic acid, isopropylmalonic acid, di-n-butylmalonic acid, succinic acid, tetrafluorosuccinic acid, methylsuccinic acid, 2,2-dimethylsuccinic acid, 2,3-dimethylsuccinic acid, dimethylmethylsuccinic acid, glutaric acid, hexafluoroglutaric acid, 2-methylglutaric acid, 3-methylglutaric acid, 2,2-dimethylglutaric acid, 3,3-dimethylglutaric acid, 3-ethyl-3-methylglutaric acid, adipic acid, octafluoroadipic acid, 3-methyladipic acid, pimelliic acid, 2,2,6,6-tetramethylpimelic acid, suberic acid, dodecafluorosuberic acid, azelaic acid, sebacic acid, hexadecafluorosebacic acid, 1,9-nonanedioic acid, dodecanedioic acid, tridecanedioic acid, tetradecanedioic acid, pentadecanedioic acid, hexadecanedioic acid, heptadecanedioic acid, octadecanedioic acid, nonadecanedioic acid, eicosanedioic acid, heneicosanedioic acid, docosanedioic acid, tricosanedioic acid, tetracosanedioic acid, pentacosanedioic acid, hexacosanedioic acid, heptacosanedioic acid, octacosanedioic acid, nonacosanedioic acid, triacontanedioic acid, hentriacontanedioic acid, dotriacontanedioic acid, diglycolic acid, phthalic acid, isophthalic acid, terephthalic acid, 4,4′-biphenylcarboxylic acid, 4,4′-dicarboxydiphenyl ether, and benzophenone-4,4′-dicarboxylic acid.

Specific examples of the dicarboxylic acid dihalide compound include a compound having a structure in which two carboxy groups in the specific examples of the dicarboxylic acid compound are halogenated.

In Formula (PAI-1), R¹¹¹ has the same meaning as R¹¹¹ in Formula (2) described above, and the same applies to the preferred aspect thereof.

In a case where the specific resin is a polyimide, the content of the repeating unit represented by Formula (1-1) is preferably 30% by mass or more, more preferably 50% by mass or more, still more preferably 70% by mass or more, and particularly preferably 80% by mass or more with respect to the total mass of the specific resin. The upper limit of the content is not particularly limited, and may be 100% by mass.

In a case where the specific resin is a polyimide, the total content of the repeating unit represented by Formula (1-1), the repeating unit represented by Formula (1-3), and the repeating unit represented by Formula (1-5) with respect to the total mass of the specific resin is preferably 30% by mass or more, preferably 50% by mass or more, still more preferably 70% by mass or more, and particularly preferably 80% by mass or more. The upper limit of the content is not particularly limited, and may be 100% by mass.

In a case where the specific resin is a polyimide, the total content of the repeating unit represented by Formula (1-1), the repeating unit represented by Formula (1-3-2), and the repeating unit represented by Formula (1-5-2) with respect to the total mass of the specific resin is preferably 30% by mass or more, preferably 50% by mass or more, still more preferably 70% by mass or more, and particularly preferably 80% by mass or more. The upper limit of the content is not particularly limited, and may be 100% by mass.

In addition, the specific resin may contain two or more kinds of repeating units contained in the specific resin among the repeating units of the structure. In that case, it is preferable that the total amount is within the above-described range.

In a case where the specific resin is a polyimide, the total content of the repeating unit represented by Formula (1-1), the repeating unit represented by Formula (1-3), the repeating unit represented by Formula (1-5), and the repeating unit represented by Formula (4) with respect to the total mass of the specific resin is preferably 50% by mass or more, preferably 70% by mass or more, more preferably 80% by mass or more, and particularly preferably 90% by mass or more. The upper limit of the content is not particularly limited, and may be 100% by mass.

In addition, in a case where the specific resin is a polyimide, the total content of the repeating unit represented by Formula (1-1), the repeating unit represented by Formula (1-3-2), the repeating unit represented by Formula (1-5-2), and the repeating unit represented by Formula (4) with respect to the total mass of the specific resin is preferably 50% by mass or more, preferably 70% by mass or more, more preferably 80% by mass or more, and particularly preferably 90% by mass or more. The upper limit of the content is not particularly limited, and may be 100% by mass.

In addition, in a case where the specific resin includes a repeating unit represented by Formula (4), the third specific resin may include two or more kinds of repeating units represented by Formula (4) having different structures. In that case, it is preferable that the total amount is within the above-described range.

In a case where the second specific resin is a polyimide precursor, the content of the repeating unit represented by Formula (1-2) is preferably 30% by mass or more, preferably 50% by mass or more, still more preferably 70% by mass or more, and particularly preferably 80% by mass or more with respect to the total mass of the second specific resin. The upper limit of the content is not particularly limited, and may be 100% by mass.

In a case where the second specific resin is a polyimide precursor, the total content of the repeating unit represented by Formula (1-2), the repeating unit represented by Formula (1-4), and the repeating unit represented by Formula (1-6) with respect to the total mass of the second specific resin is preferably 30% by mass or more, preferably 50% by mass or more, still more preferably 70% by mass or more, and particularly preferably 80% by mass or more. The upper limit of the content is not particularly limited, and may be 100% by mass.

In a case where the second specific resin is a polyimide precursor, the total content of the repeating unit represented by Formula (1-2), the repeating unit represented by Formula (1-4-2), and the repeating unit represented by Formula (1-6-2) with respect to the total mass of the second specific resin is preferably 30% by mass or more, preferably 50% by mass or more, still more preferably 70% by mass or more, and particularly preferably 80% by mass or more. The upper limit of the content is not particularly limited, and may be 100% by mass.

In addition, the specific resin may contain two or more kinds of repeating units contained in the specific resin among the repeating units of the structure. In that case, it is preferable that the total amount is within the above-described range.

In a case where the second specific resin is a polyimide precursor, the total content of the repeating unit represented by Formula (1-2) and the repeating unit represented by Formula (2) is preferably 50% by mass or more, preferably 70% by mass or more, more preferably 80% by mass or more, and particularly preferably 90% by mass or more with respect to the total mass of the second specific resin. The upper limit of the content is not particularly limited, and may be 100% by mass.

In addition, in a case where the first specific resin or the second specific resin includes a repeating unit represented by Formula (2), the first specific resin or the second specific resin may include two or more kinds of repeating units represented by Formula (2) having different structures. In that case, it is preferable that the total amount is within the above-described range.

In a case where the specific resin is polyimide, the weight-average molecular weight (Mw) is preferably 3,000 to 100,000.

The lower limit of the above-described Mw is preferably 5,000 or more, more preferably 8,000 or more, and still more preferably 10,000 or more.

The upper limit of the Mw is preferably 50,000 or less, more preferably 40,000 or less, and still more preferably 25,000 or less.

In a case where the weight-average molecular weight is set to 3,000 or more, it is possible to improve the breakage resistance of the film after curing. In order to obtain an organic film having excellent mechanical properties (for example, breaking elongation), the weight-average molecular weight is particularly preferably 5,000 or more.

The number-average molecular weight (Mn) of the polyimide is preferably 1,000 to 40,000, more preferably 2,000 to 30,000, and still more preferably 5,000 to 20,000.

The dispersity of the molecular weight of the polyimide is preferably 1.5 or more, more preferably 1.8 or more, and still more preferably 2.0 or more. The upper limit value of the dispersity of the molecular weight of the polyimide is not particularly specified, but is, for example, preferably 7.0 or less, more preferably 6.5 or less, still more preferably 6.0 or less, even more preferably 4.5 or less, and particularly preferably 3.0 or less.

In a case where the resin composition contains a plurality of kinds of polyimides as the specific resin, it is preferable that the weight-average molecular weight, the number-average molecular weight, and the dispersity of at least one kind of polyimide are in the above ranges. It is also preferable that the weight-average molecular weight, the number-average molecular weight, and the dispersity, calculated by using the plurality of kinds of polyimides as one resin, are within the above ranges.

In a case where the specific resin is a polyimide precursor, the weight-average molecular weight (Mw) is preferably 5,000 to 100,000, more preferably 10,000 to 50,000, and still more preferably 15,000 to 40,000. The number-average molecular weight (Mn) of the polyimide precursor is preferably 2,000 to 40,000, more preferably 3,000 to 30,000, and still more preferably 4,000 to 20,000.

The dispersity of the molecular weight of the polyimide precursor is preferably 1.5 or more, more preferably 1.8 or more, and still more preferably 2.0 or more. The upper limit value of the dispersity of the molecular weight of the polyimide precursor is not particularly specified, but is, for example, preferably 7.0 or less, more preferably 6.5 or less, still more preferably 6.0 or less, even more preferably 4.5 or less, and particularly preferably 3.0 or less.

In the present specification, the dispersity of the molecular weight is a value obtained by calculating “weight-average molecular weight/number-average molecular weight”.

In a case where the resin composition contains a plurality of kinds of polyimide precursors as the specific resin, it is preferable that the weight-average molecular weight, the number-average molecular weight, and the dispersity of at least one kind of polyimide precursor are in the above ranges. Further, it is also preferable that the weight-average molecular weight, the number-average molecular weight, and the dispersity, calculated by using the plurality of kinds of polyimide precursors as one resin, are within the above ranges.

In a case where the specific resin is polyimide, from the viewpoint of film hardness, insulating properties, and the like of an organic film to be obtained, an imidization rate of the polyimide (also referred to as “ring closure rate”) is preferably 70% or more, more preferably 80% or more, and still more preferably 90% or more. The upper limit of the imidization rate is not particularly limited, and it may be any imidization rate of 100% or less.

In addition, in a case where the specific resin is a polyimide, the content of the imide structure in the specific resin is preferably 3 mmol/g or less and more preferably 2.5 mmol/g or less. The lower limit of the above-described content is not particularly limited, but can be, for example, 0.5 mmol/g or more.

In a case where the specific resin is a polyimide precursor, from the viewpoint of film hardness, insulating properties, and the like of an organic film to be obtained, an imidization rate of the polyimide precursor (also referred to as “ring closure rate”) is preferably less than 70%, more preferably 50% or less, still more preferably 20% or less, and particularly preferably 10% or less. The lower limit of the imidization rate is not particularly limited, and it may be any imidization rate of 0% or more.

The imidization rate is measured by, for example, the following method.

The infrared absorption spectrum of the specific resin is measured, and a peak intensity P1 in the vicinity of 1,377 cm⁻¹, which is the absorption peak derived from the imide structure, is obtained. Next, the specific resin is subjected to a heat treatment at 350° C. for 1 hour, and then the infrared absorption spectrum is measured again to obtain a peak intensity P2 in the vicinity of 1,377 cm⁻¹. Using the obtained peak intensities P1 and P2, the imidization rate of the specific resin can be determined based on the following expression.

Imidization rate (%)=(peak intensity P1/peak intensity P2)×100

### [Method for Producing Specific Resin]

The specific resin can be obtained by, for example, a method of reacting a tetracarboxylic acid dianhydride with a diamine at a low temperature, a method of reacting a tetracarboxylic acid dianhydride with a diamine at a low temperature to obtain a polyamic acid and subjecting the polyamic acid to esterification by using a condensing agent or an alkylating agent, a method of obtaining a diester with a tetracarboxylic acid dianhydride and alcohol and then reacting the diester with a diamine in the presence of a condensing agent, and a method of obtaining a diester with a tetracarboxylic acid dianhydride and alcohol, subsequently subjecting the rest dicarboxylic acid to acid-halogenation using a halogenating agent, and carrying out reaction with a diamine. Among the above production methods, a method of obtaining a diester with a tetracarboxylic acid dianhydride and alcohol, subsequently subjecting the rest dicarboxylic acid to acid-halogenation using a halogenating agent, and carrying out a reaction with a diamine is more preferable.

Examples of the condensing agent include dicyclohexylcarbodiimide, diisopropylcarbodiimide, 1-ethoxycarbonyl-2-ethoxy-1,2-dihydroquinoline, 1,1-carbonyldioxy-di-1,2,3-benzotriazole, N,N′-disuccinimidyl carbonate, and trifluoroacetic anhydride.

Examples of the alkylating agent include N,N-dimethylformamide dimethyl acetal, N,N-dimethylformamide diethyl acetal, N,N-dialkylformamide dialkyl acetal, trimethyl orthoformate, triethyl orthoformate.

Examples of the halogenating agent include thionyl chloride, oxalyl chloride, and phosphorus oxychloride.

In addition, in a case where a polyimide is desired to be obtained as the specific resin, the polyimide can be synthesized by a method of completely imidizing the resin obtained by the above method using a known imidization reaction method, a method of introducing a partial imide structure by stopping the imidization reaction in the middle of the reaction, or a method of introducing a partial imide structure by blending a completely imidized polymer and a polyimide precursor thereof. In addition, another known method for synthesizing polyimide can also be applied.

In the method for producing the specific resin, it is preferable to use an organic solvent at the time of reaction. One kind of organic solvent may be used, or two or more kinds thereof may be used.

The organic solvent can be appropriately determined depending on the raw material; however, examples thereof include pyridine, diethylene glycol dimethyl ether (diglyme), N-methylpyrrolidone, N-ethylpyrrolidone, ethyl propionate, dimethylacetamide, dimethylformamide, tetrahydrofuran, and γ-butyrolactone.

In the method for producing the specific resin, it is preferable to add a basic compound in a case of carrying out the reaction. One kind of basic compound may be used, or two or more kinds thereof may be used.

The basic compound can be appropriately determined depending on the raw material; however, examples thereof include triethylamine, diisopropylethylamine, pyridine, 1,8-diazabicyclo[5.4.0]undec-7-ene, and N,N-dimethyl-4-aminopyridine.

### —Terminal Blocking Agent—

In the method for producing the specific resin, in order to further improve the storage stability, it is preferable to seal a carboxylic acid anhydride, an acid anhydride derivative, or an amino group, which remains at the resin terminal of the specific resin. In a case of blocking the carboxylic acid anhydride and the acid anhydride derivative, remaining at the resin terminal, examples of the terminal blocking agent include a monoalcohol, phenol, thiol, thiophenol, and a monoamine. It is more preferable to use a monoalcohol, phenols, or a monoamine from the viewpoint of reactivity and film stability. Examples of the preferred monoalcohol compound include primary alcohol such as methanol, ethanol, propanol, butanol, hexanol, octanol, dodecanol, benzyl alcohol, 2-phenylethanol, 2-methoxyethanol, 2-chloromethanol, and furfuryl alcohol; secondary alcohol such as isopropanol, 2-butanol, cyclohexyl alcohol, cyclopentanol, and 1-methoxy-2-propanol; and tertiary alcohol such as t-butyl alcohol and adamantane alcohol. Examples of the preferred compounds of phenols include phenols such as phenol, methoxyphenol, methylphenol, naphthalene-1-ol, naphthalene-2-ol, and hydroxystyrene. In addition, examples of the preferred monoamine compound include aniline, 2-ethynyl aniline, 3-ethynyl aniline, 4-ethynyl aniline, 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 2-aminobenzenesulfonic acid, 3-aminobenzenesulfonic acid, 4-aminobenzenesulfonic acid, 3-amino-4,6-dihydroxypyrimidine, 2-aminophenol, 3-aminophenol, 4-aminophenol, 2-aminothiophenol, 3-aminothiophenol, and 4-aminothiophenol. Two or more of these may be used, and a plurality of different terminal groups may be introduced by reacting a plurality of terminal blocking agents.

In addition, in a case of blocking the amino group at the terminal of the resin, it is possible to carry out blocking with a compound having a functional group capable of reacting with the amino group. The preferred terminal blocking agent for the amino group is preferably a carboxylic acid anhydride, a carboxylic acid chloride, a carboxylic acid bromide, a sulfonic acid chloride, sulfonic acid anhydride, a sulfonic acid carboxylic acid anhydride, or the like and more preferably a carboxylic acid anhydride or a carboxylic acid chloride. Examples of the preferred carboxylic acid anhydride compound include acetic anhydride, propionic anhydride, oxalic anhydride, succinic anhydride, maleic acid anhydride, phthalic anhydride, benzoic anhydride, and 5-norbornene-2,3-dicarboxylic acid anhydride. Examples of the preferred carboxylic acid chloride compound include acetyl chloride, acrylic acid chloride, propionyl chloride, methacrylic acid chloride, pivaloyl chloride, cyclohexanecarbonyl chloride, 2-ethylhexanoyl chloride, cinnamoyl chloride, 1-adamantanecarbonyl chloride, heptafluorobutyryl chloride, stearic acid chloride, and benzoyl chloride.

Furthermore, an amino acid in a compound having an amino group such as p-aminophenol and a hydroxy group may be reacted with the hydroxy group and a compound that reacts with the hydroxy group, such as 4-(chloromethyl)styrene, after the amino acid is reacted with the terminal of the resin. By such a reaction, a polymerizable group can be introduced at the terminal.

### —Solid Precipitation—

In the production method for a specific resin, a step of precipitating a solid may be included. Specifically, it is possible to obtain a specific resin by filtering out a water-absorbing by-product of the dehydration condensing agent that is present together in the reaction solution as necessary, subsequently putting the obtained polymer component in a poor solvent such as water, an aliphatic lower alcohol, or a mixed solution thereof, precipitating the polymer component to be precipitated as a solid, and then carrying out drying. In order to improve the degree of purification, operations such as redissolution, reprecipitation, and drying of the specific resin may be repeated. Further, a step of removing ionic impurities using an ion exchange resin may be included.

### Specific Example

Specific examples of the specific resin include polyimides (PI-1) to (PI-12), (PA-1), polyimide precursors (SP-1) to (SP-2), (SP-4) to (SP-6), and the like in Examples described later, but the present invention is not limited thereto.

### [Content]

The content of the specific resin in the resin composition according to the embodiment of the present invention is preferably 20% by mass or more, more preferably 30% by mass or more, still more preferably 40% by mass or more, even still more preferably 50% by mass or more, and most preferably 60% by mass or more, with respect to the total solid content of the resin composition. In addition, the content of the resin in the resin composition according to the embodiment of the present invention is preferably 99.5% by mass or less, more preferably 99% by mass or less, still more preferably 98% by mass or less, still more preferably 97% by mass or less, and even still more preferably 95% by mass or less, with respect to the total solid content of the resin composition.

The resin composition according to the embodiment of the present invention may contain only one kind of specific resin or may contain two or more kinds thereof. In a case where two or more kinds thereof are contained, the total amount thereof is preferably within the above range.

It is also preferable that the resin composition according to the embodiment of the present invention contains at least two kinds of resins.

Specifically, the resin composition according to the embodiment of the present invention may contain in total two or more kinds of the specific resins and other resins described later or may contain two or more kinds of the specific resins; however, it is preferable to include two or more kinds of the specific resins.

In a case where the resin composition according to the embodiment of the present invention contains two or more kinds of the specific resins, it is preferable to contain, for example, two or more kinds of polyimide precursors which are polyimide precursors in which the structure derived from the dianhydride is different.

### <Another Resin>

The resin composition according to the embodiment of the present invention may contain the above-described specific resin and another resin (hereinafter, also simply referred to as “the other resin”) that is different from the specific resin.

Examples of the other resins include resins different from the specific resin and corresponding to polyimide precursors, polyimides, polybenzoxazole precursors, polybenzoxazole, polyamideimide precursors, polyamideimide, aromatic polyether, phenol resin, polyamide, epoxy resin, polysiloxane, resin including a siloxane structure, (meth)acrylic resin, (meth)acrylamide resin, urethane resin, butyral resin, styryl resin, polyether resin, and polyester resin.

Examples of the other polyimide precursors, the other polyimides, the polybenzoxazole precursors, the polybenzoxazoles, the polyamideimide precursors, and the polyamideimides include the compounds described in paragraphs 0017 to 0138 of WO2022/145355A. The above description is incorporated in the present specification.

The aromatic polyether is not particularly limited, but is preferably a polyphenylene ether.

The polyphenylene ether preferably includes a repeating unit represented by Formula (PE).

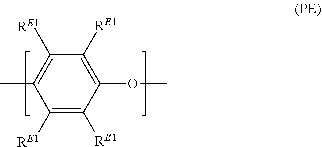

In Formula (PE), R^{E1} represents a hydrogen atom or a substituent. Examples of the substituent include a halogen atom, an alkyl group which may have a substituent, an alkoxy group which may have a substituent, an amino group which may have a substituent, a nitro group, and a carboxy group.

In addition, the polyphenylene ether is also preferably a compound having a polymerizable group.

As the polymerizable group, an epoxy group, an oxetanyl group, an oxazolyl group, a methylol group, an alkoxymethyl group, an acyloxymethyl group, a blocked isocyanate group, or a group having an ethylenically unsaturated bond is preferable, and a group having an ethylenically unsaturated bond is more preferable.

Examples of the group having an ethylenically unsaturated bond include a vinyl group, an allyl group, an isoallyl group, a 2-methylallyl group, a group (for example, a vinylphenyl group) having an aromatic ring that is directly bonded to a vinyl group, and a (meth)acrylamide group, a (meth)acryloyloxy group, where a vinylphenyl group, a (meth)acrylamide group, or a (meth)acryloyloxy group is preferable, a vinylphenyl group or a (meth)acryloyloxy group is more preferable, and a (meth)acryloyloxy group is still more preferable.

In a case where the polyphenylene ether is a compound having a polymerizable group, the position of the polymerizable group is not particularly limited, but for example, a structure in which the polymerizable group is introduced at the terminal of the main chain is preferable.

The polyphenylene ether may include other repeating units. However, the content of the other repeating units is preferably 30% by mass or less, more preferably 20% by mass or less, and still more preferably 10% by mass or less with respect to the total mass of the polyphenylene ether.

The number-average molecular weight of the polyphenylene ether is not particularly limited, but is preferably 500 to 50,000.

The lower limit of the number-average molecular weight is preferably 800 or higher, more preferably 1000 or higher, and still more preferably 1500 or higher.

The upper limit of the number-average molecular weight is preferably 30,000 or less, more preferably 20,000 or less, and still more preferably 10,000 or less.

Specific examples of the polyphenylene ether (PPE) include poly(2,6-dimethyl-1,4-phenylene ether), poly(2-methyl-6-ethyl-1,4-phenylene ether), poly(2-methyl-6-phenyl-1,4-phenylene ether), poly(2,6-dichloro-1,4-phenylene ether), a copolymer of 2,6-dimethylphenol and other phenols (for example, 2,3,6-trimethylphenol, 2-methyl-6-butylphenol, and the like), a polyphenylene ether copolymer obtained by coupling 2,6-dimethylphenol with biphenols or bisphenols, and a polyphenylene ether having a linear structure or a branched structure, which is obtained by heating poly(2,6-dimethyl-1,4-phenylene ether) and the like with phenolic compounds such as bisphenols or trisphenols in a toluene solvent in the presence of an organic peroxide and performing a redistribution reaction, but the present invention is not limited thereto.

In a case where the resin composition according to the embodiment of the present invention contains the other resin, the content of the other resin is preferably 0.01% by mass or more, more preferably 0.05% by mass or more, still more preferably 1% by mass or more, even still more preferably 2% by mass or more, even still more preferably 5% by mass or more, and even further still more preferably 10% by mass or more, with respect to the total solid content of the resin composition.

The content of the other resin in the resin composition according to the embodiment of the present invention is preferably 80% by mass or less, more preferably 75% by mass or less, still more preferably 70% by mass or less, even still more preferably 60% by mass or less, and even further still more preferably 50% by mass or less, with respect to the total solid content of the resin composition.

As one preferred aspect of the resin composition according to the embodiment of the present invention, an aspect in which the content of the other resin is a low content can be adopted. In the above aspect, the content of the other resin is preferably 20% by mass or less, more preferably 15% by mass or less, still more preferably 10% by mass or less, even still more preferably 5% by mass or less, and even further still more preferably 1% by mass or less, with respect to the total solid content of the resin composition. The lower limit of the content is not particularly limited, and it may be any content of 0% by mass or more.

In addition, in a case where the resin composition according to the embodiment of the present invention contains another resin, the content of the specific resin with respect to the total content of the specific resin and the other resin is preferably 40% to 90% by mass, more preferably 50% to 80% by mass, and still more preferably 55% to 70% by mass. The resin composition according to the embodiment of the present invention may contain only one kind of the other resin or may contain two or more kinds thereof. In a case where two or more kinds thereof are contained, the total amount thereof is preferably within the above range.

### <Polymerizable Compound>

The resin composition according to the embodiment of the present invention preferably contains a polymerizable compound.

In addition, the resin composition according to the embodiment of the present invention preferably contains a photopolymerization initiator as a photosensitizing agent and contains a polymerizable compound.

The melting point of the polymerizable compound is preferably 25° C. or lower. By setting the melting point to 25° C. or lower, the coating film is likely to flow during drying and heating, and the flatness of the cured substance can be improved.

In particular, from the viewpoint of reducing the dielectric constant of the cured substance, it is preferable that the polymerizable compound includes a compound having a C log P value of 3.0 or more, and it is more preferable that the polymerizable compound includes a compound having a C log P value of 3.0 or more and having an aromatic ring structure or an aliphatic ring structure with 6 or more carbon atoms.

In the present specification, the C log P value of a compound is defined as follows. The octanol-water partition coefficient (log P value) can be measured generally by a flask immersion method described in JIS Japanese Industrial Standard Z7260-107 (2000). In addition, the octanol-water partition coefficient (log P value) can also be estimated by a computational chemistry method or an empirical method instead of measurement. As a calculation method, a Crippen's fragmentation method (J. Chem. Inf. Comput. Sci., 27, 21 (1987)), a Viswanadhan's fragmentation method (J. Chem. Inf. Comput. Sci., 29, 163 (1989)), a Broto's fragmentation method (Eur. J. Med. Chem. -Chim. Theor., 19, 71 (1984)), and the like are known to be used. In the present invention, a Crippen's fragmentation method (J. Chem. Inf. Comput. Sci., 27, 21 (1987)) is used.

The C log P value is a value obtained by calculating the common logarithm log P of the 1-octanol/water partition coefficient P A known method or software can be used for calculating the C log P value, but unless otherwise specified, in the present invention, a C log P program incorporated in the system: PCModels of Daylight Chemical Information Systems, Inc. is used.

The C log P value is preferably 4.0 or more and more preferably 6.0 or more.

In addition, the upper limit of the C log P value is not particularly limited, but is preferably 15.0 or less.

The above-described aromatic ring structure may be an aromatic hydrocarbon ring or an aromatic heterocyclic ring, but is preferably an aromatic hydrocarbon ring, and more preferably includes a benzene ring. In addition, from the viewpoint of reducing the dielectric constant of the cured substance, a fused ring such as a fluorene ring is preferable.

As the aliphatic ring structure with 6 or more carbon atoms, an aliphatic ring structure with 6 to 30 carbon atoms is preferable, and an aliphatic ring structure with 6 to 20 carbon atoms is more preferable.

Examples of the aliphatic ring structure with 6 or more carbon atoms include a monocyclic ring such as a cyclohexane ring, and a polycyclic ring such as a dicyclopentane ring and a tricyclo[5.2.1.0^{2,6}]decane ring, and a polycyclic ring is preferable.

The polymerizable compound having a C log P value of 3.0 or more (particularly, a compound having a C log P value of 3.0 or more and having an aromatic ring structure or an aliphatic ring structure with 6 or more carbon atoms) is preferably a compound containing a group having an ethylenically unsaturated bond, and more preferably a compound containing two or more groups having an ethylenically unsaturated bond. In addition, the compound is also preferably a compound having two groups having an ethylenically unsaturated bond.

In addition, the polymerizable compound having a C log P value of 3.0 or more (particularly, a compound having a C log P value of 3.0 or more and having an aromatic ring structure or an aliphatic ring structure with 6 or more carbon atoms) is preferably a compound corresponding to a radical crosslinking agent described later.

Specific examples of the polymerizable compound having a C log P value of 3.0 or more include the following compounds, but the polymerizable compound is not limited thereto.

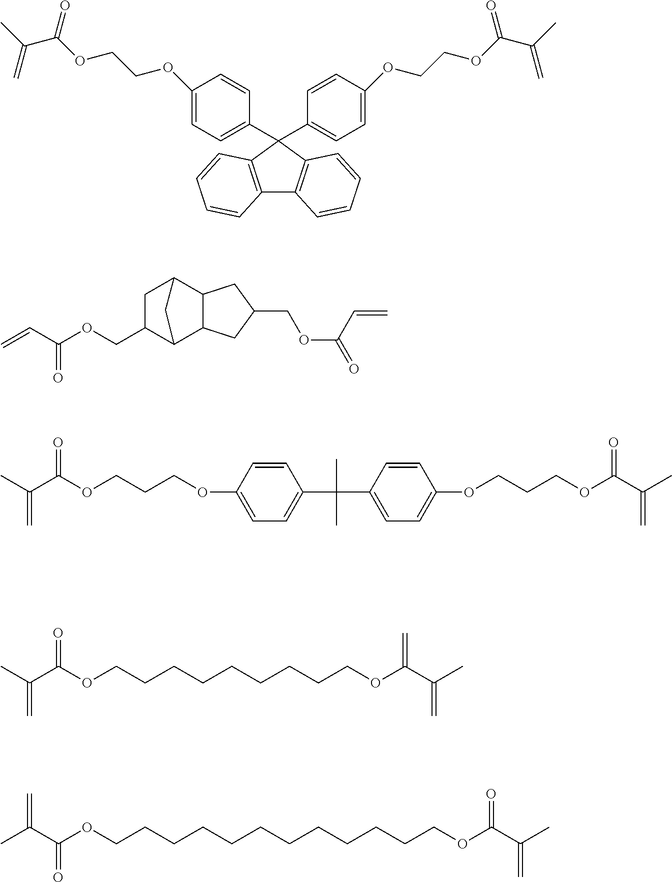

Examples of the polymerizable compound include a radical crosslinking agent and another crosslinking agent.

### [Radical Crosslinking Agent]

The resin composition according to the embodiment of the present invention preferably contains a radical crosslinking agent.

The radical crosslinking agent is a compound having a radically polymerizable group. The radically polymerizable group is preferably a group containing an ethylenically unsaturated bond. Examples of the group containing an ethylenically unsaturated bond include a vinyl group, an allyl group, a vinylphenyl group, a (meth)acryloyl group, a maleimide group, and a (meth)acrylamide group.

Among these, a (meth)acryloyl group, a (meth)acrylamide group, or a vinylphenyl group is preferable, and from the viewpoint of reactivity, a (meth)acryloyl group is more preferable.

The radical crosslinking agent is preferably a compound having one or more ethylenically unsaturated bonds; however, a compound having two or more ethylenically unsaturated bonds is more preferable. The radical crosslinking agent may have three or more ethylenically unsaturated bonds.

The compound having 2 or more ethylenically unsaturated bonds is preferably a compound having 2 to 15 ethylenically unsaturated bonds, more preferably a compound having 2 to 10 ethylenically unsaturated bonds, and still more preferably a compound having 2 to 6 ethylenically unsaturated bonds.

From the viewpoint of the film hardness of the pattern (cured substance) to be obtained, the resin composition according to the embodiment of the present invention preferably contains a compound having two ethylenically unsaturated bonds and a compound having three or more ethylenically unsaturated bonds.

The molecular weight of the radical crosslinking agent is preferably 2,000 or less, more preferably 1,500 or less, and still more preferably 900 or less. The lower limit of the molecular weight of the radical crosslinking agent is preferably 100 or more.

Specific examples of the radical crosslinking agent include unsaturated carboxylic acids (for example, acrylic acid, methacrylic acid, itaconic acid, crotonic acid, isocrotonic acid, and maleic acid), and esters and amides thereof, where esters between unsaturated carboxylic acids and polyhydric alcohol compounds or amides between unsaturated carboxylic acids and polyvalent amine compounds are preferable. In addition, addition reaction products produced by reacting unsaturated carboxylic acid esters or amides, having a nucleophilic substituent such as a hydroxy group, an amino group, or a sulfanyl group, with monofunctional or polyfunctional isocyanates or epoxies, dehydration condensation reaction products produced by reacting the above esters or amides with a monofunctional or polyfunctional carboxylic acid, or the like are also suitably used. In addition, an addition reaction product produced by reacting unsaturated carboxylic acid esters or amides, having an electrophilic substituent such as an isocyanate group or an epoxy group, with monofunctional or polyfunctional alcohols, amines, or thiols, and further, a substitution reaction product produced by reacting unsaturated carboxylic acid esters or amides, having an eliminable substituent such as a halogeno group or a tosyloxy group, with monofunctional or polyfunctional alcohols, amines, or thiols is also suitable. In addition, as other examples, it is also possible to use a group of compounds in which the unsaturated carboxylic acid described above is replaced with an unsaturated phosphonic acid, a vinylbenzene derivative such as styrene, a vinyl ether, an allyl ether, or the like. Regarding the specific examples thereof, reference can be made to the description of paragraphs 0113 to 0122 of JP2016-027357A, the content of which is incorporated in the present specification.

The radical crosslinking agent is also preferably a compound having a boiling point of 100° C. or higher under normal pressure. Examples of the compound having a boiling point of 100° C. or higher under normal pressure include the compounds described in paragraph 0203 of WO2021/112189A. The content thereof is incorporated in the present specification.

Examples of the preferred radical crosslinking agent other than those described above include the radically polymerizable compounds described in paragraphs 0204 to 0208 of WO2021/112189A. The content thereof is incorporated in the present specification.

As the radical crosslinking agent, dipentaerythritol triacrylate (as a commercially available product, KAYARAD D-330 (manufactured by Nippon Kayaku Co., Ltd.), dipentaerythritol tetraacrylate (as a commercially available product, KAYARAD D-320 (manufactured by Nippon Kayaku Co., Ltd.), A-TMMT (manufactured by Shin-Nakamura Chemical Co., Ltd.), dipentaerythritol penta(meth)acrylate (as a commercially available product, KAYARAD D-310 (manufactured by Nippon Kayaku Co., Ltd.), dipentaerythritol hexa(meth)acrylate (as a commercially available product, KAYARAD DPHA (manufactured by Nippon Kayaku Co., Ltd.), A-DPH (manufactured by Shin-Nakamura Chemical Co., Ltd.), or a structure in which a (meth)acryloyl group thereof is bonded through an ethylene glycol residue or a propylene glycol residue is preferable. Oligomer types thereof can also be used.

Examples of the commercially available product of the radical crosslinking agent include SR-494 which is a tetrafunctional acrylate having four ethyleneoxy chains, SR-209, 231, and 239 which are a difunctional methacrylate having four ethyleneoxy chains (all of which are manufactured by Sartomer Company Inc.), DPCA-60 which is a hexafunctional acrylate having six pentyleneoxy chains and TPA-330 which is a trifunctional acrylate having three isobutylene oxy chains (all of which are manufactured by Nippon Kayaku Co., Ltd.), UAS-10 and UAB-140 which are a urethane oligomer (all of which are manufactured by Nippon Paper Industries Co., Ltd.), NK Ester M-40G, NK Ester 4G, NK Ester M-9300, NK Ester A-9300, and UA-7200 (all of which are manufactured by Shin-Nakamura Chemical Co., Ltd.), DPHA-40H (manufactured by Nippon Kayaku Co., Ltd.), UA-306H, UA-306T, UA-306I, AH-600, T-600, and AI-600 (all of which are manufactured by KYOEISHA CHEMICAL Co., Ltd.), and Brenmer PME400 (manufactured by NOF Corporation).

As the radical crosslinking agent, the urethane acrylates as described in JP1973-041708B (JP-S48-041708B), JP1976-037193A (JP-S51-037193A), JP1990-032293B (JP-H02-032293B), and JP1990-016765B (JP-H02-016765B), and the urethane compounds having an ethylene oxide-based skeleton described in JP1983-049860B (JP-S58-049860B), JP1981-017654B (JP-S56-017654B), JP1987-039417B (JP-S62-039417B), and JP1987-039418B (JP-S62-039418B) are also suitable. As the radical crosslinking agent, the compounds having an amino structure or a sulfide structure in the molecule as described in JP1988-277653A (JP-S63-277653A), JP1988-260909A (JP-S63-260909A), and JP1989-105238A (JP-H01-105238A) can also be used.

The radical crosslinking agent may be a radical crosslinking agent having an acid group such as a carboxy group or a phosphoric acid group. The radical crosslinking agent having an acid group is preferably an ester between an aliphatic polyhydroxy compound and an unsaturated carboxylic acid and more preferably a radical crosslinking agent obtained by reacting an unreacted hydroxy group of an aliphatic polyhydroxy compound with a non-aromatic carboxylic acid anhydride to have an acid group. The radical crosslinking agent is particularly preferably a compound in which an aliphatic polyhydroxy compound is pentaerythritol or dipentaerythritol in a radical crosslinking agent having an acid group obtained by reacting an unreacted hydroxy group of the aliphatic polyhydroxy compound with a non-aromatic carboxylic acid anhydride. Examples of the commercially available product thereof include M-510 and M-520 as polybasic acid-modified acrylic oligomers which are manufactured by Toagosei Co., Ltd.

An acid value of the radical crosslinking agent having an acid group is preferably 0.1 to 300 mgKOH/g and more preferably 1 to 100 mgKOH/g. In a case where the acid value of the radical crosslinking agent is within the above-described range, excellent manufacturing handleability is exhibited, and excellent developability is exhibited. In addition, good polymerization properties are exhibited. The acid value is measured in accordance with the description of JIS K 0070: 1992.

In the resin composition, it is preferable to use difunctional methacrylate or acrylate from the viewpoint of pattern resolution and film elasticity.

As the specific compound, the following compound can be used; triethylene glycol diacrylate, triethylene glycol dimethacrylate, tetraethylene glycol dimethacrylate, tetraethylene glycol diacrylate, polyethylene glycol (PEG) 200 diacrylate, PEG 200 dimethacrylate, PEG 600 diacrylate, PEG 600 dimethacrylate, polytetraethylene glycol diacrylate, polytetraethylene glycol dimethacrylate, dipropylene glycol diacrylate, tripropylene glycol diacrylate, neopentyl glycol diacrylate, neopentyl glycol dimethacrylate, 3-methyl-1, 5-pentanediol diacrylate, 1,6-hexanediol diacrylate, 1,6-hexanediol dimethacrylate, dimethylol-tricyclodecanediacrylate, dimethylol-tricyclodecanedimethacrylate, a diacrylate of an ethylene oxide (EO) adduct of bisphenol A, a dimethacrylate of an EO adduct of bisphenol A, a diacrylate of a propylene oxide (PO) adduct of bisphenol A, a dimethacrylate of a PO adduct of bisphenol A, 2-hydroxy-3-acryloyloxypropyl methacrylate, isocyanuric acid EO-modified diacrylate, isocyanuric acid EO-modified dimethacrylate, another difunctional acrylate having a urethane bond, and difunctional methacrylate having a urethane bond. As necessary, two or more of these can be mixedly used.

It is noted that, for example, the PEG 200 diacrylate refers to a polyethylene glycol diacrylate having a polyethylene glycol chain Formula weight of about 200.

In the photocurable resin composition according to the embodiment of the present invention, a monofunctional radical crosslinking agent can be preferably used as the radical crosslinking agent from the viewpoint of suppressing the warping of the pattern (cured substance). As the monofunctional radical crosslinking agent, (meth)acrylic acid derivatives such as n-butyl (meth)acrylate, 2-ethylhexyl (meth)acrylate, 2-hydroxyethyl (meth)acrylate; butoxyethyl (meth)acrylate, carbitol (meth)acrylate, cyclohexyl (meth)acrylate, benzyl (meth)acrylate, phenoxyethyl (meth)acrylate, N-methylol (meth)acrylamide, glycidyl (meth)acrylate, polyethylene glycol mono(meth)acrylate, and polypropylene glycol mono(meth)acrylate, N-vinyl compounds such as N-vinylpyrrolidone and N-vinylcaprolactam, allyl glycidyl ethers, and the like are preferably used. As the monofunctional radical crosslinking agent, a compound having a boiling point of 100° C. or higher under normal pressure is also preferable in order to suppress volatilization before exposure.

In addition, examples of the bi- or higher functional radical crosslinking agent include allyl compounds such as diallyl phthalate and triallyl trimellitate.

In a case where a radical crosslinking agent is contained, the content of the radical crosslinking agent is preferably more than 0% by mass and 60% by mass or less with respect to the total solid content of the resin composition. The lower limit is more preferably 5% by mass or more and still more preferably 10% by mass or more. The upper limit thereof is more preferably 50% by mass or less and still more preferably 30% by mass or less.

One kind of radical crosslinking agent may be used alone, or two or more kinds thereof may be mixedly used. In a case where two or more kinds thereof are used in combination, the total amount thereof is preferably in the above range.

### [Another Crosslinking Agent]

The resin composition according to the embodiment of the present invention also preferably contains another crosslinking agent different from the radical crosslinking agent described above.

The other crosslinking agent refers to a crosslinking agent other than the above-described radical crosslinking agent, where it is preferably a compound having a plurality of groups, in the molecule, which accelerates a reaction of forming a covalent bond between other compounds in the composition or reaction products thereof, by the photosensitization of the above-described photoacid generator or photobase generator, and more preferably a compound having a plurality of groups, in the molecule, which accelerates a reaction of forming a covalent bond between other compounds in the composition or reaction products thereof, by the action of the acid or the base.

The acid or the base is preferably an acid or a base, which is generated from a photoacid generator or a photobase generator in the exposure step.

Examples of the other crosslinking agent include the compounds described in paragraphs 0179 to 0207 of WO2022/145355A. The above description is incorporated in the present specification.

In a case where the polymerizable compound is contained, the content of the polymerizable compound is preferably more than 0% by mass and 60% by mass or less with respect to the total solid content of the resin composition. The lower limit is more preferably 5% by mass or more and still more preferably 10% by mass or more. The upper limit thereof is more preferably 50% by mass or less and still more preferably 30% by mass or less.

One kind of the polymerizable compound may be used alone, or two or more kinds thereof may be mixed and used. In a case where two or more kinds thereof are used in combination, the total amount thereof is preferably in the above range.

The resin composition according to the embodiment of the present invention contains a photosensitizing agent.

Examples of the photosensitizing agent include a photopolymerization initiator and a photoacid generator, where a photopolymerization initiator is preferable.

### [Photopolymerization Initiator]

The resin composition according to the embodiment of the present invention preferably includes a photopolymerization initiator.

The photopolymerization initiator is preferably a photoradical polymerization initiator. The photoradical polymerization initiator is not particularly limited and can be appropriately selected from publicly known photoradical polymerization initiators. For example, a photoradical polymerization initiator having photosensitivity to rays ranging from the ultraviolet ray range to the visible light range is preferable. In addition, it may be an activator that acts with a sensitizing agent to generate an active radical.

The photoradical polymerization initiator preferably contains at least one compound having a molar absorption coefficient of at least about 50 L-mol-1 cm⁻¹ within a range of a wavelength of about 240 to 800 nm (preferably 330 to 500 nm). The molar absorption coefficient of a compound can be measured using a well-publicly known method. For example, it is preferable to carry out a measurement at a concentration of 0.01 g/L using an ethyl acetate solvent with an ultraviolet-visible spectrophotometer (Cary-5 spectrophotometer manufactured by Varian Medical Systems, Inc.).

As a photoradical polymerization initiator, well-known compounds can be optionally used. Examples thereof include a halogenated hydrocarbon derivative (for example, a compound having a triazine skeleton, a compound having an oxadiazole skeleton, or a compound having a trihalomethyl group), an acylphosphine compound such as an acylphosphine oxide, hexaarylbiimidazole, an oxime compound such as an oxime derivative, an organic peroxide, a thio compound, a ketone compound, an aromatic onium salt, a keto oxime ether, an α-amino ketone compound such as aminoacetophenone, an α-hydroxy ketone compound such as hydroxyacetophenone, an azo-based compound, an azide compound, a metallocene compound, an organic boron compound, and an iron arene complex. With regard to details thereof, reference can be made to the description of paragraphs 0165 to 0182 of JP2016-027357A and paragraphs 0138 to 0151 of WO2015/199219A, the contents of which are incorporated in the present specification. In addition, examples thereof include the compounds described in paragraphs 0065 to 0111 of JP2014-130173A and JP6301489B, the peroxide-based photopolymerization initiator described in MATERIAL STAGE 37 to 60 p, vol. 19, No. 3, 2019, the photopolymerization initiator described in WO2018/221177A, the photopolymerization initiator described in WO2018/110179A, the photopolymerization initiator described in JP2019-043864A, the photopolymerization initiator described in JP2019-044030A, and the peroxide-based initiator described in JP2019-167313A, the contents of which are incorporated in the present specification.

Examples of the ketone compound include compounds described in paragraph 0087 of JP2015-087611A, the content of which is incorporated in the present specification. As a commercially available product thereof, KAYACURE DETX-S (manufactured by Nippon Kayaku Co., Ltd.) is also suitably used.

In one embodiment of the present invention, a hydroxyacetophenone compound, an aminoacetophenone compound, and an acylphosphine compound can be suitably used as the photoradical polymerization initiator. More specifically, for example, the aminoacetophenone-based initiator described in JP1998-291969A (JP-H10-291969A) and the acylphosphine oxide-based initiator described in JP4225898B can be used, the contents of which are incorporated in the present specification.

As the α-hydroxy ketone-based initiator, Omnirad 184, Omnirad 1173, Omnirad 2959, Omnirad 127 (all of which are manufactured by IGM Resins B.V.), IRGACURE 184 (IRGACURE is a registered trademark), DAROCUR 1173, IRGACURE 500, IRGACURE-2959, and IRGACURE 127 (all of which are manufactured by BASF SE) can be used.

As the α-amino ketone-based initiator, Omnirad 907, Omnirad 369, Omnirad 369E, Omnirad 379EG (all of which are manufactured by IGM Resins B.V.), IRGACURE 907, IRGACURE 369, and IRGACURE 379 (all of which are manufactured by BASF SE) can be used.

As the aminoacetophenone-based initiator, the acylphosphine oxide-based initiator, and the metallocene compound, it is also possible to suitably use, for example, the compounds described in paragraphs 0161 to 0163 of WO2021/112189A. The content thereof is incorporated in the present specification.

Examples of the more preferred photoradical polymerization initiator include an oxime compound. In a case where an oxime compound is used, exposure latitude can be more effectively improved. The oxime compound is particularly preferable since the oxime compound has a wide exposure latitude (a wide exposure margin) and also works as a photocuring accelerator.

Specific examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A, the content of which is incorporated in the present specification.

Examples of the preferred oxime compound include compounds having the following structures, 3-(benzoyloxy(imino))butan-2-one, 3-(acetoxy(imino))butan-2-one, 3-(propionyloxy(imino))butan-2-one, 2-(acetoxy(imino))pentan-3-one, 2-(acetoxy(imino))-1-phenylpropan-1-one, 2-(benzoyloxy(imino))-1-phenylpropan-1-one, 3-((4-toluenesulfonyloxy)imino)butan-2-one, and 2-(ethoxycarbonyloxy(imino))-1-phenylpropan-1-one. In the resin composition, it is preferable to use an oxime compound, particularly as a photoradical polymerization initiator. The oxime compound as a photoradical polymerization initiator has a linking group of >C═N—O—C(═O)—in the molecule.

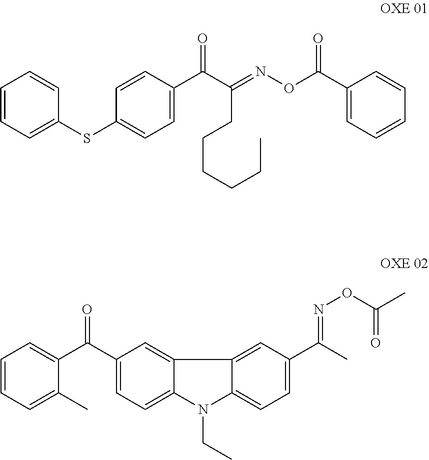 [SMILES: CCCCCC/C(=N\OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21]

Examples of the commercially available product of the oxime compound include IRGACURE OXE 01, IRGACURE OXE 02, IRGACURE OXE 03, and IRGACURE OXE 04 (all of which are manufactured by BASF SE), ADEKA OPTOMER N-1919 (manufactured by ADEKA Corporation, the photoradical polymerization initiator 2 described in JP2012-014052A), TR-PBG-304 and TR-PBG-305 (all of which are manufactured by Changzhou Tronly New Electronic Materials Co., Ltd.), ADEKA ARKLS NCI-730, NCI-831, and ADEKA ARKLS NCI-930 (all of which are manufactured by ADEKA Corporation), DFI-091 (manufactured by DAITO CHEMIX Co., Ltd.), and SpeedCure PDO (manufactured by SARTOMER ARKEMA). In addition, oxime compounds having the following structures can also be used.

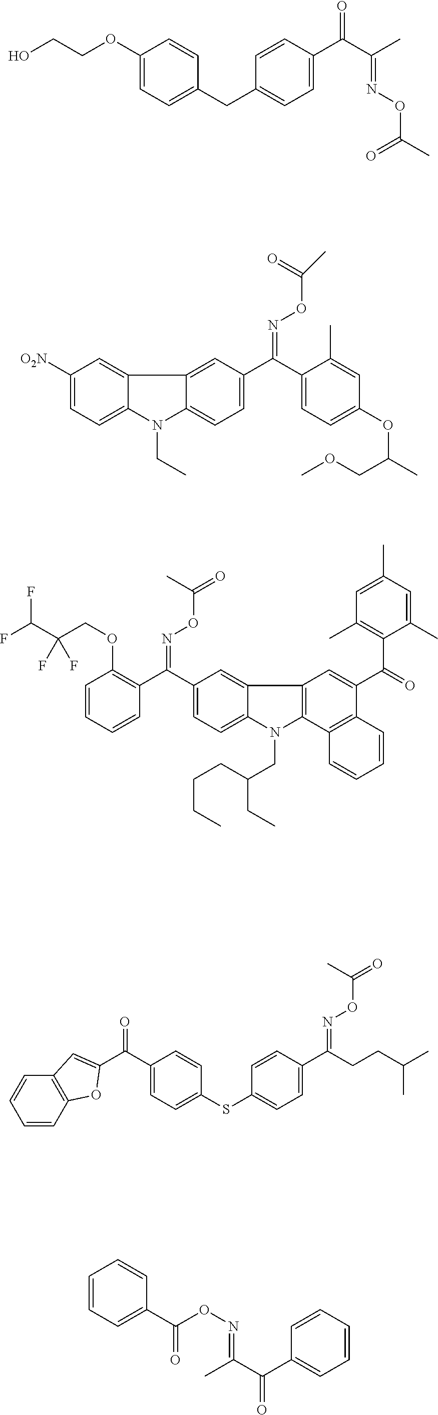 [SMILES: CC(=O)O/N=C(\C)C(=O)c1ccc(Cc2ccc(OCCO)cc2)cc1 ; CCn1c2ccc(/C(=N/OC(C)=O)c3ccc(OC(C)COC)cc3C)cc2c2cc([N+](=O)[O-])ccc21 ; CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21 ; CC(=O)O/N=C(\CCC(C)C)c1ccc(Sc2ccc(C(=O)c3cc4ccccc4o3)cc2)cc1 ; C/C(=N\OC(=O)c1ccccc1)C(=O)c1ccccc1]

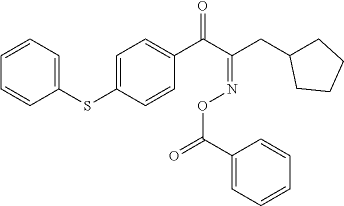 [SMILES: O=C(O/N=C(/CC1CCCC1)C(=O)c1ccc(Sc2ccccc2)cc1)c1ccccc1]

As the photoradical polymerization initiator, it is also possible to use, for example, the oxime compounds having a fluorene ring, which are described in paragraphs 0169 to 0171 of WO2021/112189A, an oxime compound having a skeleton in which at least one benzene ring of a carbazole ring is a naphthalene ring, or an oxime compound having a fluorine atom.

In addition, it is also possible to use the oxime compounds having a nitro group, which are described in paragraphs 0208 to 0210 of WO2021/020359A, an oxime compound having a benzofuran skeleton, or an oxime compound in which a substituent having a hydroxy group is bonded to a carbazole skeleton. The content thereof is incorporated in the present specification.

As the photopolymerization initiator. an oxime compound having an aromatic ring group Ar^{OX1} in which an electron withdrawing group is introduced into an aromatic ring (hereinafter, also referred to as an oxime compound OX) can also be used. Examples of the electron withdrawing group contained in the aromatic ring group Ar^{OX1} include an acyl group, a nitro group, a trifluoromethyl group, an alkylsulfinyl group, an arylsulfinyl group, an alkylsulfonyl group, an arylsulfonyl group, and a cyano group. Here, an acyl group or a nitro group is preferable, and due to the reason that a film having excellent light resistance is easily formed, an acyl group is more preferable, and a benzoyl group is still more preferable. The benzoyl group may have a substituent. The substituent is preferably a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group, more preferably an alkyl group, an alkoxy group, an aryl group, an aryloxy group, a heterocyclic oxy group, an alkylsulfanyl group, an arylsulfanyl group, or an amino group, and still more preferably an alkoxy group, an alkylsulfanyl group, or an amino group.

The oxime compound OX is preferably at least one selected from a compound represented by Formula (OX1) or a compound represented by Formula (OX2), and more preferably a compound represented by Formula (OX2).

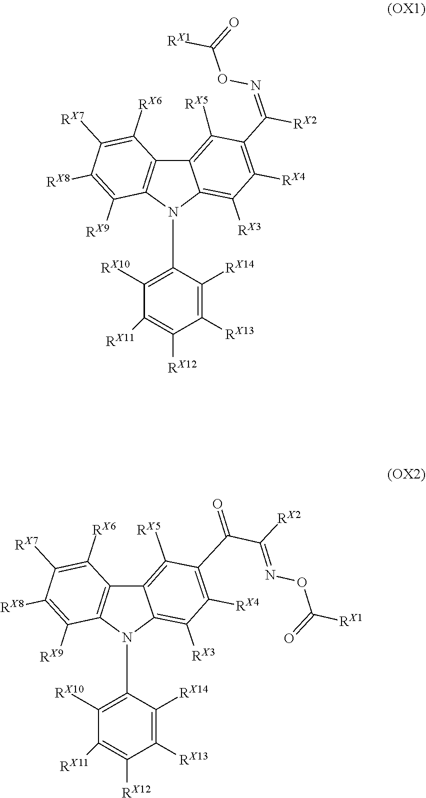

In Formulae, R^{X1} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group, R^{X2} represents an alkyl group, an alkenyl group, an alkoxy group, an aryl group, an aryloxy group, a heterocyclic group, or a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group, and R^{X3} to R^{X14} each independently represent a hydrogen atom or a substituent. However, at least one of R^{X10}, . . . , or R^{X14} is an electron withdrawing group.

In the above Formulae, it is preferable that R^{X12} is an electron withdrawing group, and R^{X10}, R^{X11}, R^{X13}, and R^{X14} are a hydrogen atom.

Specific examples of the oxime compound OX include the compounds described in paragraph Nos. 0083 to 0105 of JP4600600B, the content of which is incorporated in the present specification.

Examples of the particularly preferred oxime compound include the oxime compound having a specific substituent described in JP2007-269779A and the oxime compound having a thioaryl group described in JP2009-191061A, the contents of which are incorporated in the present specification.

From the viewpoint of exposure sensitivity, the photoradical polymerization initiator is preferably a compound selected from the group consisting of a trihalomethyltriazine compound, a benzyl dimethyl ketal compound, an α-hydroxy ketone compound, an α-aminoketone compound, an acylphosphine compound, a phosphine oxide compound, a metallocene compound, an oxime compound, a triaryl imidazole dimer, an onium salt compound, a benzothiazole compound, a benzophenone compound, an acetophenone compound and a derivative thereof, a cyclopentadiene-benzene-iron complex and a salt thereof, a halomethyl oxadiazole compound, and a 3-aryl substituted coumarin compound.

In addition, the photoradical polymerization initiator is a trihalomethyltriazine compound, an α-aminoketone compound, an acylphosphine compound, a phosphine oxide compound, a metallocene compound, an oxime compound, a triaryl imidazole dimer, an onium salt compound, a benzophenone compound, or an acetophenone compound. It is more preferably at least one compound selected from the group consisting of a trihalomethyltriazine compound, an α-aminoketone compound, a metallocene compound, an oxime compound, a triaryl imidazole dimer, and a benzophenone compound, and still more preferably a metallocene compound or an oxime compound.

As the photoradical polymerization initiator, the compounds described in paragraphs 0175 to 0179 of WO2021/020359A and the compounds described in paragraphs 0048 to 0055 of WO2015/125469A can also be used, the contents of which are incorporated in the present specification.

As the photoradical polymerization initiator, a photoradical polymerization initiator which is difunctional or tri- or higher functional may be used. In a case where such a photoradical polymerization initiator is used, two or more radicals are generated from one molecule of the photoradical polymerization initiator, and thus good sensitivity is obtained. Further, in a case where a compound having an asymmetric structure is used, the crystallinity is reduced, the solubility in a solvent or the like is improved, and the compound is hardly precipitated over time, which makes it possible to improve the temporal stability of the resin composition. Specific examples of the photoradical polymerization initiator which is difunctional or tri- or higher functional include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A, the compound (E) and compound (G) described in JP2013-522445A, Cmpd 1 to 7 described in WO2016/034963A, the oxime ester photoinitiators described in paragraph No. 0007 of JP2017-523465A, the photoinitiators described in paragraph Nos. 0020 to 0033 of JP2017-167399A, the photopolymerization initiator (A) described in paragraph Nos. 0017 to 0026 of JP2017-151342A, and the oxime ester photoinitiator described in JP6469669B, the contents of which are incorporated in the present specification.

In a case where the resin composition contains a photopolymerization initiator, the content thereof is preferably 0.1% to 30% by mass, more preferably 0.1% to 20% by mass, still more preferably 0.5% to 15% by mass, and even still more preferably 1.0% to 10% by mass with respect to the total solid content of the resin composition. Only one kind of photopolymerization initiator may be contained, or two or more kinds thereof may be contained. In a case where two or more kinds of photopolymerization initiators are contained, the total amount thereof is preferably within the above-described range.

It is noted that since the photopolymerization initiator may also function as a thermal polymerization initiator, crosslinking with the photopolymerization initiator may be further allowed to proceed by heating an oven, a hot plate, or the like.

### [Sensitizing Agent]

The resin composition may contain a sensitizing agent. The sensitizing agent absorbs a specific radioactive ray to be in an electronically excited state. The sensitizing agent in the electronically excited state is brought into contact with a thermal radical polymerization initiator, a photoradical polymerization initiator, or the like, to cause actions such as electron migration, energy transfer, and heat generation. As a result, the thermal radical polymerization and the photoradical polymerization initiator undergo a chemical change and decompose to generate a radical, an acid, or a base.

In addition, as a usable sensitizing agent, a benzophenone-based, a Michler's ketone-based, a coumarin-based, a pyrazole azo-based, an anilino azo-based, a triphenylmethane-based, an anthraquinone-based, an anthracene-based, an anthrapylidene-based, a benzylidene-based, an oxonol-based, a pyrazolotriazole azo-based, a pyridone azo-based, a cyanine-based, a phenothiazine-based, a pyrrolopyrazole azomethine-based, a xanthene-based, a phthalocyanine-based, a benzopyran-based, and an indigo-based compound can be used.

Examples of the sensitizing agent include, Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylaminocinnamylidene indanone, p-dimethylamino benzylidene indanone, 2-(p-dimethylaminophenylbiphenylene)-benzothiazole, 2-(p-dimethylaminophenylvinylene)benzothiazole, 2-(p-dimethylaminophenylvinylene)isonaphtothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin (ethyl 7-(diethylamino)coumarin-3-carboxylate), N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl)benzoxazole, 2-(p-dimethylaminostyryl)benzothiazole, 2-(p-dimethylaminostyryl)naphtho (1,2-d)thiazole, 2-(p-dimethylaminobenzoyl)styrene, diphenylacetamide, benzanilide, N-methylacetanilide, and 3′,4′-dimethylacetanilide.

In addition, other sensitizing dyes may be used.

For details of the sensitizing dye, reference can be made to the description in paragraphs 0161 to 0163 of JP2016-027357A, the content of which is incorporated in the present specification.

In a case where the resin composition contains a sensitizing agent, the content of the sensitizing agent is preferably 0.01% to 20% by mass, more preferably 0.1% to 15% by mass, and still more preferably 0.5% to 10% by mass with respect to the total solid content of the resin composition. One kind of sensitizing agent may be used alone, or two or more kinds thereof may be used in combination.

### [Chain Transfer Agent]

The resin composition according to the embodiment of the present invention may contain a chain transfer agent. The chain transfer agent is defined, for example, in Polymer Dictionary, 3rd Edition, pp. 683 to 684 (edited by The Society of Polymer Science, 2005). As the chain transfer agent, for example, the following compound is used; a group of compounds having —S—S—, —SO₂—S—, —N—O—, SH, PH, SiH, or GeH in the molecule, or a dithiobenzoate compound, a trithiocarbonate compound, dithiocarbamate, or a xanthate compound, which has a thiocarbonylthio group that is used for the reversible addition fragmentation chain transfer (RAFT) polymerization. These can donate hydrogen to a low active radical to generate a radical or can be oxidized and then deprotonated to generate a radical. In particular, a thiol compound can be preferably used.

In addition, as the chain transfer agent, the compounds described in paragraphs 0152 and 0153 of WO2015/199219A can also be used, the content of which is incorporated in the present specification.

In a case where the resin composition has a chain transfer agent, the content of the chain transfer agent is preferably 0.01 to 20 parts by mass, more preferably 0.1 to 10 parts by mass, and still more preferably 0.5 to 5 parts by mass, with respect to 100 parts by mass of the total solid content of the resin composition. Only one kind of chain transfer agent may be used alone, or two or more kinds thereof may be used. In a case where two or more kinds of chain transfer agents are used, the total thereof is preferably within the above-described range.

In addition, the polymerization initiator is preferably a photoacid generator. The photoacid generator is preferably a photoacid generator that generates a radical.

Specifically, the compound is preferably a compound that absorbs light, decomposes the absorbed light to generate a radical, and abstracts hydrogen from a solvent, an acid generator itself, or the like to generate an acid.

Examples of the photoacid generator include a quinone diazide compound, an oxime sulfonate compound, an organic halogenated compound, an organic borate compound, a disulfone compound, and an onium salt, and an onium salt is preferable.

Examples of the onium salt include a diazonium salt, a phosphonium salt, a sulfonium salt, and an iodonium salt.

Further, the onium salt is a salt of a cation having an onium structure and an anion, and the cation and the anion may be or may not be bonded through a covalent bond.

That is, the onium salt may be an intramolecular salt having a cation moiety and an anion moiety in the same molecular structure, or may be an intermolecular salt in which a cation molecule and an anion molecule, which are separate molecules, are ionically bonded; however, an intermolecular salt is preferred. Further, in the composition according to the embodiment of the present invention, the cation moiety or the cation molecule and the anion moiety or the anion molecule may be bonded by the ionic bonding or be dissociated from each other.

### [Sulfonium Salt]

In the present invention, the sulfonium salt means a salt of a sulfonium cation and an anion.

### —Sulfonium Cation—

The sulfonium cation is preferably a tertiary sulfonium cation and more preferably a triaryl sulfonium cation.

In addition, the sulfonium cation is preferably a cation represented by Formula (103).

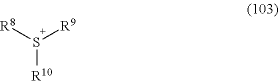

In Formula (103), R⁸ to R¹⁰ each independently represent a hydrocarbon group.

R⁸ to R¹⁰ are each independently preferably an alkyl group or an aryl group, more preferably an alkyl group having 1 to 10 carbon atoms or an aryl group having 6 to 12 carbon atoms, still more preferably an aryl group having 6 to 12 carbon atoms, and even still more preferably a phenyl group.

R⁸ to R¹⁰ may have a substituent, and examples of the substituent include a hydroxy group, an aryl group, an alkoxy group, an aryloxy group, an arylcarbonyl group, an alkylcarbonyl group, an alkoxycarbonyl group, an aryloxycarbonyl group, and an acyloxy group. Among these, R⁸ to R¹⁰ preferably have an alkyl group or an alkoxy group as the substituent, more preferably has a branched alkyl group or an alkoxy group, and still more preferably have a branched alkyl group having 3 to 10 carbon atoms or an alkoxy group having 1 to 10 carbon atoms.

R⁸ to R¹⁰ may be the same group or different groups; however, from the viewpoint of synthesis compatibility, R⁸ to R¹⁰ are preferably the same group.

### —Anion—

The anion is not particularly limited, and may be selected in consideration of the acid generated. Examples of the anion include boron-based anions such as B(C₆F₅)₄⁻ and BF₄⁻, phosphorus-based anions such as (Rf)ₙPF₆₋ₙ⁻, PF₃(C₂F₅)₃⁻ and PF₆⁻, antimony-based anions such as SbF₆⁻, and other carboxylate anions, sulfonate anions, and the like.

### [Iodonium Salt]

In the present invention, the iodonium salt means a salt of an iodonium cation and an anion. Examples of the anion include the same anions as those in the sulfonium salt described above, and the same applies to the preferred aspect.

### —Iodonium Cation—

The iodonium cation is preferably a diaryl iodonium cation.

In addition, the iodonium cation is preferably a cation represented by Formula (104).

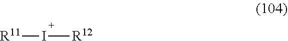

In Formula (104), R¹¹ and R¹² each independently represent a hydrocarbon group.

R¹¹ and R¹² are each independently preferably an alkyl group or an aryl group, more preferably an alkyl group having 1 to 10 carbon atoms or an aryl group having 6 to 12 carbon atoms, still more preferably an aryl group having 6 to 12 carbon atoms, and even still more preferably a phenyl group.

R¹¹ and R¹² may have a substituent, and examples of the substituent include a hydroxy group, an aryl group, an alkoxy group, an aryloxy group, an arylcarbonyl group, an alkylcarbonyl group, an alkoxycarbonyl group, an aryloxycarbonyl group, and an acyloxy group. Among these, R¹¹ and R¹² preferably have an alkyl group or an alkoxy group as the substituent, more preferably have a branched alkyl group or an alkoxy group, and still more preferably have a branched alkyl group having 3 to 10 carbon atoms or an alkoxy group having 1 to 10 carbon atoms.

R¹¹ and R¹² may be the same group or different groups; however, from the viewpoint of synthesis compatibility, R¹¹ and R¹² are preferably the same group.

### [Phosphonium Salt]

In the present invention, the phosphonium salt means a salt of a phosphonium cation and an anion. Examples of the anion include the same anions as those in the sulfonium salt described above, and the same applies to the preferred aspect.

### —Phosphonium Cation—

The phosphonium cation is preferably a quaternary phosphonium cation, and examples thereof include a tetraalkylphosphonium cation and a triarylmonoalkylphosphonium cation.

In addition, the phosphonium cation is preferably a cation represented by Formula (105).

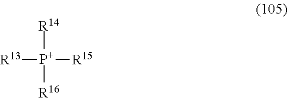

In Formula (105), R¹³ to R¹⁶ each independently represent a hydrogen atom or a hydrocarbon group.

R¹³ to R¹⁶ are each independently preferably an alkyl group or an aryl group, more preferably an alkyl group having 1 to 10 carbon atoms or an aryl group having 6 to 12 carbon atoms, still more preferably an aryl group having 6 to 12 carbon atoms, and even still more preferably a phenyl group.

R¹³ to R¹⁶ may have a substituent, and examples of the substituent include a hydroxy group, an aryl group, an alkoxy group, an aryloxy group, an arylcarbonyl group, an alkylcarbonyl group, an alkoxycarbonyl group, an aryloxycarbonyl group, and an acyloxy group. Among these, R¹³ to R¹⁶ preferably have an alkyl group or an alkoxy group as the substituent, more preferably have a branched alkyl group or an alkoxy group, and still more preferably have a branched alkyl group having 3 to 10 carbon atoms or an alkoxy group having 1 to 10 carbon atoms.

R¹³ to R¹⁶ may be the same group or different groups; however, from the viewpoint of synthesis compatibility, R¹³ to R¹⁶ are preferably the same group.

The content of the photoacid generator is preferably 0.1% to 20% by mass, more preferably 0.5% to 18% by mass, still more preferably 0.5% to 10% by mass, even more preferably 0.5% to 3% by mass, and even still more preferably 0.5% to 1.2% by mass, with respect to the total solid content of the resin composition.

One kind of photoacid generator may be used alone, or a plurality of kinds thereof may be used in combination. In the case of the combination of a plurality of kinds, it is preferable that the total amount thereof is within the above range.

In addition, in order to impart photosensitivity to a desired light source, it is also preferable to use a sensitizing agent in combination.

In addition, one of the preferred aspects of the present invention is that the resin composition according to the embodiment of the present invention contains two or more kinds of polymerization initiators as the polymerization initiator.

Specifically, the resin composition according to the embodiment of the present invention preferably contains a photopolymerization initiator and a thermal polymerization initiator described later, or contains the above-described photoradical polymerization initiator and the above-described photoacid generator.

By containing the photopolymerization initiator and the thermal polymerization initiator described later, pattern formation by exposure is possible, and radical polymerization is also likely to proceed during curing in the heating step described later, and thus the performance such as chemical resistance may be improved.

In the content ratio in a case where the photopolymerization initiator and the thermal polymerization initiator described later are contained, the content of the thermal polymerization initiator is preferably 20% to 70% by mass and more preferably 30% to 60% by mass with respect to the total content of the photopolymerization initiator and the thermal polymerization initiator.

The performance such as resolution may be improved by containing a photoradical polymerization initiator and a photoacid generator.

In the content ratio in a case where the photopolymerization initiator and the photoacid generator are contained, the content of the photoacid generator is preferably 20% to 70% by mass, and more preferably 30% to 60% by mass with respect to the total content of the photopolymerization initiator and the photoacid generator.

### [Thermal Polymerization Initiator]

Examples of the thermal polymerization initiator include a thermal radical polymerization initiator. The thermal radical polymerization initiator is a compound that generates a radical by heat energy and initiates or accelerates a polymerization reaction of a compound having polymerization properties. In a case where a thermal radical polymerization initiator is added, the polymerization reaction of the resin and the polymerizable compound can be allowed to proceed, and thus the solvent resistance can be further improved.

Specific examples of thermal radical polymerization initiator include compounds described in paragraphs 0074 to 0118 of JP2008-063554A, the content of which is incorporated in the present specification.

In a case where a thermal polymerization initiator is contained, the content thereof is preferably 0.1% to 30% by mass, more preferably 0.1% to 20% by mass, and still more preferably 0.5% to 15% by mass with respect to the total solid content of the resin composition. The resin composition may contain only one kind of thermal polymerization initiator, or may contain two or more kinds thereof. In a case where two or more kinds of thermal polymerization initiators are contained, the total amount thereof is preferably within the above-described range.

### <Base Generator>

The resin composition according to the embodiment of the present invention may contain a base generator. Here, the base generator is a compound that is capable of generating a base under a physical or chemical action. Examples of the preferred base generator include a thermal-base generator and a photobase generator.

In particular, in a case where the resin composition contains a precursor of a cyclization resin, it is preferable that the resin composition contains a base generator. In a case where the resin composition contains a thermal-base generator, it is possible to, for example, accelerate the cyclization reaction of the precursor by heating, whereby the mechanical properties and chemical resistance of the cured substance are improved and for example, the performance as an interlayer insulating film for a re-distribution layer, included in a semiconductor package, is improved.

The base generator may be an ionic base generator or may be a nonionic base generator. Examples of the base that is generated from the base generator include a secondary amine and a tertiary amine.

The base generator is not particularly limited, and a publicly known base generator can be used. Examples of the publicly known base generator include a carbamoyloxime compound, a carbamoylhydroxylamine compound, a carbamic acid compound, a formamide compound, an acetamide compound, a carbamate compound, a benzylcarbamate compound, a nitrobenzylcarbamate compound, a sulfonamide compound, an imidazole derivative compound, an aminimide compound, a pyridine derivative compound, an α-aminoacetophenone derivative compound, a quaternary ammonium salt derivative compound, an iminium salt, a pyridinium salt, an α-lactone ring derivative compound, a phthalimide derivative compound, and an acyloxyimino compound.

Specific examples of the nonionic base generator include the compounds described in paragraphs 0249 to 0275 of WO2022/145355A. The above description is incorporated in the present specification.

Examples of the base generator include the following compounds; however, the base generator is not limited thereto.

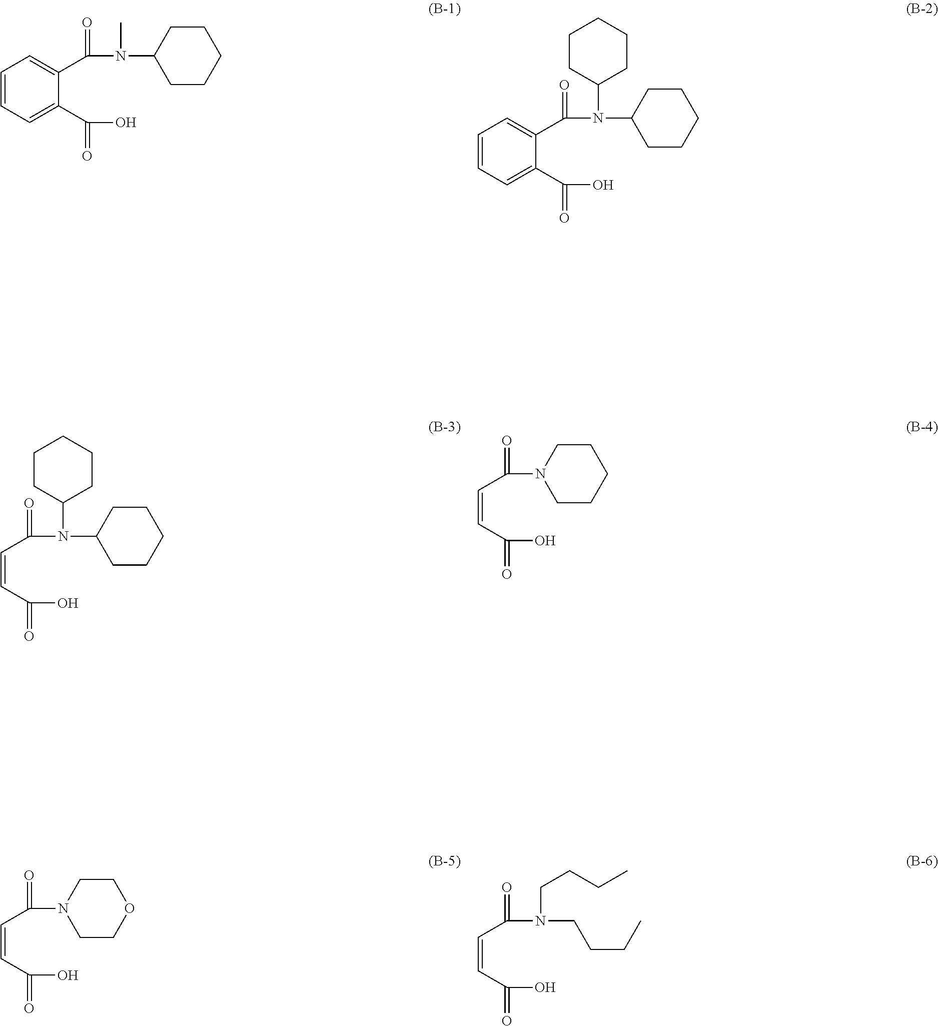 [SMILES: CN(C(=O)c1ccccc1C(=O)O)C1CCCCC1 ; O=C(O)c1ccccc1C(=O)N(C1CCCCC1)C1CCCCC1 ; O=C(O)/C=C\C(=O)N(C1CCCCC1)C1CCCCC1 ; O=C(O)/C=C\C(=O)N1CCCCC1 ; O=C(O)/C=C\C(=O)N1CCOCC1 ; CCCCN(CCCC)C(=O)/C=C\C(=O)O]

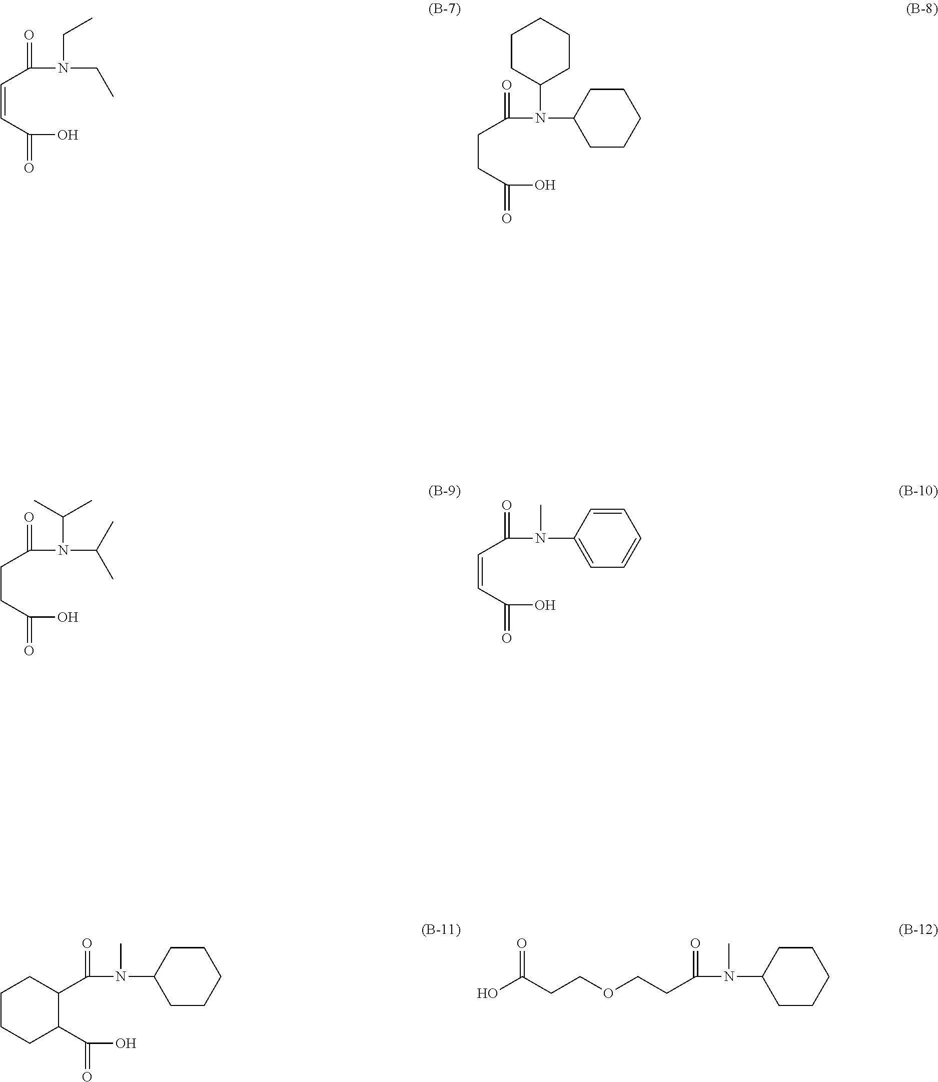 [SMILES: CCN(CC)C(=O)/C=C\C(=O)O ; O=C(O)CCC(=O)N(C1CCCCC1)C1CCCCC1 ; CC(C)N(C(=O)CCC(=O)O)C(C)C ; CN(C(=O)/C=C\C(=O)O)c1ccccc1 ; CN(C(=O)C1CCCCC1C(=O)O)C1CCCCC1 ; CN(C(=O)CCOCCC(=O)O)C1CCCCC1]

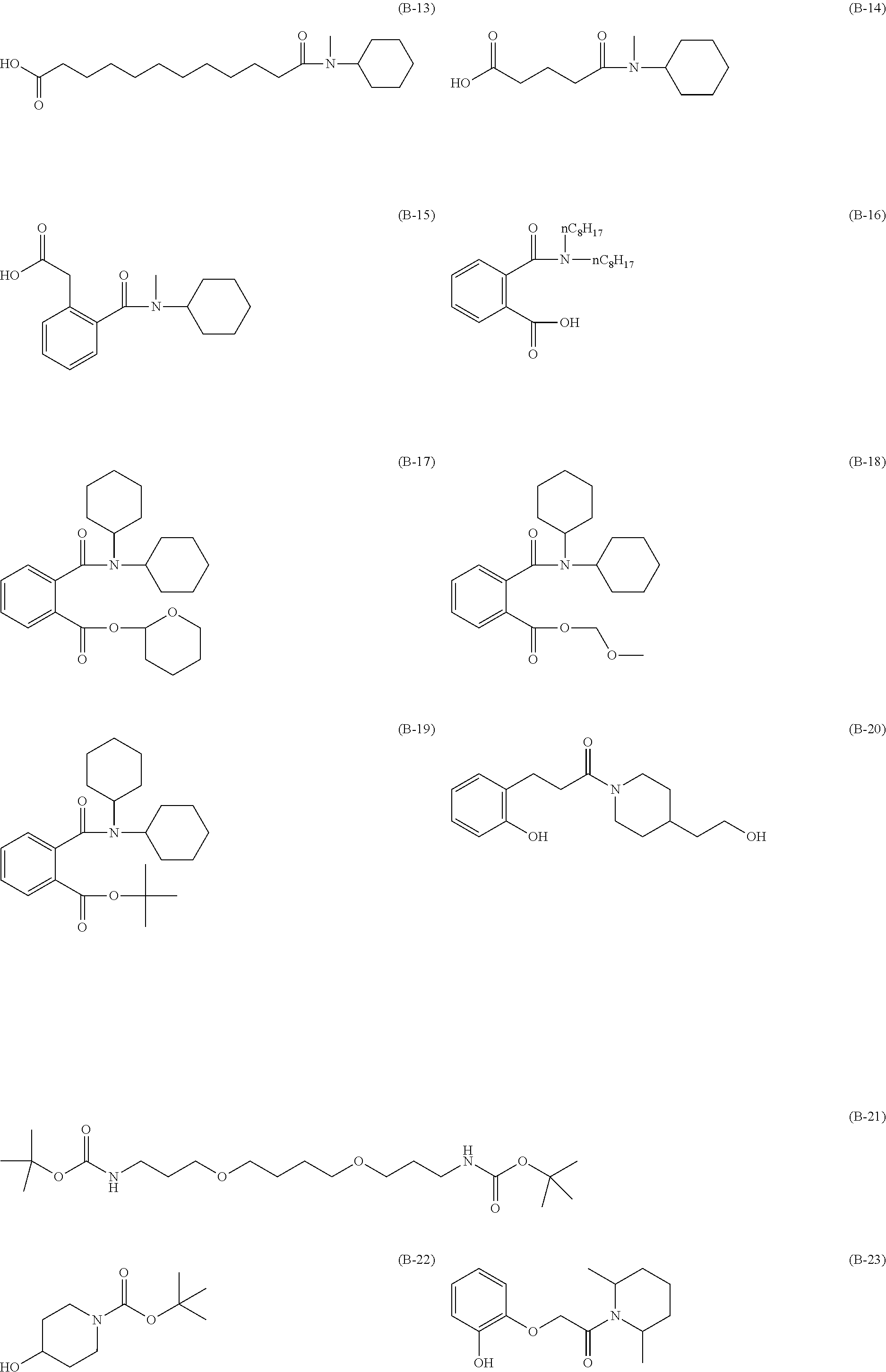

The molecular weight of the nonionic base generator is preferably 800 or less, more preferably 600 or less, and still more preferably 500 or less. The lower limit thereof is preferably 100 or more, more preferably 200 or more, and still more preferably 300 or more.

Examples of the specific preferred compound of the ionic base generator include the compounds described in paragraphs 0148 to 0163 of WO2018/038002A.

Specific examples of the ammonium salt include the following compounds; however, the ammonium salt is not limited thereto.

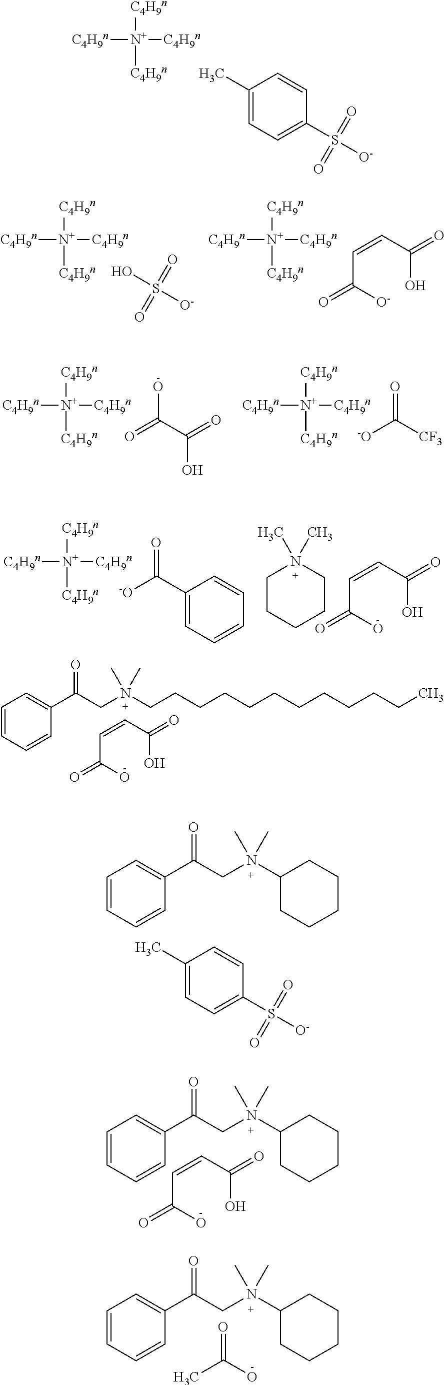

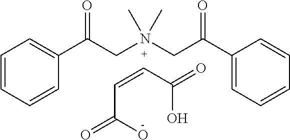

Specific examples of the iminium salt include the following compounds; however, the iminium salt is not limited thereto.

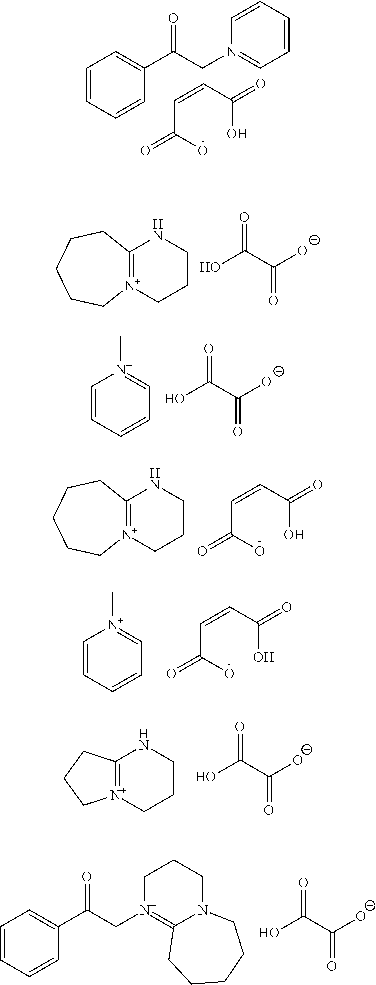

In addition, from the viewpoint of storage stability and generation of a base by deprotection during curing, the base generator is preferably an amine in which an amino group is protected by a t-butoxycarbonyl group.

Examples of the amine compound protected by a t-butoxycarbonyl group include ethanolamine, 3-amino-1-propanol, 1-amino-2-propanol, 2-amino-1-propanol, 4-amino-1-butanol, 2-amino-1-butanol, 1-amino-2-butanol, 3-amino-2,2-dimethyl-1-propanol, 4-amino-2-methyl-1-butanol, valinol, 3-amino-1,2-propanediol, 2-amino-1,3-propanediol, tyramine, norephedrine, 2-amino-1-phenyl-1,3-propanediol, 2-aminocyclohexanol, 4-aminocyclohexanol, 4-aminocyclohexanethanol, 4-(2-aminoethyl)cyclohexanol, N-methylethanolamine, 3-(methylamino)-1-propanol, 3-(isopropylamino)propanol, N-cyclohexylethanolamine, α-[2-(methylamino)ethyl]benzyl alcohol, diethanolamine, diisopropanolamine, 3-pyrrolidinol, 2-pyrrolidinomethanol, 4-hydroxypiperidine, 3-hydroxypiperidine, 4-hydroxy-4-phenylpiperidine, 4-(3-hydroxyphenyl)piperidine, 4-piperidinemethanol, 3-piperidinemethanol, 2-piperidinemethanol, 4-piperidinetanol, 2-piperidinetanol, 2-(4-piperidyl)-2-propanol, 1,4-butanol bis(3-aminopropyl)ether, 1,2-bis(2-aminoethoxy)ethane, 2,2′-oxybis(ethylamine), 1,14-diamino-3,6,9,12-tetraoxatetradecane, 1-aza-15-crown 5-ether, diethylene glycol bis(3-aminopropyl)ether, 1,11-diamino-3,6,9-trioxaundecane, or a compound in which an amino group of an amino acid and a derivative thereof is protected by a t-butoxycarbonyl group, but the present invention is not limited to these examples.

In a case where the resin composition contains a base generator, the content of the base generator is preferably 0.1 to 50 parts by mass with respect to 100 parts by mass of the resin in the resin composition. The lower limit thereof is more preferably 0.3 parts by mass or more and still more preferably 0.5 parts by mass or more. The upper limit thereof is more preferably 30 parts by mass or less, still more preferably 20 parts by mass or less, even still more preferably 10 parts by mass or less, even further still more preferably 5 parts by mass or less, and particularly preferably 4 parts by mass or less.

One kind or two or more kinds of base generators can be used. In a case where two or more kinds thereof are used, the total amount is preferably within the above-described range.

### <Solvent>

The resin composition according to the embodiment of the present invention preferably contains a solvent.

As the solvent, any publicly known solvent can be used. The solvent is preferably an organic solvent. Examples of the organic solvent include compounds such as esters, ethers, ketones, cyclic hydrocarbons, sulfoxides, amides, ureas, and alcohols.

Suitable examples of the esters include ethyl acetate, n-butyl acetate, isobutyl acetate, hexyl acetate, amyl formate, isoamyl acetate, butyl propionate, isopropyl butyrate, ethyl butyrate, butyl butyrate, methyl lactate, ethyl lactate, γ-butyrolactone, ε-caprolactone, δ-valerolactone, γ-valerolactone, alkyl alkyloxyacetate (for example, methyl alkyloxyacetate, ethyl alkyloxyacetate, and butyl alkyloxyacetate (for example, methyl methoxyacetate, ethyl methoxyacetate, butyl methoxyacetate, methyl ethoxyacetate, and ethyl ethoxyacetate)), 3-alkyloxypropionic acid alkyl esters (for example, methyl 3-alkyloxypropionate, and ethyl 3-alkyloxypropionate (for example, methyl 3-methoxypropionate, ethyl 3-methoxypropionate, methyl 3-ethoxypropionate, and ethyl 3-ethoxypropionate)), 2-alkyloxypropionic acid alkyl esters (for example, methyl 2-alkyloxypropionate, ethyl 2-alkyloxypropionate, and propyl 2-alkyloxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-alkyloxy-2-methylpropionate and ethyl 2-alkyloxy-2-methylpropionate (for example, methyl 2-methoxy-2-methylpropionate and ethyl 2-ethoxy-2-methylpropionate), methyl pyruvate, ethyl pyruvate, propyl pyruvate, methyl acetoacetate, ethyl acetoacetate, methyl 2-oxobutanoate, ethyl 2-oxobutanoate, ethyl hexanoate, ethyl heptanoate, dimethyl malonate, and diethyl malonate.

Suitable examples of ethers include ethylene glycol dimethyl ether, diethylene glycol dimethyl ether, diethylene glycol diethyl ether, diethylene glycol ethyl methyl ether, diethylene glycol butyl methyl ether, triethylene glycol dimethyl ether, tetraethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol dimethyl ether, propylene glycol monomethyl ether acetate, propylene glycol monoethyl ether acetate, ethylene glycol monobutyl ether, ethylene glycol monobutyl ether acetate, diethylene glycol ethyl methyl ether, propylene glycol monopropyl ether acetate, and dipropylene glycol dimethyl ether.

Suitable examples of the ketones include methyl ethyl ketone, cyclohexanone, cyclopentanone, 2-heptanone, 3-heptanone, 3-methylcyclohexanone, levoglucosenone, and dihydrolevoglucosenone.

Suitable examples of the cyclic hydrocarbon include aromatic hydrocarbons such as toluene, xylene, and anisole, and cyclic terpenes such as limonene.

Suitable examples of the sulfoxides include dimethyl sulfoxide.

Suitable examples of the amide include N-methyl-2-pyrrolidone, N-ethyl-2-pyrrolidone, N-cyclohexyl-2-pyrrolidone, N,N-dimethylacetamide, N,N-dimethylformamide, N,N-dimethylisobutylamide, 3-methoxy-N,N-dimethylpropionamide, 3-butoxy-N,N-dimethylpropionamide, N-formylmorpholine, and N-acetylmorpholine.

Suitable examples of the urea include N,N,N′,N′-tetramethylurea and 1,3-dimethyl-2-imidazolidinone.

Examples of the alcohols include methanol, ethanol, 1-propanol, 2-propanol, 1-butanol, 1-pentanol, 1-hexanol, benzyl alcohol, ethylene glycol monomethyl ether, 1-methoxy-2-propanol, 2-ethoxyethanol, diethylene glycol monoethyl ether, diethylene glycol monohexyl ether, triethylene glycol monomethyl ether, propylene glycol monoethyl ether, propylene glycol monomethyl ether, polyethylene glycol monomethyl ether, polypropylene glycol, tetraethylene glycol, ethylene glycol monobutyl ether, ethylene glycol monobenzyl ether, ethylene glycol monophenyl ether, methylphenyl carbinol, n-amyl alcohol, methylamyl alcohol, and diacetone alcohol.

From the viewpoint of improving the properties of a coated surface or the like, it is also preferable to mix two or more kinds of solvents.

In the present invention, the solvent is preferably one solvent selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclopentanone, γ-butyrolactone, γ-valerolactone, 3-methoxy-N,N-dimethylpropionamide, toluene, dimethyl sulfoxide, ethyl carbitol acetate, butyl carbitol acetate, N-methyl-2-pyrrolidone, propylene glycol methyl ether, and propylene glycol methyl ether acetate, as well as levoglucosenone and dihydrolevoglucosenone, or a mixed solvent composed of two or more of these. A combined use of dimethyl sulfoxide and γ-butyrolactone, a combined use of dimethyl sulfoxide and γ-valerolactone, a combined use of 3-methoxy-N,N-dimethylpropionamide and γ-butyrolactone, a combined use of 3-methoxy-N,N-dimethylpropionamide and dimethyl sulfoxide, or, a combined use of N-methyl-2-pyrrolidone and ethyl lactate is particularly preferable. An aspect in which an amount of about 1% to 10% by mass of toluene with respect to the total mass of the solvent is further added to these combinedly used solvents is also one of the preferred aspects of the present invention.

In particular, from the viewpoint of the storage stability or the like of the resin composition, an aspect in which γ-valerolactone is included as the solvent is also one of the preferred aspects of the present invention. In such an aspect, the content of γ-valerolactone with respect to the total mass of the solvent is preferably 50% by mass or more, more preferably 60% by mass or more, and still more preferably 70% by mass or more. In addition, the upper limit of the above-described content is not particularly limited, and it may be 100% by mass. The above-described content may be determined in consideration of the solubility or the like of the component contained in the resin composition, such as the specific resin.

In addition, in a case where dimethyl sulfoxide and γ-valerolactone are used in combination, with respect to the total mass of the solvent, it is preferable to contain 60% to 90% by mass of γ-valerolactone and 10% to 40% by mass of dimethyl sulfoxide, it is more preferable to contain 70% to 90% by mass of γ-valerolactone and 10% to 30% by mass of dimethyl sulfoxide, and it is still more preferable to contain 75% to 85% by mass of γ-valerolactone and 15% to 25% by mass of dimethyl sulfoxide.

Regarding the content of the solvent, the amount of the solvent is such that, from the viewpoint of coatability, the concentration of the total solid contents of the resin composition according to the embodiment of the present invention is preferably 5% to 80% by mass, more preferably 5% to 75% by mass, still more preferably 10% to 70% by mass, and even still more preferably 20% to 70% by mass. The content of the solvent may be adjusted depending on the desired thickness of the coating film and the coating method. In a case where two or more kinds of solvents are contained, the total thereof is preferably within the above-described range.

### <Metal Adhesiveness Improving Agent>

From the viewpoint of improving adhesiveness to a metal material used for an electrode, a wire, or the like, the resin composition according to the embodiment of the present invention preferably contains a metal adhesiveness improving agent. Examples of the metal adhesiveness improving agent include a silane coupling agent having an alkoxysilyl group, an aluminum-based auxiliary adhesive agent, a titanium-based auxiliary adhesive agent, a compound having a sulfonamide structure and a compound having a thiourea structure, a phosphoric acid derivative compound, a 0-ketoester compound, and an amino compound.

### [Silane Coupling Agent]

Examples of the silane coupling agent include the compounds described in paragraph 0316 of WO2021/112189A and the compounds described in paragraphs 0067 to 0078 of JP2018-173573A, the contents of which are incorporated in the present specification. In addition, it is also preferable to use two or more kinds of different silane coupling agents as described in paragraphs 0050 to 0058 of JP2011-128358A. It is also preferable to use the following compound as the silane coupling agent. In the following Formulae, Me represents a methyl group, and Et represents an ethyl group. In addition, examples of R shown below include a structure derived from a blocking agent in a blocked isocyanate group. The blocking agent may be selected depending on the desorption temperature; however, examples thereof include an alcohol compound, a phenol compound, a pyrazole compound, a triazole compound, a lactam compound, and an active methylene compound. It is preferably caprolactam or the like, for example, from the viewpoint of setting the desorption temperature to 160° C. to 180° C. Examples of the commercially available product of such a compound include X-12-1293 (manufactured by Shin-Etsu Chemical Co., Ltd.).

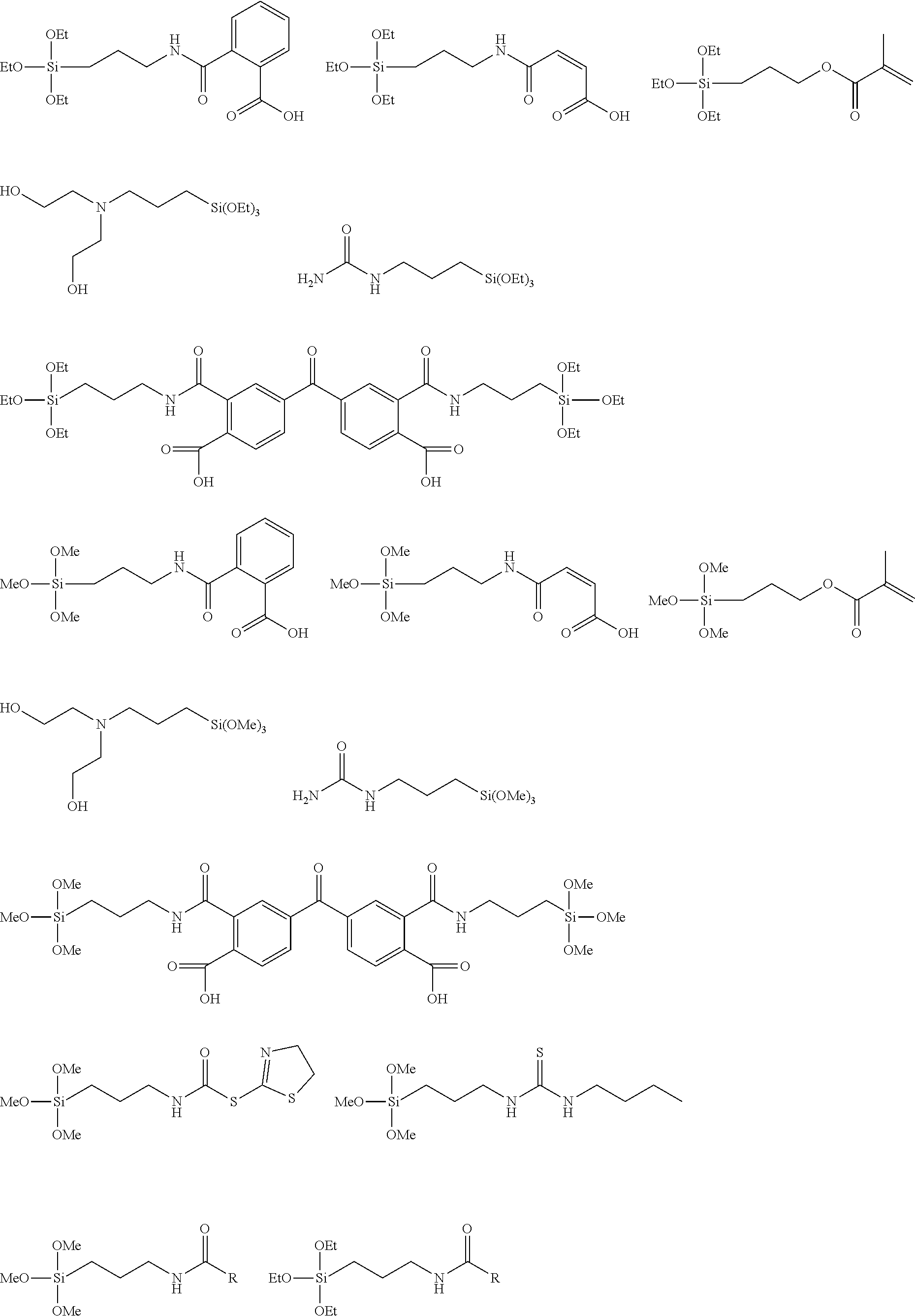

Examples of the other silane coupling agent include vinyltrimethoxysilane, vinyltriethoxysilane, 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, tris-(trimethoxysilylpropyl)isocyanurate, 3-ureidopropyltrialkoxysilane, 3-mercaptopropylmethyldimethoxysilane, 3-mercaptopropyltrimethoxysilane, 3-isocyanatepropyltriethoxysilane, and 3-trimethoxysilylpropylsuccinic acid anhydride. These can be used alone or in a combination of two or more thereof.

In addition, an oligomer type compound having a plurality of alkoxysilyl groups can also be used as the silane coupling agent.

Examples of such an oligomer type compound include a compound containing a repeating unit represented by Formula (S-1).

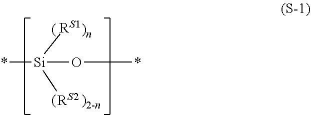

In Formula (S-1), R^{S1} represents a monovalent organic group, R^{S2} represents a hydrogen atom, a hydroxy group, or an alkoxy group, and n represents an integer of 0 to 2.

R^{S1} preferably has a structure including a polymerizable group. Examples of the polymerizable group include a group having an ethylenically unsaturated bond, an epoxy group, an oxetanyl group, a benzoxazolyl group, a blocked isocyanate group, and an amino group. Examples of the group having an ethylenically unsaturated bond include a vinyl group, an allyl group, an isoallyl group, a 2-methylallyl group, a group (for example, a vinylphenyl group) having an aromatic ring that is directly bonded to a vinyl group, and a (meth)acrylamide group, a (meth)acryloyloxy group, where a vinylphenyl group, a (meth)acrylamide group, or a (meth)acryloyloxy group is preferable, a vinylphenyl group or a (meth)acryloyloxy group is more preferable, and a (meth)acryloyloxy group is still more preferable.

R^{S2} is preferably an alkoxy group, and more preferably a methoxy group or an ethoxy group.

n represents an integer of 0 to 2, and it is preferably 1.

Here, structures of a plurality of repeating units represented by Formula (S-1) may be the same, where the plurality of repeating units are contained in the oligomer type compound.

Here, among a plurality of repeating units represented by Formula (S-1), which are contained in the oligomer type compound, it is preferable that at least one repeating unit has n of 1 or 2, it is more preferable that at least two repeating units have n of 1 or 2, and it is still more preferable that at least two repeating units have n of 1.

As such an oligomer type compound, a commercially available product can be used, and examples thereof include KR-513 (manufactured by Shin-Etsu Chemical Co., Ltd.).

### [Aluminum-Based Auxiliary Adhesive Agent]

Examples of the aluminum-based auxiliary adhesive agent include aluminum tris(ethyl acetoacetate), aluminum tris(acetyl acetate), and ethyl acetoacetate aluminum diisopropylate.

As another metal adhesiveness improving agent, the compounds described in paragraphs 0046 to 0049 of JP2014-186186A, and the sulfide-based compounds described in paragraphs 0032 to 0043 of JP2013-072935A can also be used, the contents of which are incorporated in the present specification.

The content of the metal adhesiveness improving agent is preferably 0.01 to 30 parts by mass, more preferably 0.1 to 10 parts by mass, and still more preferably 0.5 to 5 parts by mass with respect to 100 parts by mass of the specific resin. In a case where the content is set to be equal to or higher than the above lower limit value, good adhesiveness between a pattern and a metal layer is exhibited, and in a case where the content is set to be equal to or lower than the above upper limit value, good heat resistance of the pattern and good mechanical characteristics are exhibited. Only one kind of metal adhesiveness improving agent may be used, or two or more kinds thereof may be used. In a case where two or more kinds thereof are used, the total content thereof is preferably within the above-described range.

### <Migration Suppressing Agent>

The resin composition according to the embodiment of the present invention preferably further contains a migration suppressing agent. For example, in a case where the resin composition is applied to a metal layer (or a metal wiring line) to form a film, it is possible to effectively suppress the migration of metal ions derived from the metal layer (or the metal wiring line) into the film, in a case where a migration suppressing agent is contained.

The migration suppressing agent is not particularly limited; however, examples thereof include a compound having a heterocyclic ring (a pyrrole ring, a furan ring, a thiophene ring, an imidazole ring, an oxazole ring, a thiazole ring, a pyrazole ring, an isoxazole ring, an isothiazole ring, a tetrazole ring, a pyridine ring, a pyridazine ring, a pyrimidine ring, a pyrazine ring, a piperidine ring, a piperazine ring, a morpholine ring, a 2H-pyran ring and a 6H-pyran ring, or a triazine ring), a compound having thioureas and a sulfanyl group, a hindered phenol-based compound, a salicylic acid derivative-based compound, and a hydrazide derivative-based compound. In particular, it is possible to preferably use a triazole-based compound such as 1,2,4-triazole, benzotriazole, 3-amino-1,2,4-triazole, or 3,5-diamino-1,2,4-triazole, or a tetrazole-based compound such as 1H-tetrazole, 5-phenyltetrazole or 5-amino-1H-tetrazole.

As the migration suppressing agent, an ion trap agent that captures an anion such as a halogen ion can also be used.

The rust inhibitors described in paragraph 0094 of JP2013-015701A, the compounds described in paragraphs 0073 to 0076 of JP2009-283711A, the compounds described in paragraph 0052 of JP2011-059656A, the compounds described in paragraphs 0114, 0116, and 0118 of JP2012-194520A, the compounds described in paragraph 0166 of WO2015/199219A, or the like can be used as the other migration suppressing agents, the contents of which are incorporated in the present specification.

Specific examples of the migration suppressing agent include the following compounds.

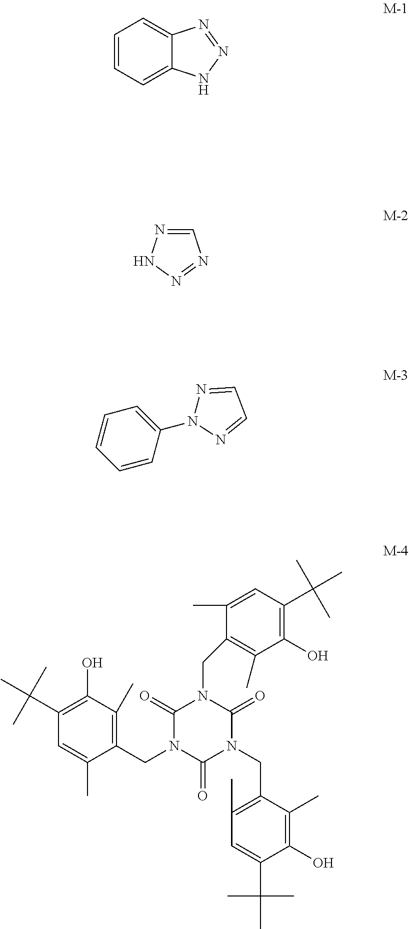 [SMILES: c1ccc2[nH]nnc2c1 ; c1nn[nH]n1 ; c1ccc(-n2nccn2)cc1 ; Cc1cc(C(C)(C)C)c(O)c(C)c1Cn1c(=O)n(Cc2c(C)cc(C(C)(C)C)c(O)c2C)c(=O)n(Cc2c(C)cc(C(C)(C)C)c(O)c2C)c1=O]

In a case where the resin composition according to the embodiment of the present invention contains the migration suppressing agent, the content of the migration suppressing agent is preferably 0.01% to 5.0% by mass, more preferably 0.05% to 2.0% by mass, and still more preferably 0.1% to 1.0% by mass, with respect to the total solid content of the resin composition.

Only one kind of migration suppressing agent may be used alone, or two or more kinds thereof may be used. In a case where two or more kinds of migration suppressing agents are used, the total thereof is preferably within the above-described range.

### <Light Absorbing Agent>

The resin composition according to the embodiment of the present invention also preferably contains a compound (a light absorbing agent) having a small absorbance at an exposure wavelength thereof upon exposure.

Examples of the light absorbing agent include compounds described in paragraphs 0159 to 0183 of WO2022/202647A and compounds described in paragraphs 0088 to 0108 of JP2019-206689A. The content thereof is incorporated in the present specification.

The content of the light absorbing agent with respect to the total solid content of the resin composition according to the embodiment of the present invention is not particularly limited, but is preferably 0.1% to 20% by mass, more preferably 0.5% to 10% by mass, and still more preferably 1% to 5% by mass.

### <Polymerization Inhibitor>

The resin composition according to the embodiment of the present invention preferably contains a polymerization inhibitor. Examples of the polymerization inhibitor include a phenol-based compound, a quinone-based compound, an amino-based compound, an N-oxyl-free radical-based compound, a nitro-based compound, a nitroso-based compound, a heteroaromatic ring-based compound, and a metal compound.

Specific examples of the compound of the polymerization inhibitor include the compounds described in paragraph 0310 of WO2021/112189A, p-hydroquinone, o-hydroquinone, a 4-hydroxy-2,2,6,6-tetramethylpiperidine-1-oxyl free radical, phenoxazine, and 1,4,4-trimethyl-2,3-diazabicyclo[3.2.2]nona-2-en-N,N-dioxide. The content thereof is incorporated in the present specification.

In a case where the resin composition according to the embodiment of the present invention has a polymerization inhibitor, the content of the polymerization inhibitor is preferably 0.01% to 20% by mass, more preferably 0.02% to 15% by mass, and still more preferably 0.05% to 10% by mass, with respect to the total solid content of the resin composition.

Only one kind of polymerization inhibitor may be used, or two or more kinds thereof may be used. In a case where two or more kinds of polymerization inhibitors are used, the total thereof is preferably within the above-described range.

### <Other Additives>

The resin composition according to the embodiment of the present invention may contain various additives as necessary, for example, a surfactant, a higher fatty acid derivative, a thermal polymerization initiator, inorganic particles, an ultraviolet absorbing agent, an organic titanium compounds, an antioxidant, a photoacid generator, an aggregation inhibitor, a phenol-based compound, another polymer compound, a plasticizer, and other auxiliary agents (for example, an anti-foaming agent, and a flame retardant) within the scope in which the effect of the present invention is obtained. By appropriately containing these components, properties such as film properties can be adjusted. The details of the components can be found in, for example, paragraph “0183” and subsequent paragraphs of JP2012-003225A (corresponding to paragraph 0237 of US2013/0034812A) and paragraphs 0101 to 0104 and 0107 to 0109 of JP2008-250074A, the contents of which are incorporated in the present specification. In a case where these additives are blended, the total content thereof is preferably 3% by mass or less of the solid content of the resin composition according to the embodiment of the present invention.

### [Inorganic Particle]

Specific examples of the inorganic particle include calcium carbonate, calcium phosphate, silica, kaolin, talc, titanium dioxide, alumina, barium sulfate, calcium fluoride, lithium fluoride, zeolite, molybdenum sulfide, and glass.

The average particle diameter of the inorganic particles is preferably 0.01 to 2.0 μm, more preferably 0.02 to 1.5 μm, still more preferably 0.03 to 1.0 μm, and particularly preferably 0.04 to 0.5 μm.

The average particle diameter of the inorganic particles is the primary particle diameter and the volume average particle diameter. The volume average particle diameter can be measured by, for example, a dynamic light scattering method with Nanotrac WAVE II EX-150 (manufactured by Nikkiso Co., Ltd.).

In a case where the above measurement is difficult, the measurement can also be carried out by a centrifugal sedimentation light transmission method, an X-ray transmission method, or a laser diffraction/light scattering method.

### [Organic Titanium Compound]

In a case where the resin composition contains an organic titanium compound, it is possible to form a resin layer having excellent chemical resistance even in a case where curing is carried out at a low temperature.

Examples of the usable organic titanium compound include those in which an organic group is bonded to a titanium atom through a covalent bond or an ionic bond.

Specific examples of the organic titanium compound are described in I) to VII) below.

I) Titanium chelate compounds: a titanium chelate compound having two or more alkoxy groups is more preferable since the resin composition has good storage stability and a good curing pattern is obtained. Specific examples thereof include titanium bis(triethanolamine)diisopropoxide, titanium di(n-butoxide) bis(2,4-pentanedionate), titanium diisopropoxide bis(2,4-pentanedionate), titanium diisopropoxide bis(tetramethylheptandionate), and titanium diisopropoxide bis(ethyl acetoacetate).

II) Tetraalkoxytitanium compounds: examples thereof include titanium tetra(n-butoxide), titanium tetraethoxide, titanium tetra(2-ethylhexoxide), titanium tetraisobutoxide, titanium tetraisopropoxide, titanium tetramethoxide, titanium tetramethoxypropoxide, titanium tetramethylphenoxide, titanium tetra(n-nonyloxide), titanium tetra(n-propoxide), titanium tetrastearyloxide, and titanium tetrakis[bis{2,2-(aryloxymethyl)butoxide}].

III) Titanocene compounds: examples thereof include pentamethylcyclopentadienyl titanium trimethoxide, bis(i5-2,4-cyclopentadien-1-yl)bis(2,6-difluorophenyl)titanium, and bis(η5-2,4-cyclopentadien-1-yl)bis(2,6-difluoro-3-(1H-pyrrol-1-yl)phenyl)titanium.

IV) Monoalkoxytitanium compounds: examples thereof include titanium tris(dioctyl phosphate)isopropoxide, and titanium tris(dodecylbenzene sulfonate)isopropoxide.

V) Titanium oxide compounds: examples thereof include titanium oxide bis(pentanedionate), titanium oxide bis(tetramethylheptandionate), and phthalocyanine titanium oxide.

VI) Titanium tetraacetylacetonate compounds: examples thereof include titanium tetraacetylacetonate.

VII) Titanate coupling agents: examples thereof include isopropyltridodecylbenzenesulfonyl titanate.

Among these, it is preferable that the organic titanium compound is at least one compound selected from the group consisting of the above-described I) titanium chelate compound, II) tetraalkoxytitanium compound, and III) titanocene compound, from the viewpoint of more favorable chemical resistance. In particular, titanium diisopropoxide bis(ethyl acetoacetate), titanium tetra(n-butoxide), or bis(η5-2,4-cyclopentadiene-1-yl) bis(2,6-difluoro-3-(1H-pyrrole-1-yl)phenyl)titanium is preferable.

In addition, it is also preferable that a compound represented by Formula (T-1) is contained as the organic titanium compound or instead of the organic titanium compound.

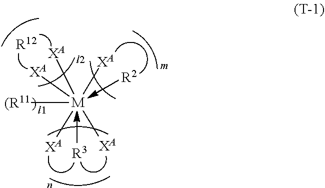

In Formula (T-1), M is titanium, zirconium, or hafnium, 11 is an integer of 0 to 2, 12 is 0 or 1, 11+12×2 is an integer of 0 to 2, m is an integer of 0 to 4, n is an integer of 0 to 2, 11+12+m+n×2=4 is satisfied, R¹¹ 's are each independently a substituted or unsubstituted cyclopentadienyl group, a substituted or unsubstituted alkoxy group, or a substituted or unsubstituted phenoxy group, R¹² is a substituted or unsubstituted hydrocarbon group, R²'s are each independently a group including a structure represented by Formula (T-2), R³'s are each independently a group including a structure represented by Formula (T-2), and X^{A}'s are each independently an oxygen atom or a sulfur atom.

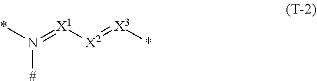

In Formula (T-2), X¹ to X³ each independently represent —C(—*)= or —N=, *'s each represent a bonding site to another structure, and #represents a bonding site to a metal atom.

In Formula (T-1), it is preferable that M represents titanium from the viewpoint of the storage stability of the composition.

An aspect in which 11 and 12 in Formula (T-1) are 0 is also one of the preferred aspects of the present invention.

In Formula (T-1), m is preferably 2 or 4, and more preferably 2.

In Formula (T-1), n is preferably 1 or 2, and more preferably 1.

Here, in Formula (T-1), it is also preferable that 11 and 12 are 0 and m is 0, 2, or 4.

In Formula (T-1), R¹¹ is preferably a substituted or unsubstituted cyclopentadienyl ligand from the viewpoint of the stability of the specific metal complex.

In addition, the cyclopentadienyl group, the alkoxy group, and the phenoxy group as R¹¹ may be substituted; however, an aspect in which these are unsubstituted is also one of the preferred aspects of the present invention.

In Formula (T-1), R¹² is preferably a hydrocarbon group having 1 to 20 carbon atoms and more preferably a hydrocarbon group having 2 to 10 carbon atoms.

The hydrocarbon group as R¹² may be any of an aliphatic hydrocarbon group or an aromatic hydrocarbon group; however, it is preferably an aromatic hydrocarbon group.

The aliphatic hydrocarbon group may be a saturated aliphatic hydrocarbon group or an unsaturated aliphatic hydrocarbon group; however, it is preferably a saturated aliphatic hydrocarbon group.

The aromatic hydrocarbon group is preferably an aromatic hydrocarbon group having 6 to 20 carbon atoms, more preferably an aromatic hydrocarbon group having 6 to 10 carbon atoms, and still more preferably a phenylene group.

The substituent as R¹² is preferably a monovalent substituent, and examples thereof include a halogen atom. In addition, in a case where R¹² is an aromatic hydrocarbon group, it may have an alkyl group as a substituent.

Among these, in Formula (T-1), R¹² is preferably an unsubstituted phenylene group. In addition, the phenylene group as R¹² is preferably a 1,2-phenylene group.

In Formula (T-1), in a case where m is 2 or more and two or more R²'s contained, the structures of the two or more R²'s may be the same or different from each other.

In Formula (T-1), in a case where n is 2 or more and two or more R³'s contained, the structures of the two or more R³'s may be the same or different from each other.

In Formula (T-2), X¹ to X³ each independently represent —C(—*)═ or —N=. It is preferable that at least one thereof represents —C(—*)=, and it is more preferable that at least two thereof represent —C(—*)=.

Specific examples of the compound represented by Formula (T-1) include compounds corresponding to I-5 to I-8 in Examples, but the present invention is not limited thereto.

In a case of containing an organic titanium compound, the content thereof is preferably 0.05 to 10 parts by mass and more preferably 0.1 to 5 parts by mass with respect to 100 parts by mass of the specific resin. In a case where the content thereof is 0.05 parts by mass or more, the heat resistance and the chemical resistance of the cured pattern to be obtained are further improved, and in a case where the content thereof is 10 parts by mass or less, the storage stability of the composition is more excellent.

In a case of containing an organic titanium compound, the content thereof is preferably 0.05 to 10 parts by mass and more preferably 0.1 to 2 parts by mass with respect to 100 parts by mass of the specific resin. In a case where the content thereof is 0.05 parts by mass or more, the heat resistance and the chemical resistance of the cured pattern to be obtained are further improved, and in a case where the content thereof is 10 parts by mass or less, the storage stability of the composition is more excellent.

Examples of the other additives include the compounds described in paragraphs 0316 to 0358 of WO2022/145355A. The above description is incorporated in the present specification.

### <Characteristics of Resin Composition>

The viscosity of the resin composition according to the embodiment of the present invention can be adjusted by adjusting the concentration of solid contents of the resin composition. From the viewpoint of the coating film thickness, it is preferably 1,000 mm²/s to 12,000 mm²/s, more preferably 2,000 mm²/s to 10,000 mm²/s, and still more preferably 2,500 mm²/s to 8,000 mm²/s. Within the above range, it is easy to obtain a coating film having high uniformity. In a case of being 1,000 mm²/s or more, it is easy to carry out coating at a film thickness to be required as, for example, an insulating film for re-distribution of a wiring line, and in a case of being 12,000 mm²/s or less, a coating film having an excellent coating surface shape is obtained.

### <Restrictions on Substances Contained in Resin Composition>

The moisture content of the resin composition according to the embodiment of the present invention is preferably less than 2.0% by mass, more preferably less than 1.5% by mass, and still more preferably less than 1.0% by mass. In a case of being less than 2.0%, the storage stability of the resin composition is improved.

Examples of the method of maintaining the moisture content include adjusting the humidity under storage conditions and reducing the void ratio of the storage container during storage.

From the viewpoint of insulating properties, the metal content of the resin composition according to the embodiment of the present invention is preferably less than 5 parts per million (ppm) by mass, more preferably less than 1 ppm by mass, and still more preferably less than 0.5 ppm by mass. Examples of the metal include sodium, potassium, magnesium, calcium, iron, copper chromium, and nickel, however, a metal contained as a complex of an organic compound and a metal is excluded. In a case where a plurality of metals are contained, the total of these metals is preferably within the above-described range.

In addition, as a method of reducing metal impurities which are unintentionally contained in the resin composition according to the embodiment of the present invention, a method of selecting a raw material containing a low metal content as the raw material that constitutes the resin composition according to the embodiment of the present invention, a method of filtering a raw material constituting the resin composition according to the embodiment of the present invention, a method of distilling under the conditions in which the inside of the device is lined with polytetrafluoroethylene or the like to suppress the contamination as little as possible, and the like can be mentioned.

In the resin composition according to the embodiment of the present invention, in a case of considering the use application as a semiconductor material, the content of halogen atoms is preferably less than 500 ppm by mass, more preferably less than 300 ppm by mass, and still more preferably less than 200 ppm by mass, from the viewpoint of wire corrosiveness. Among these, in a case of being present in a halogen ion state, the content is preferably less than 5 ppm by mass, more preferably less than 1 ppm by mass, and still more preferably less than 0.5 ppm by mass. Examples of the halogen atom include a chlorine atom and a bromine atom. It is preferable that the total content of the chlorine atom and the bromine atom, or the total content of the chlorine ion and the bromine ion is within the above-described range.

Preferred examples of the method of adjusting the content of halogen atoms include ion exchange treatment.

A storage container publicly known in the related art can be used as a storage container for the resin composition according to the embodiment of the present invention. As the storage container, for the intended purpose of suppressing the incorporation of impurities into the raw materials and the resin composition according to the embodiment of the present invention, a multilayer bottle in which an inner wall of a container is composed of six kinds of six layers of resin, and a bottle with six kinds of resin being made as a seven-layer structure are preferably used. Examples of such a container include the container described in JP2015-123351A.

### <Cured Substance of Resin Composition>

In a case of curing the resin composition according to the embodiment of the present invention, it is possible to obtain a cured substance of the resin composition.

The cured substance according to the embodiment of the present invention is a cured substance formed by curing the resin composition.

The curing of the resin composition is preferably carried out by heating. The heating temperature is more preferably 120° C. to 400° C., still more preferably 140° C. to 380° C., and particularly preferably 170° C. to 350° C. The form of the cured substance of the resin composition is not particularly limited and can be selected depending on the use application, where the form includes a film shape, a rod shape, a spherical shape, a pellet shape, and the like. In the present invention, the cured substance preferably has a film shape. The shape of the cured substance can also be selected depending on the use application by the pattern processing of the resin composition, where the use application includes the formation of a protective film on a wall surface, formation of via holes for conduction, adjustment of impedance, electrostatic capacity, or internal stress, impartment of heat radiation function, and the like. The film thickness of the cured substance (the film consisting of the cured substance) is preferably 0.5 μm or more and 150 μm or less.

The shrinkage ratio of the resin composition according to the embodiment of the present invention after curing is preferably 50% or less, more preferably 45% or less, and still more preferably 40% or less. Here, the shrinkage ratio refers to a percentage of a change in the volume of the resin composition before and after curing, and it can be calculated according to the following expression.

Shrinkage ratio [%]=100−(volume after curing/volume before curing)×100

### <Characteristics of Cured Substance of Resin Composition>

The imidization reaction rate of the cured substance of the resin composition according to the embodiment of the present invention is preferably 70% or more, more preferably 80% or more, and still more preferably 90% or more. In a case of being 70% or more, a cured substance having excellent mechanical properties may be obtained.

The breaking elongation of the cured substance of the resin composition according to the embodiment of the present invention is preferably 30% or more, more preferably 40% or more, and still more preferably 50% or more.

The glass transition temperature (Tg) of the cured substance of the resin composition according to the embodiment of the present invention is preferably 180° C. or higher, more preferably 210° C. or higher, and still more preferably 230° C. or higher.

### <Preparation of Resin Composition>

The resin composition according to the embodiment of the present invention can be prepared by mixing the above-described components. The mixing method is not particularly limited, and mixing can be carried out by methods publicly known in the related art.

Examples of the mixing method include mixing with a stirring blade, mixing with a ball mill, and mixing by rotating a tank.

The temperature during the mixing is preferably 10° C. to 30° C., and more preferably 15° C. to 25° C.

It is preferable to carry out filtration using a filter for the intended purpose of removing foreign substances such as dust and fine particles in the resin composition according to the embodiment of the present invention. The filter pore diameter is, for example, preferably 5 μm or less, more preferably 1 μm or less, still more preferably 0.5 μm or less, and even still more preferably 0.1 μm or less. The material of the filter is preferably polytetrafluoroethylene, polyethylene, or nylon. In a case where the material of the filter is polyethylene, it is more preferable to use high density polyethylene (HDPE). As the filter, a filter which has been washed with an organic solvent in advance may be used. In the filtration step using the filter, a plurality of kinds of filters may be connected in series or in parallel and used. In a case where a plurality of kinds of filters are used, filters having different pore diameters or different materials may be used in combination. Examples of the connection aspect include an aspect in which an HDPE filter having a pore diameter of 1 μm is connected in series as the first stage and an HDPE filter having a pore diameter of 0.2 μm is connected in series as the second stage. In addition, various materials may be filtered a plurality of times. In a case of being filtered a plurality of times, circulation filtration may be used. In addition, filtration may be carried out under pressure. In a case of carrying out pressurization to carry out filtration, the pressure for pressurization is, for example, preferably 0.01 MPa or more and 1.0 MPa or less, more preferably 0.03 MPa or more and 0.9 MPa or less, still more preferably 0.05 MPa or more and 0.7 MPa or less, and even still more preferably 0.05 MPa or more and 0.5 MPa or less.

In addition to filtration using a filter, impurity removal treatment using an adsorbing material may be carried out. The filtration using a filter and the impurity removal treatment using an adsorbing material may be combined. As the adsorbing material, a publicly known adsorbing material can be used. Examples thereof include an inorganic adsorbing material such as silica gel and zeolite and an organic adsorbing material such as activated carbon.

After filtration using a filter, a step of placing a bottle filled with the resin composition under reduced pressure to carry out degassing may be provided.

### (Manufacturing Method for Cured Substance)

The manufacturing method for a cured substance according to the embodiment of the present invention preferably includes a film forming step of applying a resin composition onto a base material to form a film.

The manufacturing method for a cured substance more preferably includes the above-described film forming step, an exposure step of selectively exposing the film formed by the film forming step, and a development step of developing the film exposed by the exposure step using a developer to form a pattern.

It is particularly preferable that the manufacturing method for a cured substance includes the film forming step, the exposure step, the development step, and at least one of a heating step of heating a pattern obtained by the development step or a post-development exposure step of exposing the pattern obtained by the development step.

In addition, it is also preferable that the manufacturing method for a cured substance includes the above-described film forming step and a step of heating the film.

Hereinafter, details of each step will be described.

### <Film Forming Step>

The resin composition according to the embodiment of the present invention can be applied onto a base material, thereby being used in a film forming step of forming a film.

The manufacturing method for a cured substance according to the embodiment of the present invention preferably includes a film forming step of applying a resin composition onto a base material to form a film.

### [Base Material]

The kind of the base material can be appropriately determined depending on the use application and is not particularly limited. Examples of the base material include a base material for semiconductor production, such as silicon, silicon nitride, polysilicon, silicon oxide, or amorphous silicon, quartz, glass, an optical film, a ceramic material, a vapor-deposited film, a magnetic film, a reflective film, a metal base material (for example, it may be any one of a base material formed from a metal or a base material having a metal layer formed by plating, vapor deposition, or the like) such as Ni, Cu, Cr, or Fe, paper, spin-on-glass (SOG), a thin film transistor (TFT) array base material, a mold base material, and an electrode plate of a plasma display panel (PDP). In particular, the base material is preferably a base material for semiconductor production, and more preferably a silicon base material, a Cu base material, or a mold base material.

A layer such as an intimate attachment layer made of hexamethyl disilazane (HMDS) or the like, or an oxide layer may be provided on the surface of these base materials.

The shape of the base material is not particularly limited, and it may be a circular shape or may be a rectangular shape.

In a case where the base material has a circular shape, the size of the base material is, for example, preferably a diameter of 100 to 450 mm and more preferably 200 to 450 mm. In a case of a rectangular shape, the length of the short side is, for example, preferably 100 to 1,000 mm and more preferably 200 to 700 mm.

As the base material, for example, a base material having a plate shape and preferably a base material (a substrate) having a panel shape are used.

In a case where the resin composition is applied to form a film on a surface of a resin layer (for example, a layer consisting of a cured substance) or on a surface of a metal layer, the resin layer or the metal layer serves as the base material.

The means for applying the resin composition onto a base material is preferably coating.

Specific examples of the means for application include a dip coating method, an air knife coating method, a curtain coating method, a wire bar coating method, a gravure coating method, an extrusion coating method, a spray coating method, a spin coating method, a slit coating method, and an ink jet method. From the viewpoint of the uniformity of the film thickness, a spin coating method, a slit coating method, a spray coating method, or an ink jet method is more preferable, and from the viewpoint of the uniformity of the film thickness and the viewpoint of productivity, a spin coating method or a slit coating method is more preferable. A film having a desired thickness can be obtained by adjusting the concentration of solid contents of the resin composition and application conditions according to the means to be applied. In addition, the coating method can be appropriately selected depending on the shape of the base material. In a case where a circular base material such as a wafer is used, a spin coating method, a spray coating method, an ink jet method, or the like is preferable, and in a case where a rectangular base material is used, a slit coating method, a spray coating method, an ink jet method, or the like is preferable. For example, the spin coating method can be applied at a rotation speed of 500 to 3,500 rpm for about 10 seconds to 3 minutes.

In addition, it is also possible to apply a method of transferring a coating film formed in advance on a temporary support by the above-described coating method, onto a base material.

Regarding the transfer method, the production methods described in paragraphs 0023 and 0036 to 0051 of JP2006-023696A and paragraphs 0096 to 0108 of JP2006-047592A can also be suitably used.

In addition, a step of removing an unnecessary film at the end part of the base material may be carried out. Examples of such a step include edge bead rinsing (EBR) and back rinsing.

A pre-wetting step of applying various solvents onto the base material before applying the resin composition onto the base material to improve the wettability of the base material and then applying the resin composition may be adopted.

### <Drying Step>

The above film may be subjected to a step (a drying step) of drying the film (or the layer) formed for removing the solvent, after the film forming step (the layer forming step).

That is, the manufacturing method for a cured substance according to the embodiment of the present invention may include a drying step of drying the film formed by the film forming step.

It is preferable that the drying step is carried out after the film forming step and before the exposure step.

The drying temperature of the film in the drying step is preferably 50° C. to 150° C., more preferably 70° C. to 130° C., and still more preferably 90° C. to 110° C. In addition, the drying may be carried out by reducing the pressure. Examples of the drying time include 30 seconds to 20 minutes, and the drying time is preferably 1 minute to 10 minutes and more preferably 2 minutes to 7 minutes.

### <Exposure Step>

The film may be subjected to an exposure step of selectively exposing the film.

The manufacturing method for a cured substance may include an exposure step of selectively exposing the film formed by the film forming step.

The selective exposure means that a part of the film is exposed. In addition, by selectively exposing the film, an exposed region (an exposed portion) and an unexposed region (a non-exposed portion) are formed in the film.

The exposure amount is not particularly limited as long as the resin composition according to the embodiment of the present invention can be cured; however, it is, for example, preferably 50 to 10,000 mJ/cm² and more preferably 200 to 8,000 mJ/cm² in terms of conversion of exposure energy at a wavelength of 365 nm.

The exposure wavelength can be appropriately determined in a range of 190 to 1,000 nm and preferably in a range of 240 to 550 nm.

Examples of the exposure wavelength, which are mentioned in the relationship with the light source, include (1) a semiconductor laser (wavelength: 830 nm, 532 nm, 488 nm, 405 nm, 375 nm, 355 nm, or the like); (2) a metal halide lamp; (3) a high pressure mercury lamp, a g-line (wavelength: 436 nm), an h-line (wavelength: 405 nm), an i-line (wavelength: 365 nm), or broadband light (three wavelengths of the g, h, and i-line); (4) an excimer laser, a KrF excimer laser (wavelength: 248 nm), an ArF excimer laser (wavelength: 193 nm), or an F₂ excimer laser (wavelength: 157 nm); (5) an extreme ultraviolet ray: EUV (wavelength: 13.6 nm); (6) an electron beam; and (7) a second harmonic wave of 532 nm and a third harmonic wave of 355 nm of a YAG laser. Regarding the resin composition according to the embodiment of the present invention, exposure with a high pressure mercury lamp is particularly preferable, and from the viewpoint of exposure sensitivity, exposure with an i-line is more preferable.

The exposure method is not particularly limited as long as at least a part of the film consisting of the resin composition according to the embodiment of the present invention is exposed; however, examples thereof include exposure using a photo mask and exposure by a laser direct imaging method.

### <Post-Exposure Heating Step>

The film may be subjected to a step of carrying out heating after the exposure (a post-exposure heating step).

That is, the manufacturing method for a cured substance according to the embodiment of the present invention may include a post-exposure heating step of heating the film exposed in the exposure step.

The post-exposure heating step can be carried out after the exposure step and before the development step.

The heating temperature in the post-exposure heating step is preferably 50° C. to 140° C. and more preferably 60° C. to 120° C.

The heating time in the post-exposure heating step is preferably 30 seconds to 300 minutes and more preferably 1 minute to 10 minutes.

In the post-exposure heating step, the temperature rising rate from the temperature at the start of heating to the maximum heating temperature is preferably 1 to 12° C./min, more preferably 2 to 10° C./min, and still more preferably 3 to 10° C./min.

In addition, the temperature rising rate may be appropriately changed during heating.

The heating means in the post-exposure heating step is not particularly limited, and a publicly known hot plate, oven, infrared heater, or the like can be used.

In addition, it is also preferable to carry out the heating in an atmosphere having a low oxygen concentration by allowing an inert gas such as nitrogen, helium, argon, or the like to flow.

### <Development Step>

The exposed film may be subjected to a development step of carrying out development using a developer to form a pattern.

That is, the manufacturing method for a cured substance according to the embodiment of the present invention may include a development step of developing the film exposed in the exposure step using a developer to form a pattern.

By carrying out the development, one of the exposed portion and the non-exposed portion of the film is removed, and a pattern is formed.

Here, the development in which the non-exposed portion of the film is removed by the development step is referred to as negative-tone development, and the development in which the exposed portion of the film is removed by the development step is referred to as positive-tone development.

### [Developer]

Examples of the developer that is used in the development step include a developer containing an alkaline aqueous solution or an organic solvent.

In a case where the developer is an alkaline aqueous solution, examples of the basic compound that can be contained in the alkaline aqueous solution include inorganic alkalis, primary amines, secondary amines, tertiary amines, and a quaternary ammonium salt. The basic compound is preferably tetramethylammonium hydroxide (TMAH), potassium hydroxide, sodium carbonate, sodium hydroxide, sodium silicate, sodium metasilicate, ammonia, ethylamine, n-propylamine, diethylamine, di-n-butylamine, triethylamine, methyldiethylamine, dimethylethanolamine, triethanolamine, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, dibutyldipentylammonium hydroxide, dimethylbis(2-hydroxyethyl)ammonium hydroxide, trimethylphenylammonium hydroxide, trimethylbenzylammonium hydroxide, triethylbenzylammonium hydroxide, pyrrole, or piperidine, and it is more preferably TMAH. The content of the basic compound in the developer is preferably 0.01% to 10% by mass, more preferably 0.1% to 5% by mass, and still more preferably 0.3% to 3% by mass in the total mass of the developer.

In a case where the developer contains an organic solvent, the compounds described in paragraph 0387 of WO2021/112189A can be used as the organic solvent. The content thereof is incorporated in the present specification. In addition, suitable examples of the alcohols include methanol, ethanol, propanol, isopropanol, butanol, pentanol, octanol, diethylene glycol, propylene glycol, methyl isobutyl carbinol, and triethylene glycol, and suitable examples of the amides include N-methylpyrrolidone, N-ethylpyrrolidone, and dimethylformamide.

In a case where the developer contains an organic solvent, one kind of organic solvent can be used, or two or more kinds thereof can be mixedly used. In the present invention, in particular, a developer containing at least one selected from the group consisting of cyclopentanone, γ-butyrolactone, dimethyl sulfoxide, N-methyl-2-pyrrolidone, and cyclohexanone is preferable, a developer containing at least one selected from the group consisting of cyclopentanone, γ-butyrolactone, and dimethyl sulfoxide is more preferable, and a developer containing cyclopentanone is particularly preferable.

In a case where the developer contains an organic solvent, the content of the organic solvent with respect to the total mass of the developer is preferably 50% by mass or more, more preferably 70% by mass or more, still more preferably 80% by mass or more, and particularly preferably 90% by mass or more. In addition, the above content may be 100% by mass.

The developer may further contain another component.

Examples of the other component include a publicly known surfactant and a publicly known anti-foaming agent.

### [Method of Supplying Developer]

The method of supplying a developer is not particularly limited as long as a desired pattern can be formed, and it includes a method of immersing a base material on which a film has been formed in a developer, puddle development of supplying a developer to a film formed on a base material using a nozzle, and a method of continuously supplying a developer. The kind of nozzle is not particularly limited, and examples thereof include a straight nozzle, a shower nozzle, and a spray nozzle.

From the viewpoint of the permeability of the developer, the removability of the non-image area, and the manufacturing efficiency, a method of supplying a developer with a straight nozzle or a method of continuously supplying a developer with a spray nozzle is preferable, and from the viewpoint of the permeability of the developer into the image area, a method of supplying a developer with a spray nozzle is more preferable.

In addition, after the continuous supply by a straight nozzle, the base material is spun to remove the developer from the base material, and then the developer is continuously supplied by the straight nozzle again after the spin drying, a step of spinning the base material to remove the developer from the base material may be adopted, and this step may be repeated a plurality of times.

Examples of the method of supplying a developer in the development step include a step of continuously supplying a developer to a base material, a step of keeping a developer in a substantially stationary state on a base material, a step of vibrating a developer on a base material by ultrasonic waves or the like, and a step obtained by combining these steps.

The development time is preferably 10 seconds to 10 minutes and more preferably 20 seconds to 5 minutes. The temperature of the developer during development is not particularly determined; however, it is preferably 10° C. to 45° C. and more preferably 18° C. to 30° C.

In the development step, washing (rinsing) of the pattern with a rinsing liquid may be further carried out after the treatment with the developer. In addition, a method such as supplying a rinsing liquid before the developer which is in contact with the pattern is completely dried may be adopted.

### [Rinsing Liquid]

In a case where the developer is an alkaline aqueous solution, it is possible to use, for example, water as the rinsing liquid. In a case where the developer is a developer containing an organic solvent, it is possible to use as the rinsing liquid, for example, a solvent (for example, water, an organic solvent different from the organic solvent contained in the developer) different from the solvent contained in the developer.

Examples of the organic solvent in a case where the rinsing liquid contains an organic solvent include the same organic solvents as the organic solvents exemplified in the above-described case where the developer contains an organic solvent.

The organic solvent contained in the rinsing liquid is preferably an organic solvent different from the organic solvent contained in the developer, and it is more preferably an organic solvent having a solubility of the pattern, which is lower than that of the organic solvent contained in the developer.

In a case where the rinsing liquid contains an organic solvent, one kind of organic solvent can be used, or two or more kinds thereof can be mixedly used. The organic solvent is preferably cyclopentanone, γ-butyrolactone, dimethyl sulfoxide, N-methylpyrrolidone, cyclohexanone, PGMEA, or PGME, more preferably cyclopentanone, γ-butyrolactone, dimethyl sulfoxide, PGMEA, or PGME, and still more preferably cyclohexanone or PGMEA.

In a case where the rinsing liquid contains an organic solvent, the organic solvent is preferably 50% by mass or more, more preferably 70% by mass or more, and still more preferably 90% by mass or more with respect to the total mass of the rinsing liquid. In addition, the organic solvent may be 100% by mass with respect to the total mass of the rinsing liquid.

The rinsing liquid may further contain another component.

Examples of the other component include a publicly known surfactant and a publicly known anti-foaming agent.

### [Method of Supplying Rinsing Liquid]

The method of supplying a rinsing liquid is not particularly limited as long as a desired pattern can be formed and includes a method of immersing a base material in a rinsing liquid, a method of supplying a rinsing liquid to a base material by liquid filling, a method of supplying a rinsing liquid to a base material with a shower, and a method of continuously supplying a rinsing liquid to a base material by means such as a straight nozzle.

From the viewpoint of the permeability of the rinsing liquid, the removability of non-image area, and the manufacturing efficiency, there is a method of supplying a rinsing liquid with a shower nozzle, a straight nozzle, a spray nozzle, or the like, and a method of continuously supplying a rinsing liquid with a spray nozzle is preferable. From the viewpoint of the permeability of the rinsing liquid into the image area, a method of supplying a rinsing liquid with a spray nozzle is more preferable. The kind of nozzle is not particularly limited, and examples thereof include a straight nozzle, a shower nozzle, and a spray nozzle.

That is, the rinsing step is preferably a step of supplying, with a straight nozzle, or continuously supplying a rinsing liquid to the exposed film, and it is more preferably a step of supplying a rinsing liquid with a spray nozzle.

In the method of supplying a rinsing liquid in the rinsing step, a step of continuously supplying a rinsing liquid to a base material, a step of keeping a rinsing liquid in a substantially stationary state on a base material, a step of vibrating a rinsing liquid on the base material by ultrasonic waves or the like, and a step obtained by combining these steps can be adopted.

The rinsing time is preferably 10 seconds to 10 minutes and more preferably 20 seconds to 5 minutes. The temperature of the rinsing liquid during rinsing is not particularly determined; however, it is preferably 10° C. to 45° C. and more preferably 18° C. to 30° C.

### <Heating Step>

The pattern obtained by the development step (a pattern after the rinsing in a case where the rinsing step is carried out) may be subjected to a heating step of heating the pattern obtained by the development.

That is, the manufacturing method for a cured substance according to the embodiment of the present invention may include a heating step of heating the pattern obtained by the development step.

In addition, the manufacturing method for a cured substance according to the embodiment of the present invention may include a pattern obtained by another method without carrying out the development step, or a heating step of heating a film obtained by the film forming step.

In the heating step, the resin such as the polyimide precursor is cyclized to be a resin such as polyimide.

In addition, the crosslinking of unreacted crosslinkable groups in the specific resin or a crosslinking agent other than the specific resin also proceeds.

The heating temperature (the maximum heating temperature) in the heating step is preferably 50° C. to 450° C., more preferably 150° C. to 350° C., still more preferably 150° C. to 250° C., even still more preferably 160° C. to 250° C., and particularly preferably 160° C. to 230° C.

The heating step is preferably a step of accelerating the cyclization reaction of the polyimide precursor in the pattern under the action of the base or the like generated from the base generator by heating.

The heating in the heating step is preferably carried out at a temperature rising rate of 1 to 12° C./min from the temperature at the start of heating to the maximum heating temperature. The temperature rising rate is more preferably 2 to 10° C./min and still more preferably 3 to 10° C./min. In a case where the above temperature rising rate is set to 1° C./min or higher, the excessive volatilization of the acid or solvent can be prevented while securing productivity, and in a case where the above temperature rising rate is to 12° C./min or lower, the residual stress of the cured substance can be relaxed.

In addition, in a case of an oven that enables rapid heating, the heating is preferably carried out at a temperature rising rate of 1 to 8° C./sec from the temperature at the start of heating to the maximum heating temperature, more preferably 2 to 7° C./sec, and still more preferably 3 to 6° C./sec.

The temperature at the start of heating is preferably 20° C. to 150° C., more preferably 20° C. to 130° C., and still more preferably 25° C. to 120° C. The temperature at the start of heating refers to a temperature at which the step of heating to the maximum heating temperature is started. For example, in a case where the resin composition according to the embodiment of the present invention is applied on a base material and then dried, the temperature at the start of heating is the temperature of the film (the layer) after drying, and for example, it is preferable to raise the temperature from a temperature lower by 30° C. to 200° C. than the boiling point of the solvent contained in the resin composition.

The heating time (the heating time at the maximum heating temperature) is preferably 5 to 360 minutes, more preferably 10 to 300 minutes, and still more preferably 15 to 240 minutes.

In particular, in a case of forming a multilayered laminate, the heating temperature is preferably 30° C. or higher, more preferably 80° C. or higher, still more preferably 100° C. or higher, and particularly preferably 120° C. or higher, from the viewpoint of adhesiveness between layers.

The upper limit of the heating temperature is preferably 350° C. or lower, more preferably 250° C. or lower, and still more preferably 240° C. or lower.

The heating may be carried out stepwise. For example, a step in which the temperature is raised from 25° C. to 120° C. at 3° C./min, held at 120° C. for 60 minutes, raised from 120° C. to 180° C. at 2° C./min, and held at 180° C. for 120 minutes, may be carried out. In addition, it is also preferable to carry out the treatment while carrying out irradiation with ultraviolet rays as described in U.S. Pat. No. 9,159,547B. By such a pretreatment step, it is possible to improve the properties of the film. The pretreatment step may be carried out for a short time of about 10 seconds to 2 hours and more preferably 15 seconds to 30 minutes. The pretreatment step may be carried out as a step of two or more stages, for example, a first stage pretreatment step may be carried out in a range of 100° C. to 150° C., and then a second stage pretreatment step may be carried out in a range of 150° C. to 200° C.

Further, cooling may be carried out after heating, and the cooling rate, in this case, is preferably 1 to 5° C./min.

From the viewpoint of preventing the decomposition of the specific resin, it is preferable that the heating step is carried out in an atmosphere of a low oxygen concentration, for example, by allowing an inert gas such as nitrogen, helium, argon, or the like to flow, or carrying out heating under reduced pressure. The oxygen concentration is preferably 50 ppm (volume ratio) or lower, and more preferably 20 ppm (volume ratio) or lower.

The heating means in the heating step is not particularly limited; however, examples thereof include a hot plate, an infrared furnace, an electric heating oven, a hot air oven, and an infrared oven.

### <Post-Development Exposure Step>

The pattern obtained by the development step (a pattern after the rinsing in a case where the rinsing step is carried out) may be subjected to a post-development exposure step of exposing the pattern after the development step, instead of the heating step or in addition to the heating step.

That is, the manufacturing method for a cured substance according to the embodiment of the present invention may include a post-development exposure step of exposing the pattern obtained by the development step. The manufacturing method for a cured substance according to the embodiment of the present invention may include the heating step and the post-development exposure step or may include only one of the heating step and the post-development exposure step.

In the post-development exposure step, it is possible to accelerate, for example, a reaction in which the cyclization of a polyimide precursor or the like proceeds by photosensitization of a photobase generator, a reaction in which the elimination of an acid-decomposable group proceeds by photosensitization of a photoacid generator.

In the post-development exposure step, it is sufficient that at least a part of the pattern obtained in the development step is exposed; however, it is preferable that the whole of the above pattern is exposed.

The exposure amount in the post-development exposure step is preferably 50 to 20,000 mJ/cm² and more preferably 100 to 15,000 mJ/cm² in terms of conversion of exposure energy at the wavelength at which the photosensitive compound has a sensitivity.

The post-development exposure step can be carried out using, for example, the light source in the above-described exposure step, and it is preferable to use broadband light.

### <Metal Layer Forming Step>

The pattern (preferably a pattern that has been subjected to at least one of the heating step or the post-development exposure step) obtained by the development step may be subjected to a metal layer forming step of forming a metal layer on the pattern.

That is, it is preferable that the manufacturing method for a cured substance according to the embodiment of the present invention includes a metal layer forming step of forming a metal layer on the pattern (preferably a pattern that has been subjected to at least one of the heating step or the post-development exposure step) obtained by the development step.

For the metal layer, existing metal kinds can be used without particular limitations. Examples thereof include copper, aluminum, nickel, vanadium, titanium, chromium, cobalt, gold, tungsten, tin, silver, and an alloy including these metals, where copper or aluminum is more preferable, and copper is still more preferable.

The forming method for the metal layer is not particularly limited, and the existing method can be applied. For example, the methods described in JP2007-157879A, JP2001-521288A, JP2004-214501A, JP2004-101850A, U.S. Pat. No. 7,888,181B2, and U.S. Pat. No. 9,177,926B2 can be used. For example, photolithography, physical vapor deposition method (PVD), chemical vapor phase growth method (CVD), lift-off, electrolytic plating, electroless plating, etching, printing, and a method obtained by combining these may be conceivable. More specific examples of the forming method for the metal layer include a patterning method obtained by combining sputtering, photolithography, and etching, and a patterning method combining photolithography and electrolytic plating. Examples of the preferred aspect of the plating include electrolytic plating using a copper sulfate plating liquid or a copper cyanide plating liquid.

The thickness of the metal layer at the thickest portion is preferably 0.01 to 50 μm and more preferably 1 to 10 μm.

### <Use Application>

Examples of the field to which the manufacturing method for a cured substance according to the embodiment of the present invention or the cured substance according to the embodiment of the present invention can be applied include an insulating film of an electronic device, an interlayer insulating film for a re-distribution layer, and a stress buffer film. In addition, a sealing film, a substrate material (a base film or cover lay of a flexible print substrate, an interlayer insulating film), or such an insulating film in a use application for mounting as described above, which is patterned by etching, is mentioned. For these use applications, for example, Science & Technology Co., Ltd., “High functionality and applied technology of polyimide” April 2008, Technical library CMC TL “Basics and development of polyimide materials” supervised by Masaaki Kakimoto, published in November 2011, “Latest Polyimide Basics and Applications” edited by Japan Polyimide & Aromatic Polymers Study Group, NTS Inc., August 2010, or the like can be referred to.

The manufacturing method for a cured substance according to the embodiment of the present invention and the cured substance according to the embodiment of the present invention can also be used for the production of board surfaces such as an offset board surface or a screen board surface, for etching of molded parts, for the production of protective lacquers and dielectric layers in electronics, in particular, microelectronics.

### (Laminate and Manufacturing Method for Laminate)

A laminate according to the embodiment of the present invention refers to a structure body having a plurality of layers consisting of the cured substance according to the embodiment of the present invention.

The laminate is a laminate including two or more layers consisting of a cured substance, and it may be a laminate in which three or more layers are laminated.

At least one of the two or more layers consisting of a cured substance, which are included in the laminate, is a layer consisting of the cured substance according to the embodiment of the present invention, and from the viewpoint of suppressing the shrinkage of the cured substance, the deformation of the cured substance due to the shrinkage, or the like, it is also preferable that all the layers consisting of a cured substance which are included in the laminate are layers consisting of the cured substance according to the embodiment of the present invention.

That is, it is preferable that the manufacturing method for a laminate according to the embodiment of the present invention includes the manufacturing method for a cured substance according to the embodiment of the present invention, and it is more preferable to include repeating, a plurality of times, the manufacturing method for a cured substance according to the embodiment of the present invention.

In the laminate according to the embodiment of the present invention, an aspect in which two or more layers of layers consisting of a cured substance are included and a metal layer is provided between any of the layers consisting of the cured substance is preferable. The metal layer is preferably formed in the metal layer forming step.

That is, it is preferable that the manufacturing method for a laminate according to the embodiment of the present invention further includes a metal layer forming step of forming a metal layer on a layer consisting of the cured substance, between the manufacturing methods for a cured substance which are carried out a plurality of times. The preferred aspect of the metal layer forming step is as described above.

Examples of the preferred laminate include a laminate including at least a layer structure in which three layers of a layer consisting of a first cured substance, a metal layer, and a layer consisting of a second cured substance are laminated in order.

It is preferable that both the layer consisting of the first cured substance and the layer consisting of the second cured substance are layers consisting of the cured substance according to the embodiment of the present invention. The resin composition according to the embodiment of the present invention which is used for forming a layer consisting of the first cured substance and the resin composition according to the embodiment of the present invention which is used for forming a layer consisting of the second cured substance may have the same composition or may have compositions different from each other. The metal layer in the laminate according to the embodiment of the present invention is preferably used as the metal wiring line of the re-distribution layer or the like.

### <Laminating Step>

The manufacturing method for a laminate according to the embodiment of the present invention preferably further includes a laminating step.

The laminating step is a series of steps including carrying out again, in the following order on the surface of the pattern (the resin layer) or the metal layer, at least one of (a) the film forming step (the layer forming step), (b) the exposure step, (c) the development step, or (d) the heating step and the post-development exposure step. However, the aspect thereof may be such that at least one of (a) the film forming step or (d) the heating step and the post-development exposure step is repeated. In addition, (e) the metal layer forming step may be included after at least one of the heating step or the post-development exposure step of (d). It is needless to say that the laminating step may further include appropriately the above-described drying step or the like.

In a case where another laminating step is further carried out after the laminating step, a surface activation treatment step may be further carried out after the exposure step, the heating step, or the metal layer forming step. Examples of the surface activation treatment include plasma treatment. Details of the surface activation treatment will be described later.

The laminating step is preferably carried out 2 to 20 times and more preferably 2 to 9 times.

For example, a configuration having resin layers of 2 or more layers and 20 or fewer layers, such as a resin layer/a metal layer/a resin layer/a metal layer/a resin layer/a metal layer, is preferable, and a configuration having resin layers of 2 or more layers and 9 or fewer layers is still more preferable.

In the above layers, the compositions, shapes, film thicknesses, and the like may be the same or may be different from each other.

In the present invention, an aspect in which a metal layer is provided, and then furthermore, a cured substance (a resin layer) of the resin composition according to the embodiment of the present invention is formed to cover the metal layer is particularly preferable. Specific examples thereof include an aspect in which (a) the film forming step, (b) the exposure step, (c) the development step, (d) at least one of the heating step or the post-development exposure step, (e) the metal layer forming step are repeated in this order, and an aspect in which (a) the film forming step, (d) at least one of the heating step or the post-development exposure step, and (e) the metal layer forming step are repeated in order. By alternately carrying out the laminating step of laminating the resin composition layer (the resin layer) according to the embodiment of the present invention and the metal layer forming step, the resin composition layer (the resin layer) according to the embodiment of the present invention and the metal layer can be alternately laminated.

### (Surface Activation Treatment Step)

The manufacturing method for a laminate according to the embodiment of the present invention preferably includes a surface activation treatment step of subjecting at least a part of the metal layer or a part of the resin composition layer to a surface activation treatment.

The surface activation treatment step is usually carried out after the metal layer forming step (preferably, after at least one of the heating step or the post-development exposure step). However, after the development step, the metal layer forming step may be carried out after the resin composition layer is subjected to the surface activation treatment step.

Only at least a part of the metal layer may be subjected to the surface activation treatment, only at least a part of the resin composition layer after the exposure may be subjected to the surface activation treatment, or both at least a part of the metal layer and at least a part of the resin composition layer after the exposure may be subjected to the surface activation treatment. It is preferable to carry out the surface activation treatment on at least a part of the metal layer, and it is preferable to carry out the surface activation treatment on a part or whole of the region of the metal layer having a surface on which the resin composition layer is formed. In a case where a surface of the metal layer is subjected to the surface activation treatment in this manner, it is possible to improve the adhesiveness to the resin composition layer (film) to be provided on the surface thereof.

It is preferable that the surface activation treatment is carried out on a part or whole of the resin composition layer (the resin layer) after the exposure. In a case where a surface of the resin composition layer is subjected to the surface activation treatment in this manner, it is possible to improve the adhesiveness to a metal layer or a resin layer to be provided on the surface that has been subjected to the surface activation treatment. In particular, in a case where the resin composition layer is cured, such as in a case where negative-tone development is carried out, it is less likely to be damaged by the surface treatment, and thus the adhesiveness is likely to be improved.

The surface activation treatment can be carried out, for example, according to the method described in paragraph 0415 of WO2021/112189A. The content thereof is incorporated in the present specification.

### (Semiconductor Device and Manufacturing Method Therefor)

The present invention also discloses a semiconductor device, which includes the cured substance according to the embodiment of the present invention or the laminate.

In addition, the present invention also discloses a manufacturing method for a semiconductor device, which includes the manufacturing method for a cured substance according to the embodiment of the present invention or the manufacturing method for a laminate according to the embodiment of the present invention.

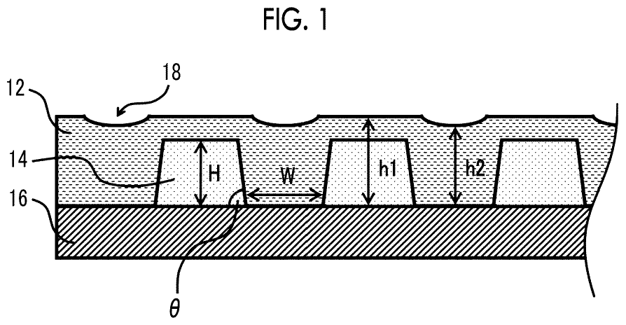

As the specific examples of the semiconductor device using the resin composition according to the embodiment of the present invention for forming an interlayer insulating film for a re-distribution layer, the description in paragraphs 0213 to 0218 and the description of FIG. 1 of JP2016-027357A can be referred to, the content of which is incorporated in the present specification.

### EXAMPLES

Hereinafter, the present invention will be described in detail using examples. Materials, using amounts, proportions, treatment details, treatment content, and the like shown in the following examples can be appropriately changed without departing from the gist of the present invention. Accordingly, the scope of the present invention is not limited to the following specific examples. Unless otherwise specified, “parts” and “%” are based on mass.

### <Synthesis of Resin>

### Synthesis Example PI-1: Synthesis of Polyimide (PI-1)

30.0 g (57.64 mmol) of 4,4′-(4,4′-isopropylidenediphenoxy)diphtalic acid anhydride was dissolved in 120 g of N-methylpyrrolidone (NMP), thereby obtaining a solution. Subsequently, 9.94 g (24.2 mmol) of 4,4′-isopropylidenebis(2-aminophenol), 5.235 g (24.2 mmol) of 4,4′-diamino-3,3′-dihydroxybiphenyl, and 0.629 g (5.764 mmol) of p-aminophenol were dissolved in 100 g of NMP, and the solution was added dropwise to the above-described solution over 1 hour at a temperature of 10° C. to 25° C., stirred at 25° C. for 30 minutes, 10 g of toluene was added thereto, the mixture was reacted at 200° C. for 4 hours while flowing nitrogen, and the mixture was cooled to 25° C. Subsequently, 13.2 g (86.4 mmol) of 4-(chloromethyl)styrene, 16.6 g (120 mmol) of potassium carbonate, 1.66 g (12 mmol) of potassium iodide, and 0.08 g of 2,2,6,6-tetramethylpiperidine 1-oxide free radical were added to the reaction solution after cooling, the mixture was reacted at 95° C. for 15 hours, cooled to 25° C., and diluted with 200 g of tetrahydrofuran. Subsequently, the reaction solution was added dropwise to a mixed solution of 2.0 L of methanol and 0.5 L of water, and the mixture was stirred for 15 minutes and a polyimide resin was filtered. Next, the resin was subjected to reslurrying with 1 L of water, filtered, reslurried again with 1 L of methanol, filtered, and dried at 40° C. for 10 hours under reduced pressure. Subsequently, the resin dried as described above was dissolved in 250 g of tetrahydrofuran, 40 g of an ion exchange resin (MB-1: manufactured by ORGANO CORPORATION) was added thereto, the mixture was stirred for 4 hours, the ion exchange resin was filtered and removed, and then the polyimide resin was precipitated in 2 L of methanol and stirred for 15 minutes. The polyimide resin was filtered and acquired, and dried at 45° C. for 1 day under reduced pressure to obtain polyimide (PI-1). The obtained polyimide (PI-1) had a weight-average molecular weight of 19,600 and a number-average molecular weight of 7,700. The polyimide (PI-1) is a resin having a repeating unit represented by Formula (PI-1). The structure of the repeating unit was determined from a ¹H-NMR spectrum. In the following structures, the subscripts of the repeating units represent the content molar ratio of the respective repeating units.

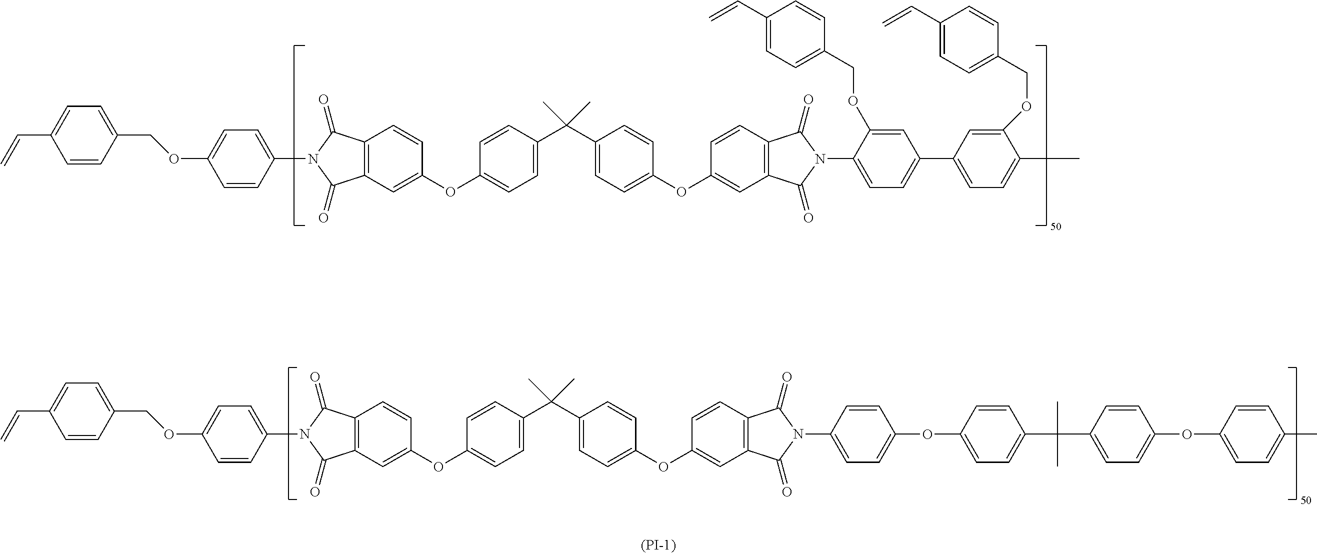

### Synthesis Examples PI-2 to PI-12: Synthesis of Polyimides (PI-2) to (PI-12)

Polyimides (PI-2) to (PI-12) were synthesized in the same method as in Synthesis Example PI-1, except that the raw materials were appropriately changed. Each of the polyimides (PI-2) to (PI-12) is a resin having a repeating unit represented by Formulae (PI-2) to (PI-12). The structure of each repeating unit was determined from a ¹H-NMR spectrum. The weight-average molecular weight (Mw) and the number-average molecular weight (Mn) of each resin are shown in the table below. In the following structures, the subscripts of the repeating units represent the content molar ratio of the respective repeating units.

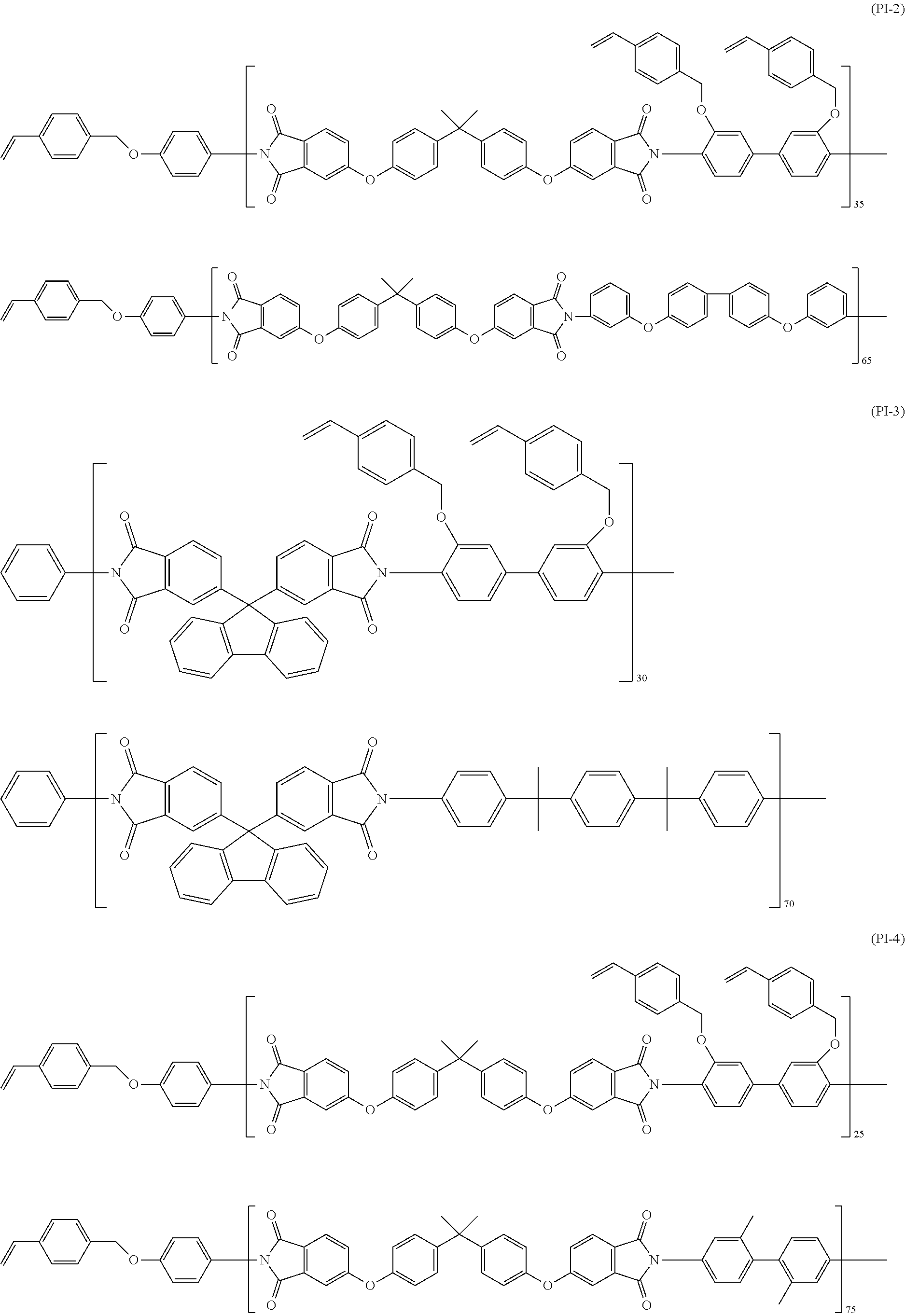

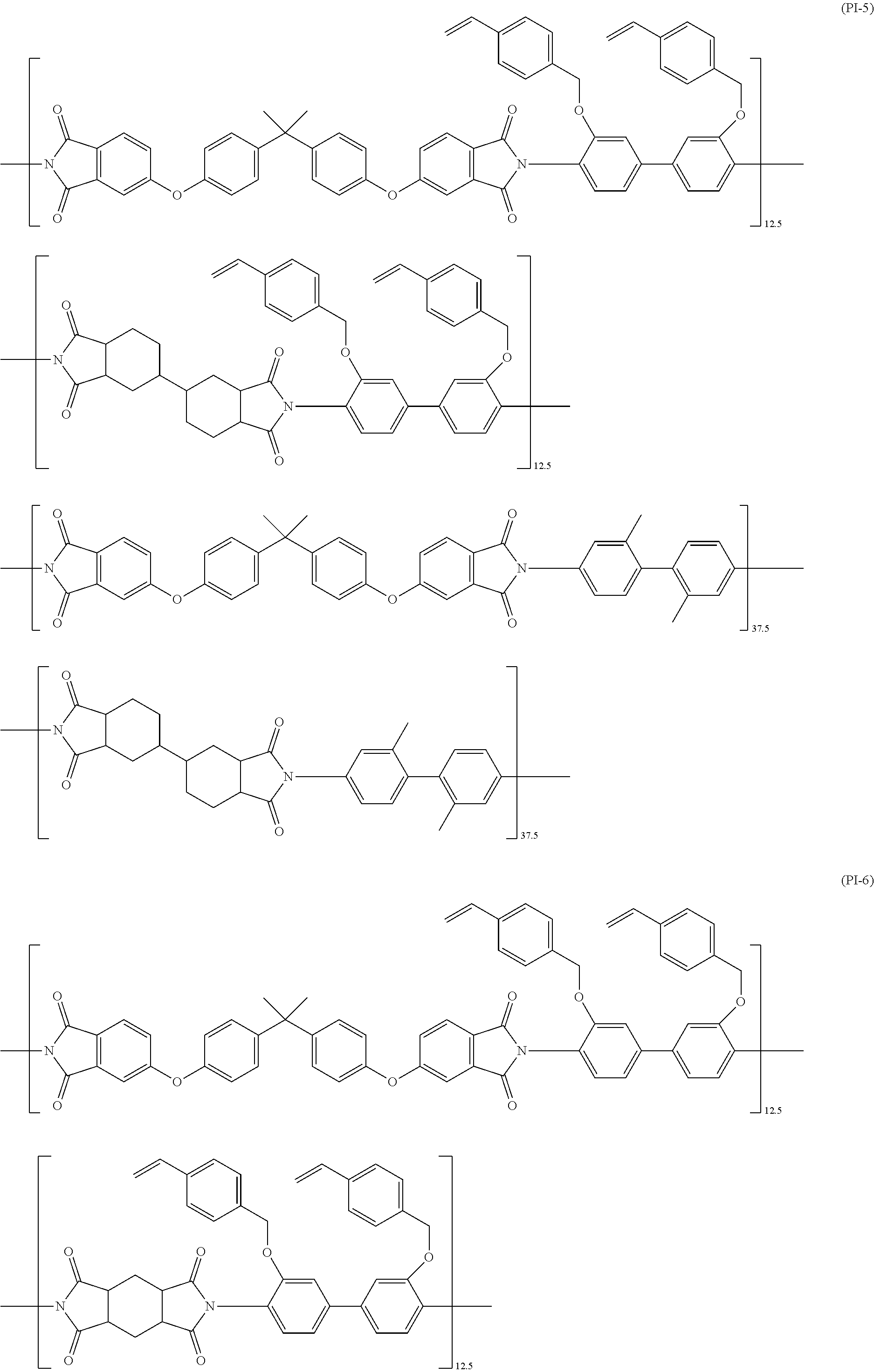

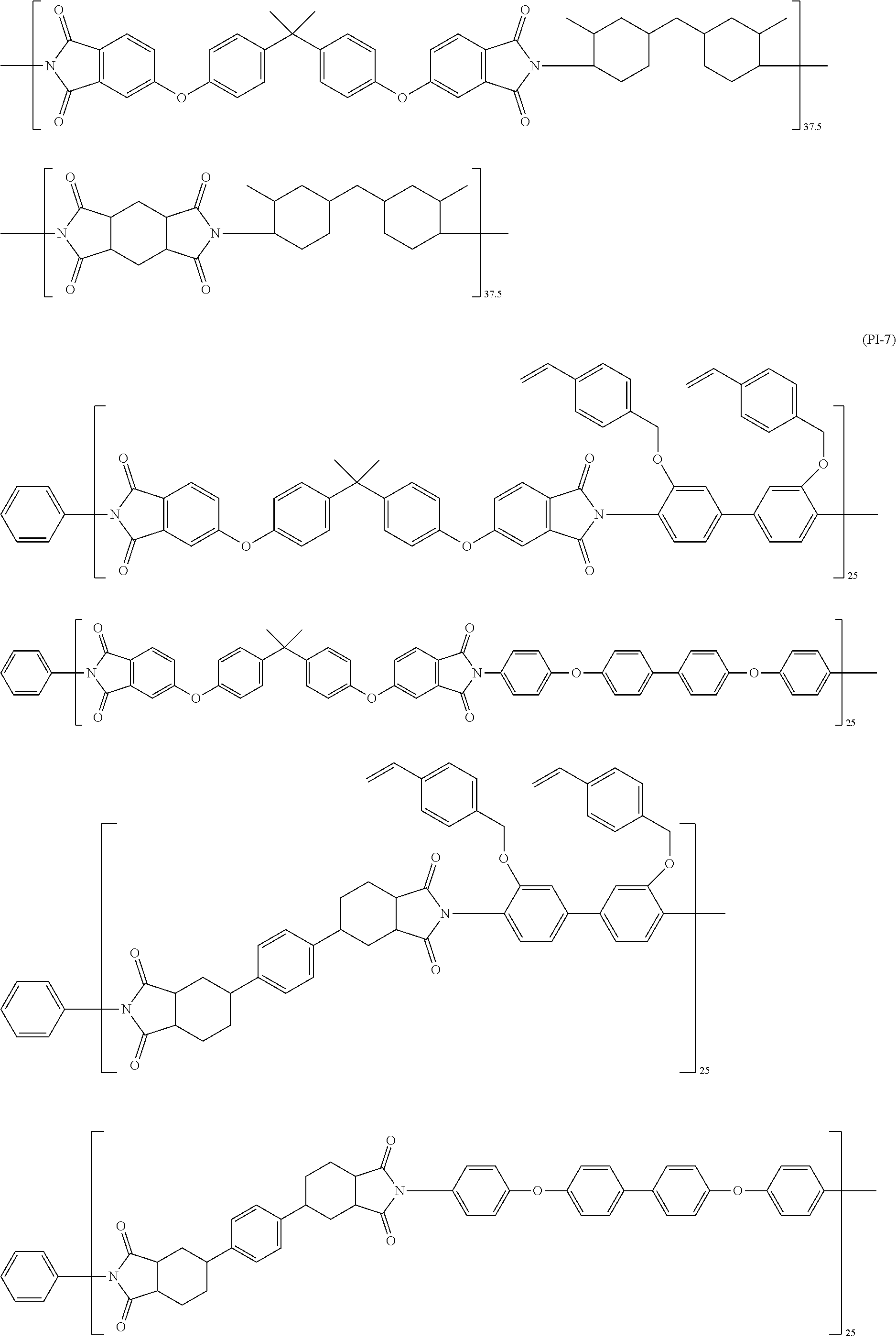

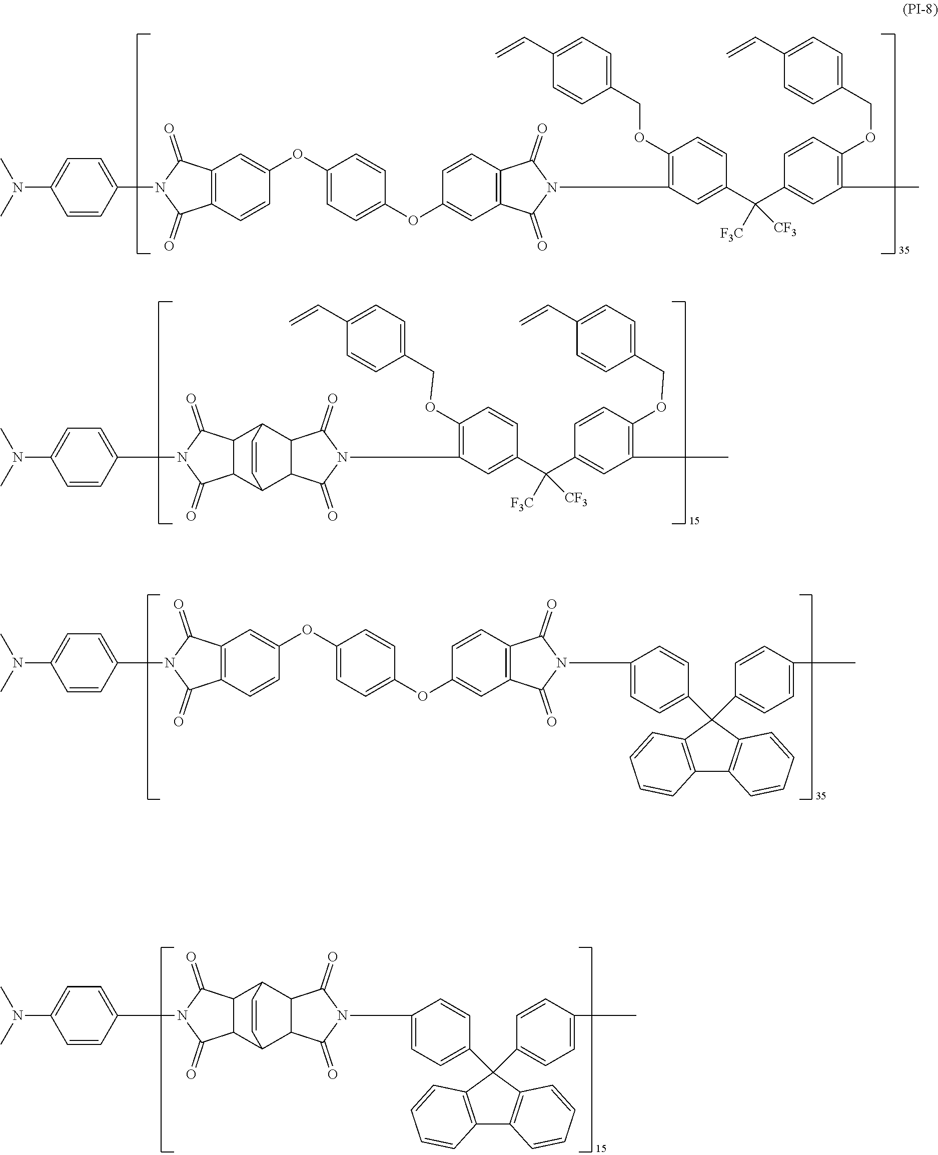

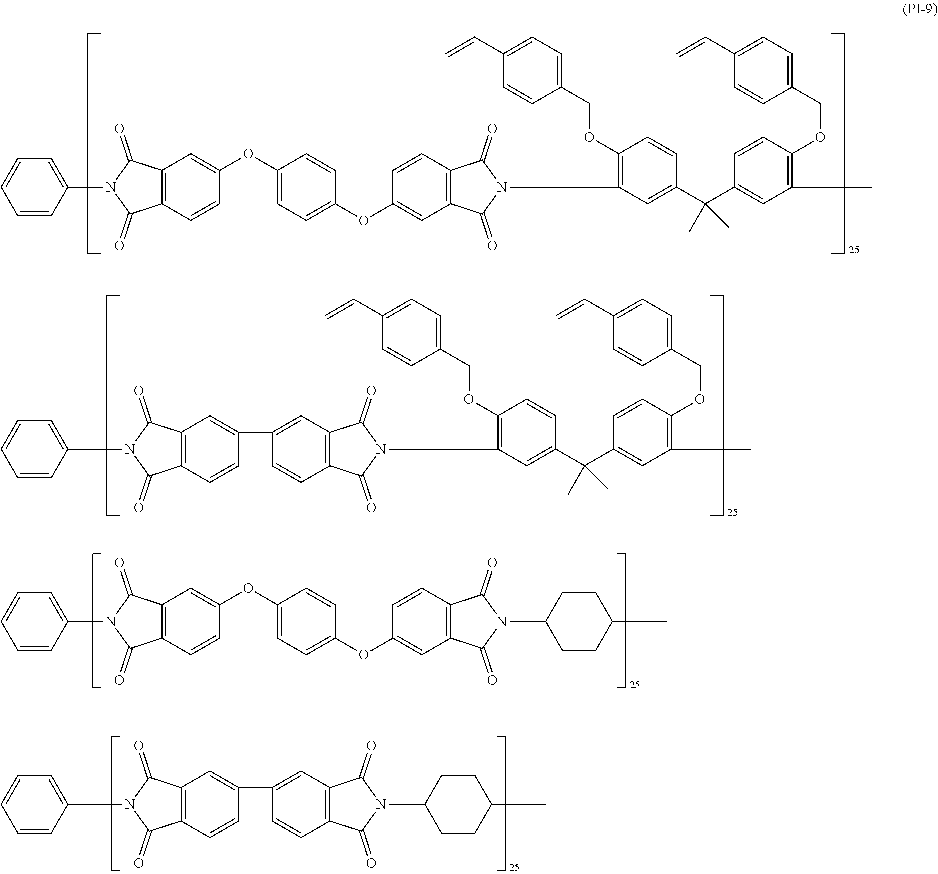

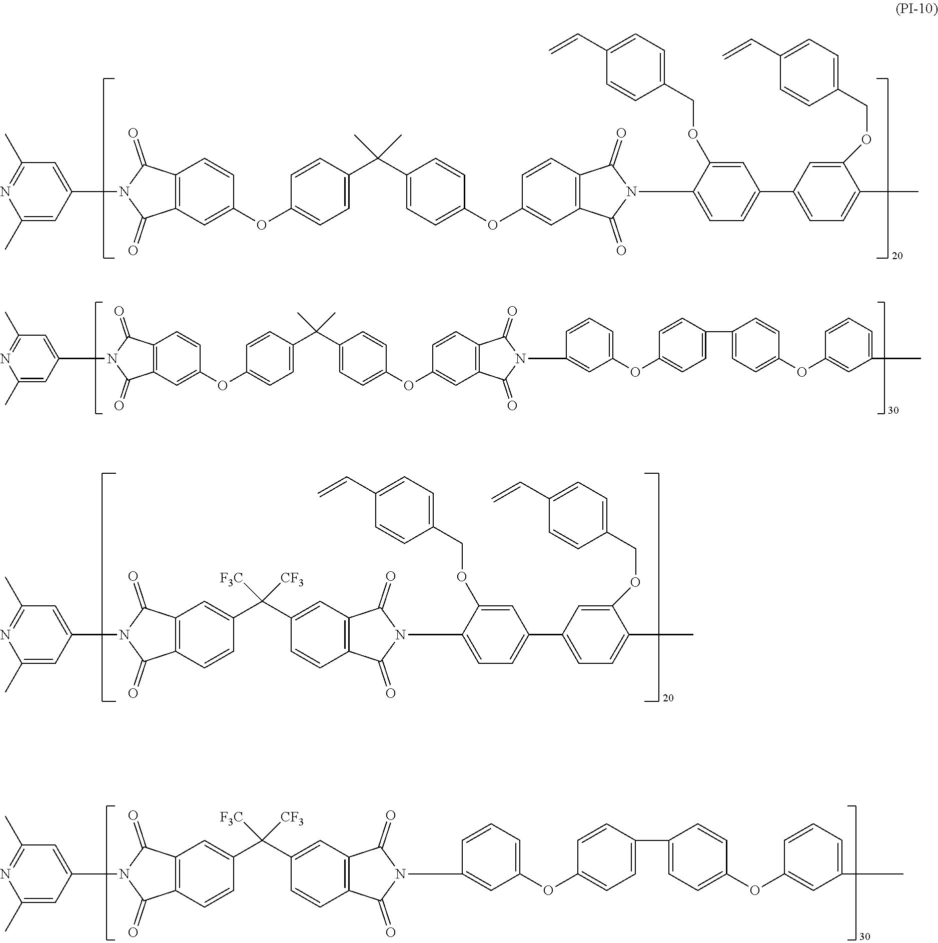

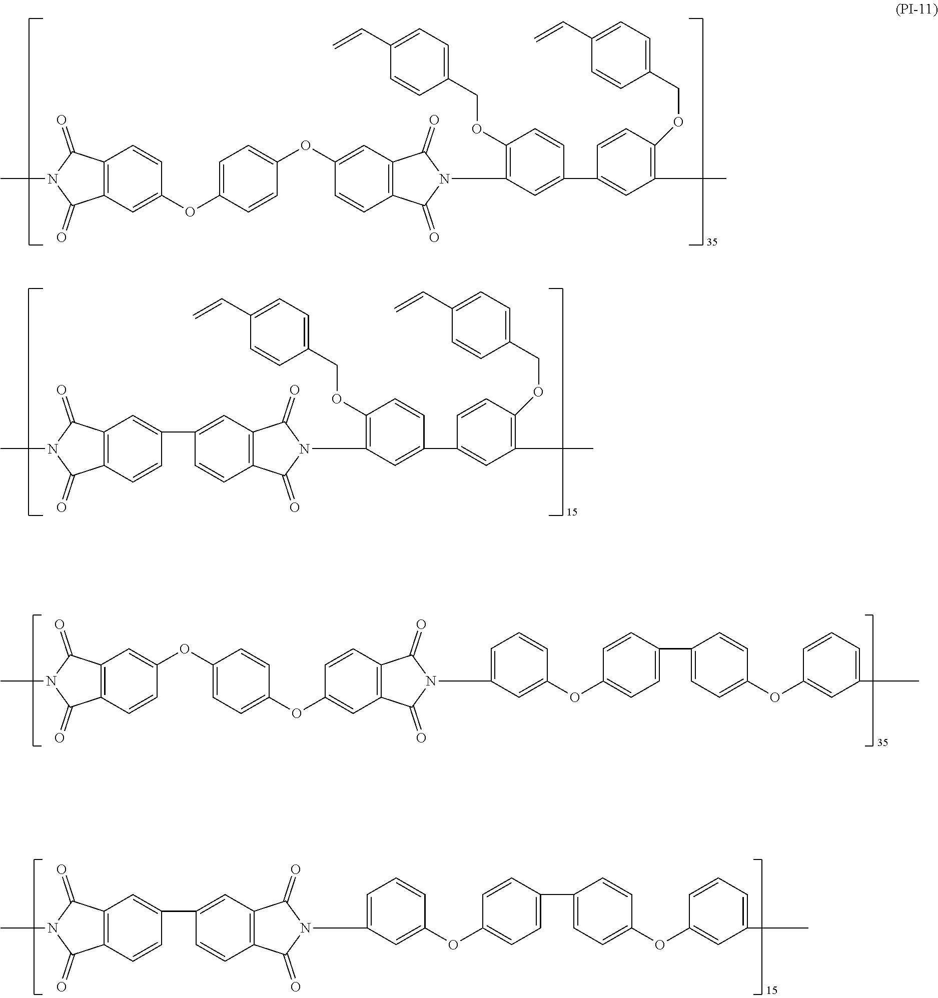

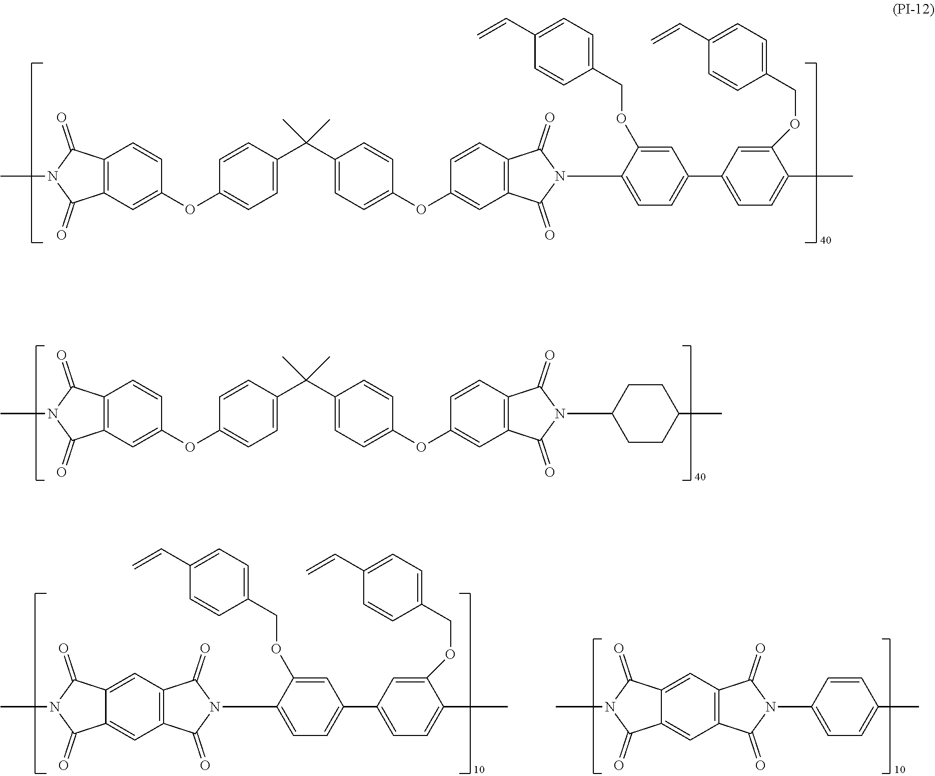

TABLE 1

| | Weight-average | Number-average |
|---|---|---|
| | molecular weight | molecular weight |
| PI-2 | 22,500 | 10,100 |
| PI-3 | 15,700 | 6,200 |
| PI-4 | 11,500 | 5,800 |
| PI-5 | 6,800 | 3,500 |
| PI-6 | 8,900 | 4,300 |
| PI-7 | 14,300 | 6,200 |
| PI-8 | 12,500 | 5,800 |
| PI-9 | 9,900 | 4,710 |
| PI-10 | 13,700 | 6,300 |
| PI-11 | 12,800 | 5,900 |
| PI-12 | 14,700 | 6,600 |

### Synthesis Example PA-1: Synthesis of Polyamideimide (PA-1)

Polyamideimide (PA-1) was synthesized in the same method as in Synthesis Example PI-1, except that the acid anhydride and the diamine used as raw materials were changed.

The weight-average molecular weight of the obtained polyamideimide (PA-1) was 9,500, and the number-average molecular weight thereof was 4,600. The polyamideimide (PA-1) is a resin having a repeating unit represented by Formula (PA-1). The structure of the repeating unit was determined from a ¹H-NMR spectrum. In the following structures, the subscripts of the repeating units represent the content molar ratio of the respective repeating units.

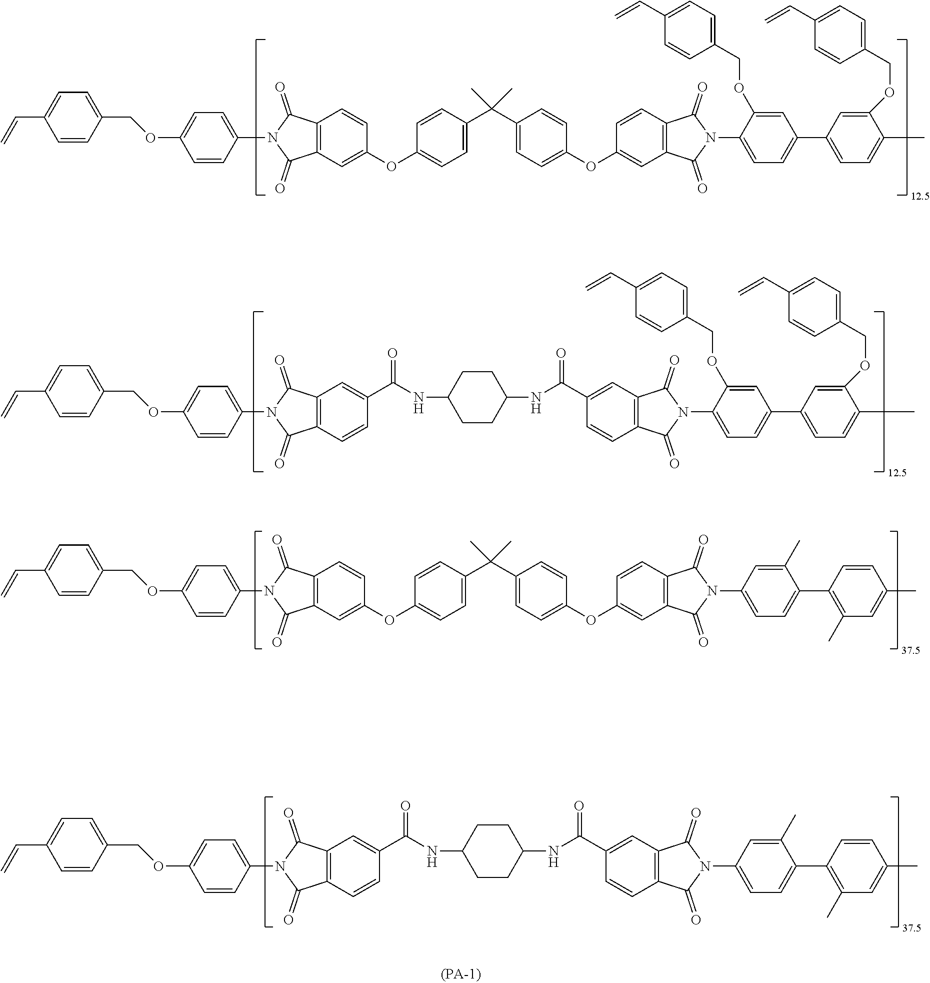

### Synthesis Example PA-1: Synthesis of Polyamideimide (PA-2)

Polyamideimide (PA-2) was synthesized in the same method as in the synthesis of the polyamideimide (PA-1), except that the raw materials were changed. The polyamideimide (PA-2) had a weight-average molecular weight of 13,500 and a number-average molecular weight of 6,100. The polyamideimide (PA-2) is a resin having a repeating unit represented by Formula (PA-2). The structure of the repeating unit was determined from a ¹H-NMR spectrum. In the following structures, the subscripts of the repeating units represent the content molar ratio of the respective repeating units.

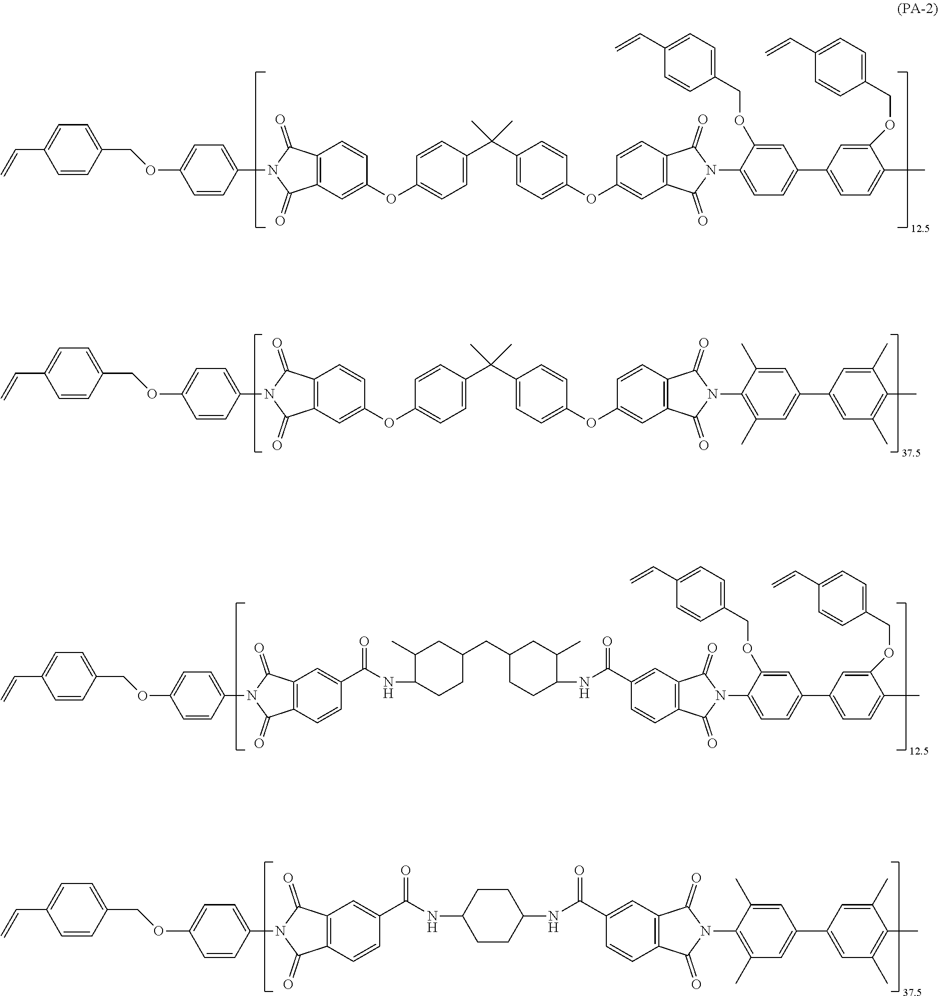

### Synthesis Example SP-1: Synthesis of Polyimide Precursor (SP-1)

21.18 g (68.1 mmol) of 4,4′-oxydiphthalic acid dianhydride, 18.12 g (136 mmol) of 2-hydroxyethyl methacrylate, 0.05 g of hydroquinone, 23.93 g (302 mmol) of pyridine, and 90 g of diglyme were mixed and stirred at a temperature of 60° C. for 5 hours to produce a diester of 4,4′-oxydiphthalic acid dianhydride and 2-hydroxyethyl methacrylate. Next, the mixture was cooled to −10° C., 17.12 g (141 millimoles) of thionyl chloride was subsequently added dropwise over 90 minutes, and stirring was carried out for 2 hours to obtain a white precipitate of pyridinium hydrochloride. Next, a solution obtained by dissolving 8.86 g (44.2 mmol) of 4,4′-diaminodiphenyl ether in 100 mL of NMP was added dropwise to the mixture over 2 hours. Next, 10.0 g (217 mmol) of ethanol was added to the mixture, and the mixture was stirred for 2 hours. Next, the polyimide precursor resin was precipitated by adding 4 L of water and the water-polyimide precursor resin mixture was stirred for 15 minutes at a speed of 500 rpm. The polyimide precursor resin was filtered and acquired, and then the mixture was stirred again in 4 L of water for 30 minutes, filtered again, and dried at 40° C. for 2 days. Subsequently, the resin dried as described above was dissolved in 200 g of tetrahydrofuran, 50 g of an ion exchange resin (MB-1: manufactured by ORGANO CORPORATION) was added thereto, and the mixture was stirred for 6 hours. Next, the polyimide precursor resin was precipitated by adding 4 L of water and the water-polyimide precursor resin mixture was stirred for 15 minutes at a speed of 500 rpm. The polyimide precursor resin was filtered and acquired, and dried at 45° C. for 2 days under reduced pressure to obtain a polyimide precursor (SP-1). The weight-average molecular weight of the obtained polyimide precursor SP-1 was 10,500, and the number-average molecular weight thereof was 3,400. The polyimide precursor (SP-1) is a resin having a repeating unit represented by Formula (SP-1). The structure of the repeating unit was determined from a ¹H-NMR spectrum.

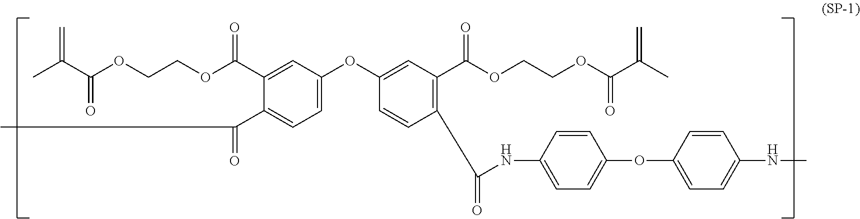

### Synthesis Examples SP-2 and SP-4 to SP-6: Synthesis of Polyamideimide Precursors (SP-2) and (SP-4) to (SP-6)

Polyimide precursors (SP-2) and (SP-4) to (SP-6) were synthesized in the same method as in Synthesis Example SP-1, except that the raw materials were appropriately changed. The polyimide precursors (SP-2) and (SP-4) to (SP-6) are each a resin having a repeating unit represented by Formula (SP-2) and Formulae (SP-4) to (SP-6). The structure of each repeating unit was determined from a ¹H-NMR spectrum. The weight-average molecular weight (Mw) and the number-average molecular weight (Mn) of each resin are shown in the table below. In the following structures, the subscripts of the repeating units represent the content molar ratio of the respective repeating units.

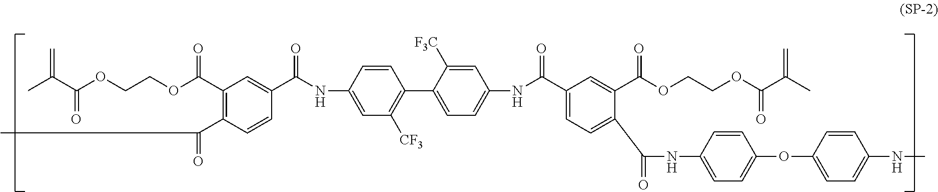

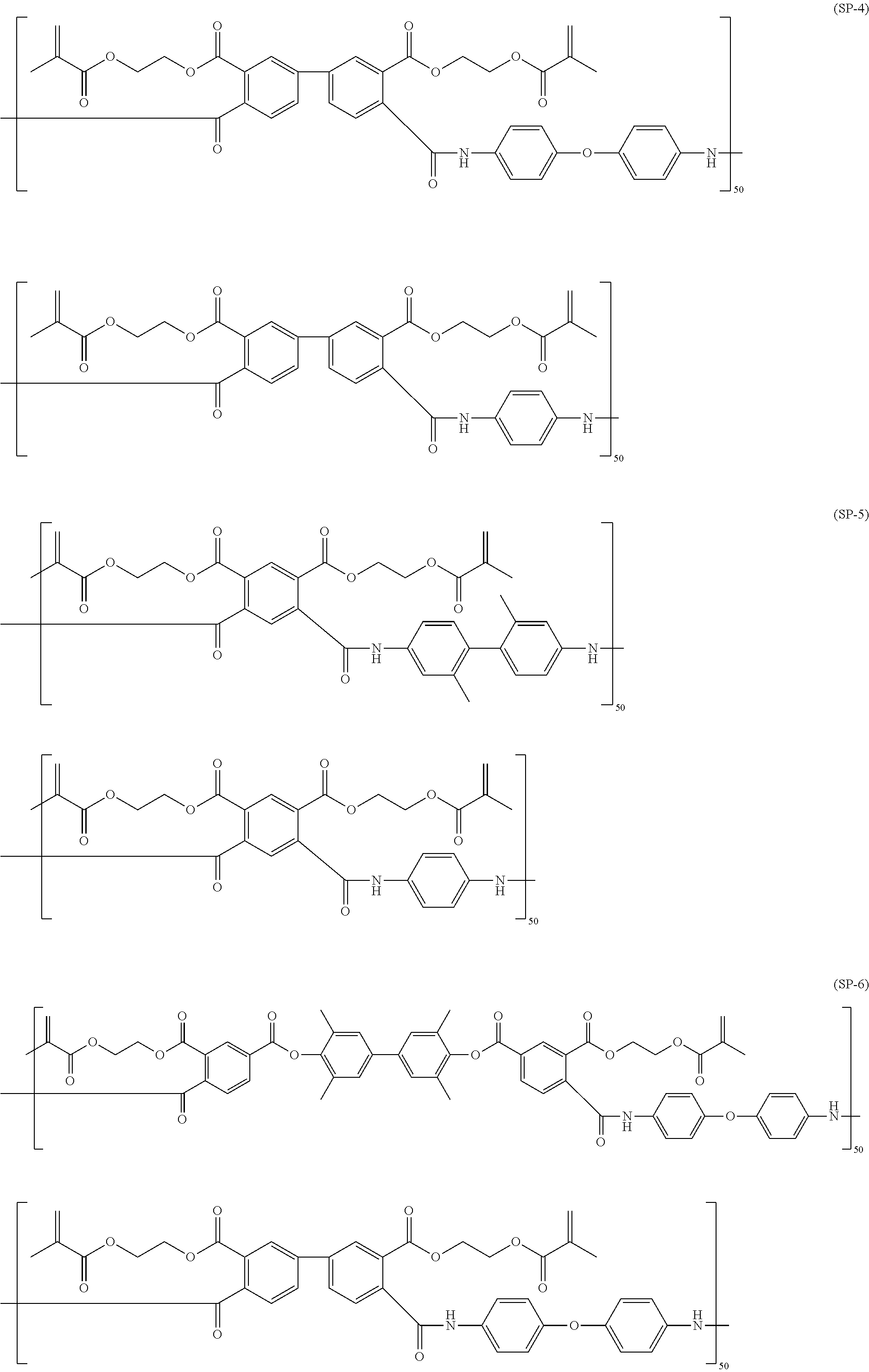

TABLE 2

| | Weight-average | Number-average |
|---|---|---|
| | molecular weight | molecular weight |
| SP-2 | 11,500 | 5,800 |
| SP-4 | 22,000 | 10,500 |
| SP-5 | 16,400 | 7,300 |
| SP-6 | 8,000 | 3,200 |

### <Synthesis of Polymerizable Compound>

### [Synthesis of CX-1]

7.21 g (65.2 mmol) of 2-aminophenol, 14.6 g (144 mmol) of triethylamine, and 200 mL of tetrahydrofuran were placed in a flask equipped with a condenser, and cooled to 0° C. to 10° C. Subsequently, a solution obtained by diluting 15.0 g (143 mmol) of methacrylic acid chloride with 80 mL of tetrahydrofuran was added dropwise thereto over 1 hour, and the mixture was heated to 60° C. and stirred for 3 hours.

Subsequently, the reaction solution was cooled to 20° C. to 25° C., mixed with 300 mL of ethyl acetate, and transferred to a separatory funnel. The mixture was washed twice with 300 mL of saturated aqueous sodium bicarbonate, washed with 300 mL of a saturated aqueous ammonium chloride solution, 300 mL of water, and 300 mL of saturated saline in this order, dried with sodium sulfate, 15 mg of p-methoxyphenol was added, the solvent was removed with an evaporator, and crystals of CX-1 was obtained. The crystals of CX-1 were stirred in a mixed solution of 100 mL of ethyl acetate and 200 mL of hexane for 30 minutes, filtered, and dried at 40° C. for 24 hours, thereby obtaining 12 g of CX-1. It was confirmed by ¹H-NMR spectrum that the compound was CX-1. CX-1 is a compound having a structure represented by Formula (CX-1).

¹H-NMR data: (heavy DMSO, 400 MHz, internal standard: tetramethylsilane)

δ (ppm)=1.90 (s, 3H), 1.96 (s, 3H), 5.46 (s, 1H), 5.76 (s, 1H), 5.83 (s, 1H), 6.25 (s, 1H), 7.24 to 7.27 (m, 3H), 7.53 to 7.55 (t, 1H), 9.42 (s, 1H)

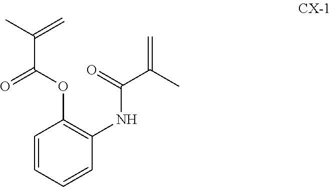 [SMILES: C=C(C)C(=O)Nc1ccccc1OC(=O)C(=C)C]

### [Synthesis of CX-2]

7.21 g (65.2 mmol) of 2-aminophenol, 0.05 g of NEOSTANN U-600 (manufactured by Nitto Kasei Co., Ltd.), and 100 mL of tetrahydrofuran were placed in a flask equipped with a condenser, and the flask was cooled to 10° C. to 15° C. Subsequently, 10.6 g (68.5 mmol) of Karenz MOI (manufactured by Showa Denko K.K.) was added dropwise thereto over 1 hour, and the mixture was heated to 60° C. and stirred for 5 hours.

Subsequently, the reaction solution was cooled to 20° C. to 25° C., mixed with 800 mL of ethyl acetate, and transferred to a separatory funnel. The mixture was washed twice with 300 mL of saturated aqueous sodium bicarbonate, washed with 300 mL of a saturated aqueous ammonium chloride solution, 300 mL of water, and 300 mL of saturated saline in this order, dried with sodium sulfate, 15 mg of p-methoxyphenol was added, the solvent was removed with an evaporator, and 13 g of CX-2 was obtained. It was confirmed by ¹H-NMR spectrum that the compound was CX-2. CX-2 is a compound having a structure represented by Formula CX-2.

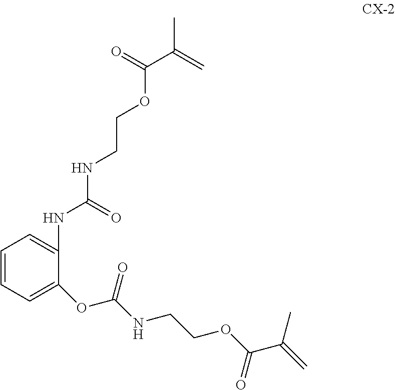 [SMILES: C=C(C)C(=O)OCCNC(=O)Nc1ccccc1OC(=O)NCCOC(=O)C(=C)C]

### <Synthesis of Comparative Compound A-1>

44.4 g (100 mmol) of 4,4′-(hexafluoroisopropylidene)diphtalic dianhydride was dissolved in 200.0 g of N-methylpyrrolidone (NMP) while removing moisture in a drying reactor comprising a stirrer, a condenser, and an internal thermometer. Subsequently, 18.42 g (92 millimoles) of 4,4′-diaminodiphenyl ether was added thereto, and the mixture was stirred at a temperature of 25° C. for 1 hour. Next, 50 mL of toluene was added thereto, the temperature was raised to 180° C. while flowing nitrogen at a flow rate of 200 mL/min, stirring was carried out for 6 hours, and cooling was carried out to room temperature. Next, 130.0 g of N-methylpyrrolidone was added thereto, the mixture was diluted, the polyimide was precipitated in 2 L of methanol, the mixture was stirred for 30 minutes, and then filtered. The filtrate was mixed with 1.5 liters of methanol, stirred for 30 minutes, and filtered. The polyimide obtained above was dried at 40° C. for 1 day under reduced pressure to obtain A-1. The weight-average molecular weight (Mw) of A-1 was 44,500, and the number-average molecular weight (Mn) thereof was 18,200. It was confirmed by ¹H-NMR spectrum that the structure of A-1 is a structure represented by Formula (A-1).

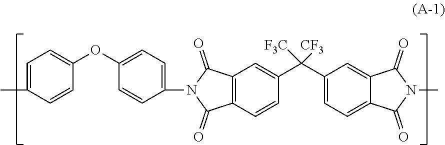

### <Synthesis of Comparative Compound A-2>

44.43 g (121.3 mmol) of 2,2-bis(3-amino-4-hydroxyphenyl)hexafluoropropane and 57.29 g (125.0 mmol) of 1,4-phenylene bis(1,3-dioxo-1,3-dihydroisobenzofuran-5-carboxylic acid) were added to a drying reactor comprising a flat bottom joint to which a stirrer, a condenser, and an internal thermometer were attached while removing moisture, 492.43 g of γ-butyrolactone was added thereto, and the mixture was stirred at a temperature of 60° C. for 1.5 hours. Next, 50 mL of toluene was added thereto, the temperature was raised to 180° C. while flowing nitrogen at a flow rate of 200 mL/min, stirring was carried out for 3 hours, and cooling was carried out to room temperature. The obtained polymerization solution was diluted with acetone to prepare a diluted solution, and the diluted solution was added dropwise to a mixed solution of water/methanol=3/1 to precipitate a white solid. The obtained white solid was recovered and vacuum-dried at a temperature of 120° C. to obtain 90 g of a polymer.

Subsequently, 73.86 g (150.0 mmol in terms of hydroxyl group) of the polymer obtained above, 21.17 g (150.0 mmol) of 2-isocyanatoethyl acrylate (hereinafter, also referred to as AOI, manufactured by Showa Denko K.K.), and 828.26 g of γ-butyrolactone (GBL) were placed in a reaction container comprising a stirrer and a cooling pipe. Thereafter, the temperature was raised to 120° C. with stirring, and the mixture was reacted for 6 hours. Subsequently, the obtained reaction solution was diluted with acetone to prepare a diluted solution, and the diluted solution was added dropwise to a mixed solution of water/methanol=2/1 to precipitate a white solid. The obtained white solid was recovered and vacuum-dried at a temperature of 40° C. to obtain 71.8 g of A-2. The weight-average molecular weight (Mw) of A-2 was 78,500, and the number-average molecular weight (Mn) thereof was 30,200. It was confirmed by ¹H-NMR spectrum that the structure of A-2 was a structure represented by Formula (A-2). From the measurement results of ¹H-NMR, the introduction rate of the crosslinking group was 55%.

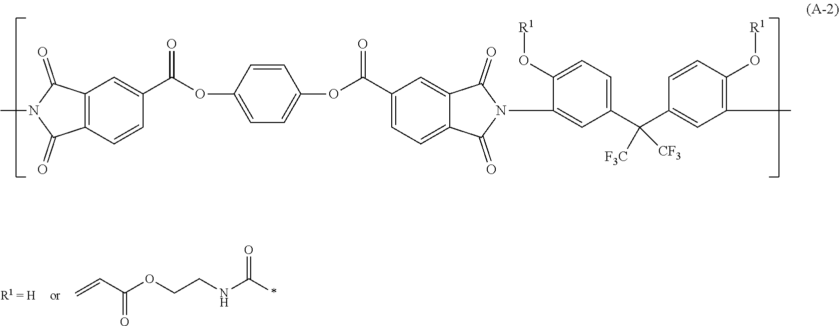

### <Synthesis of Comparative Compound A-3>

4,4′-(4,4′-isopropylidenediphenoxy)diphtalic acid anhydride (30.0 g (57.64 mmol)) was dissolved in 120 g of N-methylpyrrolidone (NMP) while removing moisture in a drying reactor comprising a bottom joint to which a stirrer, a condenser, and an internal thermometer were attached. Subsequently, 9.79 g (46.1 mmol) of m-triazine was dissolved in 80 g of NMP, and the solution was added dropwise thereto over 1 hour at a temperature of 10° C. to 25° C., stirred at 25° C. for 30 minutes, 10 g of toluene was added thereto, the mixture was reacted at 190° C. for 4 hours while flowing nitrogen, and the mixture was cooled to 25° C. Next, 130.0 g of tetrahydrofuran was added thereto, the mixture was diluted, the polyimide was precipitated in 2 liters of methanol, the methanol-polyimide mixture was stirred at a speed of 2,000 rpm for 30 minutes, filtered, mixed again with 1.5 liters of methanol, stirred for 30 minutes, and filtered. Next, the obtained polyimide was dried at 40° C. for 1 day under reduced pressure to obtain A-3. The weight-average molecular weight (Mw) of A-3 was 15,700, and the number-average molecular weight (Mn) thereof was 7,200. It was confirmed by ¹H-NMR spectrum that the structure of A-3 is a structure represented by Formula (A-3).

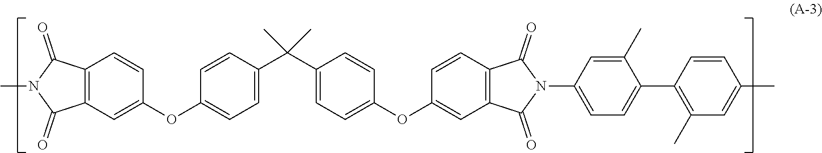

### Examples and Comparative Examples

In each of Examples, the components shown in the table were mixed to obtain each of the resin compositions. Further, in each Comparative Example, components shown in the table were mixed to obtain each of the comparative compositions.

Specifically, the content of each component described in the table was set to the amount (in terms of parts by mass) described in the column of “Adding amount” of each column of the table.

The obtained resin composition and comparative composition were subjected to pressure filtration using a filter made of a polypropylene having a micropore width of 0.5 km. In addition, in the table, the description of “-” indicates that the corresponding component is not contained in the composition.

TABLE 3

| | | | | | | | | | Migration | | Metal | | | |
|---|---|---|---|---|---|---|---|---|---|---|---|---|---|---|
| | | | Polymerizable | | | | Polymerization | | suppressing | | adhesiveness | | Polymerization | |
| | Resin | | compound | | Solvent | | initiator | | agent | | improving agent | | inhibitor | |
| | | Addi- | | Addi- | | Addi- | | Addi- | | Addi- | | Addi- | | Addi- |
| | Type | tive | Type | tive | Type | tive | Type | tive | Type | tive | Type | tive | Type | tive |
| Example | PI-1 | 30.6 | B-1 | 7.0 | GBL | 60 | OXE-01 | 1.6 | E-1 | 0.1 | F-1 | 0.7 | G-1 | 0.04 |
| 1 | | | | | | | | | | | | | | |
| Example | PI-2 | 30.5 | B-5 | 7.0 | GBL | 60 | OXE-02 | 1.7 | E-7 | 0.1 | F-6 | 0.7 | G-2 | 0.04 |
| 2 | | | | | | | | | | | | | | |
| Example | PI-3 | 31 | B-3/ | 4.0/2.5 | GBL | 60 | OXE-03 | 1.7 | E-1 | 0.1 | F-7 | 0.7 | G-2 | 0.04 |
| 3 | | | B-2 | | | | | | | | | | | |
| Example | PI-4 | 30.3 | B-1 | 7.2 | GBL | 60 | OXE-01 | 1.65 | E-2 | 0.1 | F-2 | 0.7 | G-3 | 0.04 |
| 4 | | | | | | | | | | | | | | |
| Example | PI-5 | 32 | B-1 | 5.5 | GBL | 60 | OXE-01 | 1.65 | E-3 | 0.1 | F-3 | 0.7 | G-5 | 0.04 |
| 5 | | | | | | | | | | | | | | |
| Example | PI-6 | 29.4 | B-5 | 7.1 | DMSO/ | 61 | OXE-02 | 1.65 | E-4 | 0.1 | F-4 | 0.7 | G-2 | 0.05 |
| 6 | | | | | GBL | | | | | | | | | |
| Example | PI-4 | 29 | B-6 | 7.0 | NMP | 61 | OXE-01 | 1.65 | E-5 | 0.1 | F-4 | 0.7 | G-2 | 0.05 |
| 7 | | | | | | | | | | | | | | |
| Example | PI-4 | 29 | B-7 | 7.0 | NMP | 61 | OXE-02 | 1.65 | E-6 | 0.1 | F-4 | 0.7 | G-2 | 0.05 |
| 8 | | | | | | | | | | | | | | |
| Example | PI-4 | 29 | B-8 | 7.0 | γ-V | 61 | OXE-02/ | 1.25/0.4 | E-7 | 0.1 | F-4 | 0.7 | G-2 | 0.05 |
| 9 | | | | | | | D-1 | | | | | | | |
| Example | PI-7 | 30.6 | B-1 | 7.0 | GBL | 60 | OXE-01 | 1.6 | E-1 | 0.1 | F-1 | 0.7 | G-1 | 0.04 |
| 10 | | | | | | | | | | | | | | |
| Example | PI-8 | 29 | B-6 | 7.0 | NMP | 61 | OXE-01 | 1.65 | E-5 | 0.1 | F-4 | 0.7 | G-2 | 0.05 |
| 11 | | | | | | | | | | | | | | |
| Example | PI-9 | 30.6 | B-1 | 7.0 | GBL | 60 | OXE-01 | 1.6 | E-1 | 0.1 | F-1 | 0.7 | G-1 | 0.04 |
| 12 | | | | | | | | | | | | | | |
| Example | PI-10 | 31 | B-1/B-3 | 4.0/2.5 | γ-V | 60 | OXE-03 | 1.7 | E-1 | 0.1 | F-7 | 0.7 | G-2 | 0.04 |
| 13 | | | | | | | | | | | | | | |
| Example | PA-1 | 29.5 | B-1 | 8.0 | NMP | 60 | Irgacure | 1.65 | E-5 | 0.1 | F-5 | 0.7 | G-2 | 0.04 |
| 14 | | | | | | | 784 | | | | | | | |
| Example | PA-2 | 31 | B-1/B-4 | 4.0/2.5 | GBL | 60 | OXE-03 | 1.7 | E-1 | 0.1 | F-7 | 0.7 | G-2 | 0.04 |
| 15 | | | | | | | | | | | | | | |
| Example | SP-1 | 26.3 | B-3/B-4 | 10.2/3.5 | DMSO/ | 57 | OXE-01/ | 1.0/0.93 | E-1 | 0.1 | F-1 | 0.7 | G-2 | 0.04 |
| 16 | | | | | GBL | | CPI-310B | | | | | | | |

| | Base | | Other | | Curing | | | | | | | | | |
|---|---|---|---|---|---|---|---|---|---|---|---|---|---|---|
| | generator | | additives | | condition | | | | | | | | | |
| | | Addi- | | Addi- | Temper- | | Rinsing | Resolu- | Focus | | Curing | Chemical | | |
| | Type | tive | Type | tive | ature | Developer | liquid | tion | margin | Flatness | shrinkage | resistance | CTE | pH |
| Example | — | — | — | — | 230° C. | J-1 | K-1 | B | B | A | A | A | B | 6.7 |
| 1 | | | | | | | | | | | | | | |
| Example | — | — | — | — | 200° C. | J-1 | K-1 | A | A | A | A | A | B | 6.3 |
| 2 | | | | | | | | | | | | | | |
| Example | — | — | — | — | 230° C. | J-1 | K-1 | B | B | A | A | B | B | 6.5 |
| 3 | | | | | | | | | | | | | | |
| Example | — | — | — | — | 230° C. | J-1 | K-1 | A | A | A | A | A | B | 6.1 |
| 4 | | | | | | | | | | | | | | |
| Example | — | — | — | — | 200° C. | J-1 | K-1 | A | A | A | A | B | B | 7.1 |
| 5 | | | | | | | | | | | | | | |
| Example | — | — | — | — | 230° C. | J-1 | K-1 | A | A | A | A | A | B | 6.8 |
| 6 | | | | | | | | | | | | | | |
| Example | — | — | I-1 | 0.5 | 230° C. | J-1 | K-1 | A | B | A | A | A | B | 6.2 |
| 7 | | | | | | | | | | | | | | |
| Example | — | — | I-2 | 0.5 | 230° C. | J-1 | K-1 | A | B | A | A | A | B | 6.2 |
| 8 | | | | | | | | | | | | | | |
| Example | — | — | I-2 | 0.5 | 200° C. | J-1 | K-1 | A | B | A | A | A | B | 6.1 |
| 9 | | | | | | | | | | | | | | |
| Example | — | — | — | — | 230° C. | J-1 | K-1 | B | B | A | A | A | B | 6.9 |
| 10 | | | | | | | | | | | | | | |
| Example | — | — | I-1 | 0.5 | 230° C. | J-1 | K-1 | B | B | A | A | A | A | 8.5 |
| 11 | | | | | | | | | | | | | | |
| Example | — | — | — | — | 230° C. | J-1 | K-1 | B | B | A | A | A | A | 6.7 |
| 12 | | | | | | | | | | | | | | |
| Example | — | — | — | — | 230° C. | J-1 | K-1 | B | B | A | A | B | B | 7.8 |
| 13 | | | | | | | | | | | | | | |
| Example | — | — | — | — | 170° C. | J-1 | K-1 | B | B | A | B | A | A | 6.1 |
| 14 | | | | | | | | | | | | | | |
| Example | — | — | — | — | 230° C. | J-1 | K-1 | B | B | A | A | B | B | 6.5 |
| 15 | | | | | | | | | | | | | | |
| Example | H-1 | 0.2 | — | — | 230° C. | J-1 | K-1 | B | B | B | B | B | B | 6.3 |
| 16 | | | | | | | | | | | | | | |

TABLE 4

| | | | | | | | | | Migration | | Metal | | | |
|---|---|---|---|---|---|---|---|---|---|---|---|---|---|---|
| | | | Polymerizable | | | | Polymerization | | suppressing | | adhesiveness | | Polymerization | |
| | Resin | | compound | | Solvent | | initiator | | agent | | improving agent | | inhibitor | |
| | | Addi- | | Addi- | | Addi- | | Addi- | | Addi- | | Addi- | | Addi- |
| | Type | tive | Type | tive | Type | tive | Type | tive | Type | tive | Type | tive | Type | tive |
| Example 17 | SP-2 | 25.9 | B-3/CX-1 | 8.2/5.8 | NMP | 57 | OXE-01 | 1.95 | E-1 | 0.1 | F-1 | 0.7 | G-2 | 0.04 |
| Example 18 | SP-6 | 24 | B-2/CX-2 | 8.5/4.5 | DMSO/GBL | 60 | OXE-01 | 1.95 | E-1 | 0.1 | F-1 | 0.7 | G-4 | 0.04 |
| Example 19 | PI-2/PA-1 | 15/15 | B-1 | 6.8 | DMSO/GBL | 61 | OXE-01 | 1.27 | E-1 | 0.15 | F-1 | 0.7 | G-2 | 0.08 |
| Example 20 | SP-4 | 31 | B-3 | 6.5 | DMSO/GBL | 60 | OXE-02 | 1.65 | E-4 | 0.1 | F-4 | 0.7 | G-2 | 0.05 |
| Example 21 | SP-5 | 31 | B-2 | 6.0 | DMSO/GBL | 60 | OXE-02 | 1.65 | E-2 | 0.1 | F-2 | 0.7 | G-2 | 0.05 |
| Example 22 | PI-11 | 30.6 | B-2 | 7.0 | GBL | 60 | OXE-01 | 1.6 | E-1 | 0.1 | F-1 | 0.7 | G-1 | 0.04 |
| Example 23 | PI-12 | 30.6 | B-3 | 7.0 | GBL | 60 | OXE-01 | 1.6 | E-1 | 0.1 | F-1 | 0.7 | G-1 | 0.04 |
| Example 24 | PI-11/SP-5 | 18/12.5 | B-2 | 6.8 | DMSO/GBL | 60 | OXE-01 | 1.27 | E-1 | 0.15 | F-1 | 0.7 | G-2 | 0.08 |
| Example 25 | PI-12/SP-4 | 20/10.5 | B-2 | 6.8 | DMSO/GBL | 60 | OXE-01 | 1.27 | E-1 | 0.15 | F-1 | 0.7 | G-2 | 0.08 |
| Comparative | A-1 | 30 | B-3 | 7.7 | DMSO/GBL | 60 | OXE-01 | 1.3 | E-3 | 0.2 | F-3 | 0.7 | G-3 | 0.1 |
| Example 1 | | | | | | | | | | | | | | |
| Comparative | A-2 | 22.7 | B-1 | 15.0 | DMSO/GBL | 60 | OXE-01 | 1.3 | E-3 | 0.2 | F-3 | 0.7 | G-3 | 0.1 |
| Example 2 | | | | | | | | | | | | | | |
| Comparative | A-3 | 16.7 | B-1 | 21.0 | DMSO/GBL | 60 | OXE-01 | 1.3 | E-3 | 0.2 | F-3 | 0.7 | G-3 | 0.1 |
| Example 3 | | | | | | | | | | | | | | |

| | Base | | Other | | Curing | | | | | | | | | |
|---|---|---|---|---|---|---|---|---|---|---|---|---|---|---|
| | generator | | additives | | condition | | | | | | | | | |
| | | Addi- | | Addi- | Temper- | | Rinsing | Resolu- | Focus | | Curing | Chemical | | |
| | Type | tive | Type | tive | ature | Developer | liquid | tion | margin | Flatness | shrinkage | resistance | CTE | pH |
| Example 17 | H-2 | 0.3 | — | — | 230° C. | J-1 | K-1 | B | B | B | B | A | A | 6.3 |
| Example 18 | H-1 | 0.2 | — | — | 230° C. | J-1 | K-1 | B | B | B | B | B | A | 6.2 |
| Example 19 | — | — | — | — | 230° C. | J-1 | K-1 | B | B | A | A | A | B | 6.3 |
| Example 20 | — | — | — | — | 170° C. | J-2 | K-3 | B | B | A | B | A | A | 6.0 |
| Example 21 | — | — | I-1 | 0.5 | 230° C. | J-1 | K-2 | B | B | A | B | A | A | 6.2 |
| Example 22 | — | — | — | — | 230° C. | J-1 | K-3 | A | A | A | A | A | B | 6.9 |
| Example 23 | — | — | — | — | 230° C. | J-1 | K-1 | A | A | A | A | A | B | 6.8 |
| Example 24 | — | — | I-2 | 0.5 | 230° C. | J-1 | K-3 | A | B | A | B | A | A | 6.3 |
| Example 25 | — | — | I-2 | 0.5 | 230° C. | J-3 | K-1 | A | A | A | B | A | A | 6.3 |
| Comparative | — | — | — | — | 230° C. | J-1 | K-1 | D | D | D | D | D | C | 5.9 |
| Example 1 | | | | | | | | | | | | | | |
| Comparative | — | — | — | — | 230° C. | J-1 | K-1 | D | D | D | B | D | B | 5.5 |
| Example 2 | | | | | | | | | | | | | | |
| Comparative | — | — | — | — | 230° C. | J-1 | K-1 | D | D | C | D | C | C | 5.8 |
| Example 3 | | | | | | | | | | | | | | |

Details of each of the components listed in the table are as follows.

### [Resin]

PI-1 to PI-12: PI-1 to PI-12 synthesized as described above
PA-1 and PA-2: PA-1 and PA-2 synthesized above
SP-1 and SP-2, SP-4 to SP-6: SP-1 and SP-2 and SP-4 to SP-6 synthesized above
A-1 to A-3: synthetic products described above

PI-1 to PI-12, PA-1, SP-1 to SP-2, and SP-4 to SP-6 are compounds corresponding to the specific resin.

A-1 to A-3 are compounds that do not correspond to the specific resin. [0355][Polymerizable compound (all trade names)]
B-1: SR-209: SR-209 (manufactured by SARTOMER, melting point: 25° C. or lower)
B-2: ADPH: dipentaerythritol hexaacrylate (manufactured by Shin-Nakamura Chemical Co., Ltd., melting point: 25° C. or lower)
B-3: LIGHT ACRYLATE 4EG-A (manufactured by KYOEISHA CHEMICAL Co., Ltd., melting point: 25° C. or lower)
B-4: M-305 (manufactured by Toagosei Co., Ltd., melting point: 25° C. or lower)
B-5: 1,9-nonanediol dimethacrylate (melting point: 25° C. or lower)
B-6: 1,9-nonanediol diacrylate (melting point: 25° C. or lower)
B-7: 1,10-decanediol dimethacrylate (melting point: 25° C. or lower)
B-8: 1,12-dodecanediol diacrylate (melting point: 25° C. or lower)
CX-1 and CX-2: polymerizable compounds CX-1 and CX-2 synthesized above (melting point: 25° C. or lower)

### [Solvent]

DMSO: dimethyl sulfoxide
GBL: γ-butyrolactone
NMP: N-methylpyrrolidone
γ-V: γ-valerolactone

In the table, the description of “DMSO/GBL” indicates that a mixture of DMSO and GBL at a mixing ratio (mass ratio) of DMSO:GBL=20:80 was used.

### [Polymerization Initiator (all Trade Names)]

OXE-01: IRGACURE OXE 01 (manufactured by BASF SE)
OXE-02: IRGACURE OXE 02 (manufactured by BASF SE)
OXE-03: IRGACURE OXE 03 (manufactured by BASF SE)
Irgacure 784 (manufactured by BASF SE)
D-1: Benzoyl peroxide (manufactured by Tokyo Chemical Industry Co., Ltd.)
CPI-310B (manufactured by San-Apro Ltd.)

### [Migration Suppressing Agent]

E-1 to E-7: Compounds having the following structures

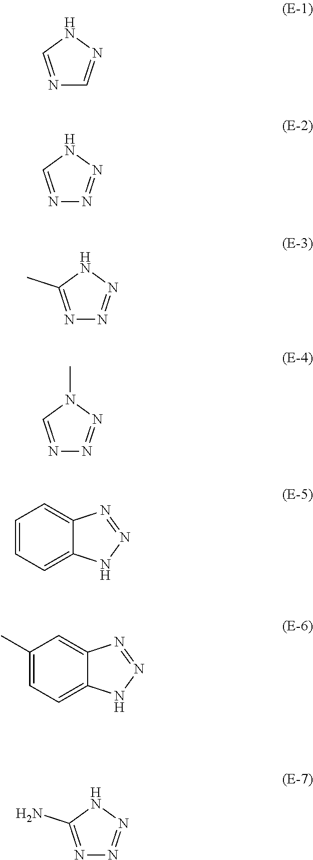

### [Metal Adhesiveness Improving Agent]

F-1 to F-3: Compounds having the following structures

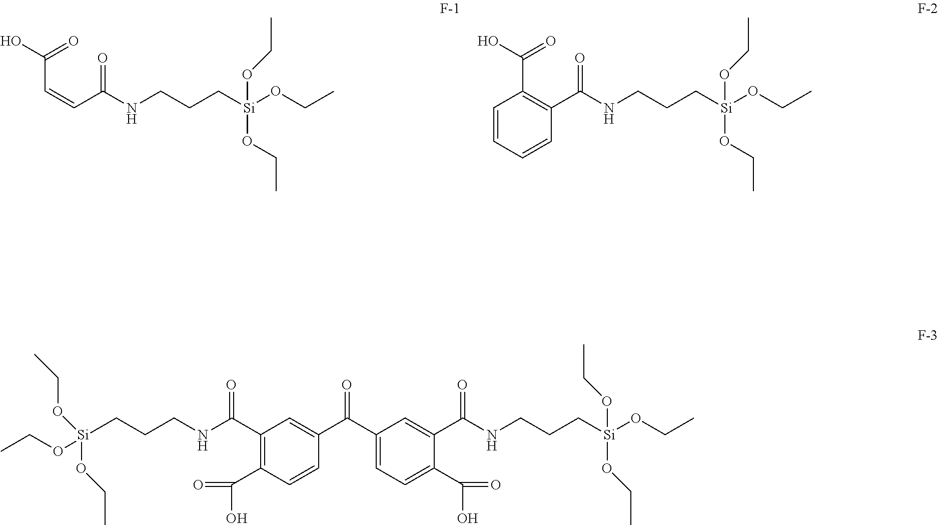 [SMILES: CCO[Si](CCCNC(=O)/C=C\C(=O)O)(OCC)OCC ; CCO[Si](CCCNC(=O)c1ccccc1C(=O)O)(OCC)OCC ; CCO[Si](CCCNC(=O)c1cc(C(=O)c2ccc(C(=O)O)c(C(=O)NCCC[Si](OCC)(OCC)OCC)c2)ccc1C(=O)O)(OCC)OCC]

F-4: X-12-1293 (manufactured by Shin-Etsu Chemical Co., Ltd.)
F-5: KR-513 (manufactured by Shin-Etsu Chemical Co., Ltd.)
F-6: X-12-989 (manufactured by Shin-Etsu Chemical Co., Ltd.)
F-7: 3-(triethoxysilyl)propyl methacrylate (manufactured by Tokyo Chemical Industry Co., Ltd.)

### [Polymerization Inhibitor]

G-1: 1,4-benzoquinone
G-2: 4-methoxyphenol
G-3: 1,4-dihydroxybenzene
G-4: A compound having the following structure

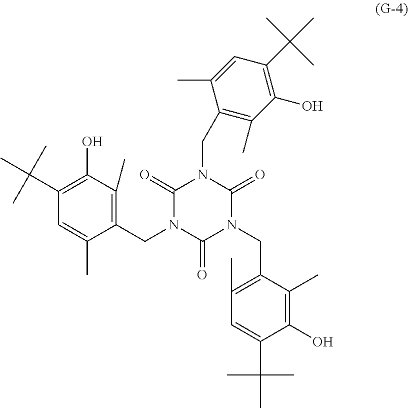 [SMILES: Cc1cc(C(C)(C)C)c(O)c(C)c1Cn1c(=O)n(Cc2c(C)cc(C(C)(C)C)c(O)c2C)c(=O)n(Cc2c(C)cc(C(C)(C)C)c(O)c2C)c1=O]

G-5: 2-nitroso-1-naphthol (manufactured by Tokyo Chemical Industry Co., Ltd.) [0361][Base generator]
H-1 and H-2: Compounds having the following structures

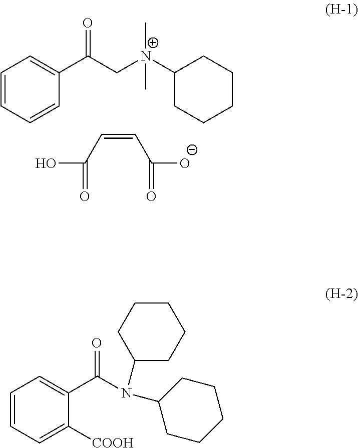 [SMILES: C[N+](C)(CC(=O)c1ccccc1)C1CCCCC1 ; O=C([O-])/C=C\C(=O)O ; O=C(O)c1ccccc1C(=O)N(C1CCCCC1)C1CCCCC1]

### [Other Additives]

I-1: An ester of 2,2′,3,3′-tetrahydro-3,3,3′,3′-tetramethyl-1,1′-spirobi(1H-indene)-5,5′,6,6′,7,7′-hexanol and 1,2-naphthoquinone-(2)-diazo-5-sulfonic acid
I-2: TC-750 (manufactured by Matsumoto Fine Chemical Co., Ltd.)

### [Developer]

J-1: cyclohexanone
J-2: 5% by mass dimethylcyclohexylamine cyclohexanone solution
J-3: 5% by mass PGMEA solution of N-[2-(dimethylamino)ethyl]methacrylamide

### [Rinsing Liquid]

K-1: propylene glycol monomethyl ether acetate (PGMEA)
K-2: 10% by mass of dimethylcyclohexylamine PGMEA solution
K-3: 10% by mass PGMEA solution of N-[2-(dimethylamino)ethyl]methacrylamide

<Evaluation>

### [Evaluation of Resolution]

Each of the resin compositions used in each Example and Comparative Example was applied, in a layer shape by a spin coating method, onto a surface of a thin copper layer of the resin base material having a surface on which the thin copper layer was formed and then dried at 100° C. for 5 minutes. A resin composition layer having a film thickness of 3 μm after film formation was formed and then exposed at 300 mJ/cm² and NA=0.50 using a stepper (FPA-3000 i5 (manufactured by Canon Inc.)). The exposure was performed at a wavelength of 365 nm through a hole pattern mask in which hole patterns having a diameter of 3 to 20 μm were formed at an interval of 1 μm. Subsequently, development was performed with the developer described in the column of “Developer” in the table for 15 seconds, rinsing was performed with the rinsing liquid described in the column of “Rinsing liquid” in the table for 30 seconds, heating was performed at a temperature rising rate of 10° C./min in a nitrogen atmosphere, and heating was performed under conditions selected from 230° C. for 3 hours, 200° C. for 2 hours, and 170° C. for 2 hours to obtain a hole pattern of 3 to 20 μm. In each of Examples and Comparative Examples, which heating was selected based on conditions is described in the column of “Curing condition” in the table. The formed hole pattern was evaluated according to the following evaluation standards. The evaluation results are described in the column of “Resolution” in the table. In a case where the residual film ratio at the hole bottom portion was 1% or less as a result of the image analysis with a scanning electron microscope (SEM), it was determined that the resolution was possible. It can be said that the smaller the diameter of the hole pattern that can be formed, the better the resolution, and for example, A, B, or C is preferable.

### —Evaluation Standards—

A: A hole pattern having a diameter of up to 3 μm could be resolved.

B: A hole pattern having a diameter of 5 μm could be resolved, but a hole pattern having a diameter of 3 μm could not be resolved.

C: A hole pattern having a diameter of 7 μm could be resolved, but a hole pattern having a diameter of 5 μm could not be resolved.

D: A hole pattern having a diameter of 10 am could be resolved, but a hole pattern having a diameter of 7 μm could not be resolved.

E: A hole pattern having a diameter of 20 am could be resolved, but a hole pattern having a diameter of 10 μm could not be resolved.

### [Evaluation of Focus Margin Property]

Each of the resin compositions or comparative compositions prepared in each of Examples and Comparative Examples was applied onto an δ-inch silicon wafer by a spin coating method to form a coating film. The silicon wafer to which the obtained coating film was applied was dried on a hot plate at 100° C. for 5 minutes, and a resin composition layer having a uniform thickness of 8 μm was formed on the silicon wafer.

The resin composition layer was irradiated with energy from 200 mJ/cm² to 600 mJ/cm² in steps of 100 mJ/cm² using an i-ray stepper FPA-3030 iWa (NA=0.16) (manufactured by Canon Inc.) using a mask having a circular pattern having a mask size of a diameter of 5 μm. In this case, the focus was moved by 2 μm in the film bottom portion direction with respect to each exposure amount based on the film surface, and the exposure was performed. After the exposure, the wafer was placed on a horizontal rotary table of a spin-shower developing machine (DW-30 type; manufactured by Chemitronics Co., Ltd.), and development was performed at 23° C. for 60 seconds using the developer described in the column of “Developer” in the table, and for Examples 20 to 25, rinsing was performed using the rinsing liquid described in the column of “Rinsing liquid” in the table, and the non-exposed portion was removed by development to form a pattern.

The exposed resin composition layer (resin layer) was heated at a temperature rising rate of 10° C./min in a nitrogen atmosphere and heated for 180 minutes at the temperature described in the column of “Temperature” in “Curing condition” in the table to obtain a pattern of the cured layer (resin layer) of the resin composition layer.

For each of the obtained patterns, the pattern shape and the width of the pattern portion were observed under an optical microscope, the focus margin was obtained, and the evaluation was performed according to the following evaluation standard. The evaluation results are described in the column of “Focus margin” in the table. In a case where the angle between the bottom surface and the side surface of the pattern was 80° to 1000 and the diameter of the pattern was 4 to 6 μm, it was determined that the pattern was formed. As the focus margin is wider (the numerical value is larger), the result is more preferable in terms of the focus margin property.

### —Evaluation Standards—

A: The focus margin was 10 μm or more.

B: The focus margin was 7 μm or more and less than 10 μm.

C: The focus margin was more than 4 μm and less than 7 am.

D: The focus margin was 4 μm or less.

### [Evaluation of Flatness]

In each of Examples and Comparative Examples, the resin composition or the comparative composition was applied onto a silicon wafer on which a copper wire having a height of 15 μm and a width of 20 μm 1:1 line-and-space (L/S) pattern and a taper angle of 85 degrees was formed by a spin coating method to form a resin composition layer. The silicon wafer to which the obtained resin composition layer was applied was dried on a hot plate, thereby obtaining a resin composition layer having a uniform thickness of a film thickness of about 20 μm in the space portion of the copper wire on the silicon wafer.

The temperature of the above-described resin composition layer was raised at a temperature rising rate of 10° C./min in a nitrogen atmosphere, and the layer was heated and cured at a temperature described in the column of “Temperature” in “Curing conditions” in the table to obtain a cured substance.

The obtained cured substance was measured for a recess X (μm) of the cured substance in the space portion of the copper wire with a scanning electron microscope (S-4800) (manufactured by Hitachi High-Tech Corporation), and evaluated according to the following standard. The evaluation results are described in the column of “Flatness” in the table.

FIG. 1 is a schematic cross-sectional view of a state in which a cured substance is formed on a silicon wafer on which a copper wire is formed. A silicon wafer 16 in FIG. 1 comprises a copper wire 14, and a cured substance 12 is formed on the silicon wafer 16. Here, the cured substance 12 in the region on the silicon wafer 16 where the copper wire 14 is not formed has a recess 18 of X μm. The width W of the space portion of the copper wire was 20 μm, and the taper angle θ of the copper wire was 85° C. The recess 18 is observed, for example, as a difference between a total thickness h1 of the cured substance and the copper wire at the center position of the copper wire and a thickness h2 of the cured substance at the center position of the space portion of the copper wire.

The flatness is a difference in unevenness, and can be calculated from the height (15 μm) of the copper wire and the recess of X μm. The difference in unevenness was obtained from the following Expression Z.

Recess X (μm)÷15 (μm)×100(%) Formula Z:

The smaller the value (%) of the expression Z, the more excellent the flatness, which is preferable, and for example, the evaluation is preferably A, B, or C.

In addition, in an example in which a temperature different from 230° C. was described as the temperature described in the column of “Temperature” in “Curing conditions” in the table, the flatness was evaluated by the same method as the above-described method except that the heating temperature was set to 230° C., but the evaluation results were the same as those in a case where the heating was carried out at the temperature described in the column of “Temperature” in “Curing conditions”.

### —Evaluation Standards—

A: less than 15%.

B: 15% or more and less than 30%.

C: 30% or more and less than 40%.

D: 40% or more.

### [Evaluation of Curing Shrinkage (Shrinkage Ratio)]

Each of the resin compositions or comparative compositions in Examples and Comparative Examples was applied onto a silicon wafer by a spin coating method to form a resin composition layer. The silicon wafer to which the obtained resin composition layer was applied was dried on a hot plate at 100° C. for 5 minutes, thereby obtaining a uniform curable resin composition layer having a thickness of about 15 μm on the silicon wafer. The film thickness of the curable resin composition layer was measured using a reflection spectroscopic film thickness meter (FE-3000, manufactured by Otsuka Electronics Co., Ltd.), and this value was defined as a “film thickness A”. In any of the examples, the measurement result of the film thickness A was 15 μm.

Subsequently, the entire surface of the obtained curable resin composition layer was exposed to i-rays at an exposure energy of 500 mJ/cm² using a stepper (Nikon NSR 2005 i9C).

The temperature of the above-described cured curable resin composition layer (resin layer) after the exposure was performed was raised at a temperature rising rate of 10° C./min in a nitrogen atmosphere, was heated for 3 hours after reaching the temperature described in the column of “Temperature” in “Curing conditions” in the table, and was cooled to 25° C., thereby obtaining a cured substance. The film thickness of the cured substance was measured using a reflection spectroscopic film thickness meter (FE-3000, manufactured by Otsuka Electronics Co., Ltd.), and this value was defined as a “film thickness B”. From the following calculation formula, the shrinkage ratio of the film was calculated.

Calculation formula: shrinkage ratio (%)=100−(film thickness B+film thickness A×100)

The evaluation was carried out according to the following evaluation standard, and the evaluation results are described in the column of “Curing shrinkage properties” in the table. It can be said that the smaller the value of the above-described shrinkage ratio, the better the cured shrinkage properties of the obtained composition layer.

In addition, in an example in which a temperature different from 230° C. was described as the temperature described in the column of “Temperature” in “Curing conditions” in the table, the curing shrinkage was evaluated by the same method as the above-described method except that the heating temperature was set to 230° C., but the evaluation results were the same as those in a case where the heating was carried out at the temperature described in the column of “Temperature” in “Curing conditions”.

### —Evaluation Standards—

A: The shrinkage ratio of the film was less than 10%.

B: The shrinkage ratio of the film was 10% or more and less than 15%.

C: The shrinkage ratio of the film was 15% or more and less than 20%.

D: The shrinkage ratio of the film was 20% or more.

### [Evaluation of Chemical Resistance]

Each of the resin compositions or comparative compositions prepared in each of Examples and Comparative Examples was applied onto a silicon wafer by a spin coating method to form a resin composition layer. The silicon wafer to which the obtained resin composition layer was applied was dried on a hot plate at 100° C. for 5 minutes, and a resin composition layer having a uniform thickness of 15 μm was formed on the silicon wafer. The resin composition layer on the silicon wafer was exposed over the entire surface using a stepper (Nikon NSR 2005 i9C) at an exposure energy of 500 mJ/cm², the exposed resin composition layer (resin layer) was heated at a temperature rising rate of 10° C./min in a nitrogen atmosphere, and heated at the temperature described in the column of “Temperature” in “Curing condition” in the table for 180 minutes, thereby obtaining a cured layer (resin layer) of the resin composition layer.

The obtained resin layer was immersed in the following chemical liquid under the following conditions, and the dissolution rate was calculated.

Chemical liquid: a 90:10 (mass ratio) mixture of dimethyl sulfoxide (DMSO) and an aqueous solution containing 25% by mass of tetramethylammonium hydroxide (TMAH).

Evaluation conditions: the resin layer was immersed in the chemical liquid at 75° C. for 15 minutes, and the change rate in film thickness (100−(film thickness after immersion/film thickness before immersion×100) (%)) was calculated from the film thickness before and after immersion. The film thickness was determined by measuring the film thickness at 10 points on the coated surface with an ellipsometer (KT-22 manufactured by FOOTHILL Co., Ltd.) and calculating the arithmetic mean value thereof.

The evaluation was carried out according to the following evaluation standards, and the evaluation results are described in the column of “Chemical resistance” of the table. It can be said that the smaller the ratio of the change in film thickness before and after immersion in the chemical solution, the more excellent the chemical resistance.

In addition, in an example in which a temperature different from 230° C. was described as the temperature described in the column of “Temperature” in “Curing conditions” in the table, the chemical resistance was evaluated by the same method as the above-described method except that the heating temperature was set to 230° C., but the evaluation results were the same as those in a case where the heating was carried out at the temperature described in the column of “Temperature” in “Curing conditions”.

### —Evaluation Standards—

A: The change rate in film thickness was less than 10%.

B: The change rate in film thickness was 10% or more and less than 20%.

C: The change rate in film thickness was 20% or more and less than 40%.

D: The change rate in film thickness was 40% or more.

### [Evaluation of Coefficient of Thermal Expansion (CTE)]

Each of the resin compositions or comparative compositions in Examples and Comparative Examples was applied onto a silicon wafer by a spin coating method to form a resin composition layer. The silicon wafer to which the obtained resin composition layer was applied was dried on a hot plate at 100° C. for 5 minutes, thereby obtaining a uniform resin composition layer having a thickness of about 15 μm on the silicon wafer.

The entire surface of the obtained resin composition layer was exposed to i-rays at an exposure energy of 500 mJ/cm² using a stepper (Nikon NSR 2005 i9C).

The temperature of the resin composition layer (resin layer) after the exposure was raised at a temperature rising rate of 10° C./min in a nitrogen atmosphere, and after reaching the temperature described in the column of “Temperature” in “Curing conditions” in the table, the resin composition layer was heated at the temperature for 3 hours (however, in the example in which the column of “Temperature” describes 170° C., the resin composition layer was heated for 2 hours). The resin layer (cured film) after curing was immersed in a 4.9% by mass hydrofluoric acid aqueous solution, and the cured film was peeled off from the silicon wafer. The peeled cured film was punched out using a punching machine to prepare a test piece having a sample width of 3 mm and a sample length of 30 mm.

The elongation (displacement) of the test piece (cured substance) was measured while changing the temperature using a thermomechanical analysis/thermal expansion coefficient measuring device Discovery TMA manufactured by TA Instruments Japan Co., Ltd.

The temperature rising and falling conditions at the time of evaluation were set to the following (1) to (4).
(1) The temperature was raised from room temperature to 130° C. at a temperature rising rate of 5° C./min.
(2) The temperature was lowered from 130° C. to 10° C. at a temperature lowering rate of 5° C./min.
(3) The temperature was raised from 10° C. to 220° C. at a temperature rising rate of 5° C./min.
(4) The sample was naturally cooled to room temperature.

In the above-described temperature rising and falling processes (1) to (4), the elongation (displacement) of the specimen was measured, and a calculation was carried out to determine a value obtained by dividing the elongation (displacement) of the specimen at 25° C. and 125° C. in the process (3) by the temperature difference (100° C.), where the value was defined as the coefficient of thermal expansion.

(Example: In a case where the length of the specimen at 25° C. was 30 mm, and the length of the specimen at 125° C. was 30.12 mm, the displacement was calculated as 0.4%=4,000 ppm, and the coefficient of thermal expansion was calculated as 4,000/(125-25)=40 ppm/K)

The obtained coefficient of thermal expansion was evaluated according to the following evaluation standard, and the evaluation results are described in the column of “CTE” in the table.

In addition, in an example in which a temperature different from 230° C. was described as the temperature described in the column of “Temperature” in “Curing conditions” in the table, the coefficient of thermal expansion was evaluated by the same method as the above-described method except that the heating temperature was set to 230° C., but the evaluation results were the same as those in a case where the heating was carried out at the temperature described in the column of “Temperature” in “Curing conditions”.

### —Evaluation Standards—

A: CTE was more than 20 ppm/° C. and 50 ppm/° C. or less.

B: CTE was more than 50 ppm/° C. and 75 ppm/° C. or less.

C: CTE was more than 20 ppm/° C. and was out of the range of 75 ppm/° C. or less.

From the above results, it can be seen that the resin composition according to the embodiment of the present invention has excellent resolution of a pattern obtained by exposure and development.

The comparative compositions according to Comparative Examples 1 to 3 do not correspond to the resin according to the embodiment of the present invention.

The comparative composition according to Comparative Example 1 does not contain the repeating unit represented by Formula (1-1), and has a flatness of 30% or more and a shrinkage ratio of 15% or more.

The comparative composition according to Comparative Example 2 does not contain the repeating unit represented by Formula (1-1), and has a flatness of 30% or more.

The comparative composition according to Comparative Example 3 does not contain the repeating unit represented by Formula (1-1), and has a flatness of more than 30% and a shrinkage ratio of 15% or more.

It can be seen that the cured substance formed of such a comparative composition has poor resolution of a pattern obtained by exposure and development.

### Example 101

The resin composition used in Example 1 was applied in a layer shape onto a surface of a thin copper layer of the resin base material on the surface of which the thin copper layer was formed, by a spin coating method, dried at 100° C. for 4 minutes, and after forming a resin composition layer having a film thickness of 20 μm, exposure was carried out using a stepper (NSR1505 i6, manufactured by Nikon Corporation). Exposure was carried out through a mask (a binary mask in which the pattern is a pattern of 1:1 line and space and the line width is 10 μm) at a wavelength of 365 nm. After the exposure, heating was carried out at 100° C. for 4 minutes. After the heating, development was carried out with cyclohexanone for 2 minutes and rinsing was carried out with PGMEA for 30 seconds to obtain a layer pattern.

Next, the temperature was raised at a temperature rising rate of 10° C./min in a nitrogen atmosphere, and after the temperature reached 230° C., the temperature was maintained at 230° C. for 3 hours, thereby forming an interlayer insulating film for a re-distribution layer. This interlayer insulating film for a re-distribution layer was excellent in insulating properties.

In addition, in a case where a semiconductor device was manufactured using this interlayer insulating film for a re-distribution layer, it has been confirmed that the semiconductor device operates without any problem.

### Explanation of References

12: cured substance
14: copper wire
16: silicon wafer
18: recess
H: height of copper wire
h1: total thickness of cured substance and copper wire at center position of copper wire
h2: thickness of cured substance at center position of space portion of copper wire
W: width of space portion of copper wire
θ: taper angle of copper wire

What is claimed is:

1. A photosensitive resin composition comprising:
a resin having a repeating unit represented by Formula (1-1); and
a photosensitizing agent, 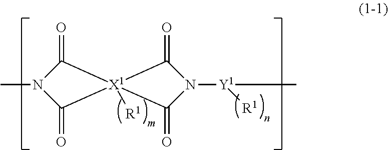
in Formula (1-1), X¹ represents an organic group including a structure obtained by removing two or more hydrogen atoms from a structure represented by any of Formula (V-1) to Formula (V-10), Y¹ represents an organic group including a structure obtained by removing two or more hydrogen atoms from a structure represented by any of Formula (V-1) to Formula (V-6) and Formula (V-8), R¹'s each independently represent an organic group having a polymerizable group, m represents an integer of 0 to 4, and n represents an integer of 1 or more, 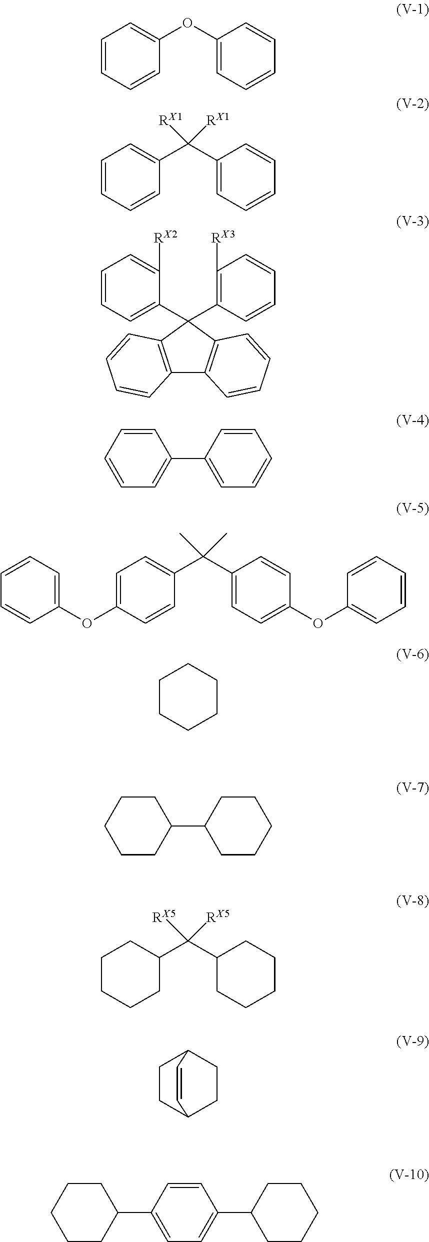
in Formula (V-2), R^{X}l's each independently represent a hydrogen atom, an alkyl group, or a halogenated alkyl group,
in Formula (V-3), R^{X2} and R^{X3} each independently represent a hydrogen atom or a substituent, and R^{X2} and R^{X3} may be bonded to each other to form a ring structure,
in Formula (V-8), R^{X5}'s each independently represent a hydrogen atom, an alkyl group, or a halogenated alkyl group.

2. The photosensitive resin composition according to claim 1,
wherein X¹ is an organic group having no ester bond.

3. The photosensitive resin composition according to claim 1,
wherein the photosensitive resin composition has 50% by mass or more of the repeating unit represented by Formula (1-1) with respect to a total mass of the resin.

4. A photosensitive resin composition comprising:
at least one resin selected from the group consisting of a polyimide and a precursor of the polyimide; and
a photosensitizing agent,
wherein the photosensitive resin composition is applied, at a film thickness in which a distance from a base material to a film surface is 20 μm, to a silicon wafer on which a copper wire having a 1:1 line-and-space pattern with a height of 15 μm, a width of 20 μm, and a taper angle of 85 degrees is formed, and a maximum value of a difference in the distance from the base material to the film surface of a cured substance obtained by heating at 230° C. for 3 hours is less than 30%, and
the photosensitive resin composition is applied to the silicon wafer to form a film at a thickness of 15 am, and a change rate in thickness of the cured substance obtained by heating at 230° C. for 3 hours after entire surface exposure with respect to a thickness of 15 μm of the cured substance before the exposure is less than 15%.

5. The photosensitive resin composition according to claim 1,
wherein a film in a case where the photosensitive resin composition is applied onto a silicon wafer satisfies Condition (1),
Condition (1): a dissolution rate of the film in cyclopentanone is 0.1 μm/sec or more and less than 0.6 μm/sec.

6. The photosensitive resin composition according to claim 1,
wherein a cured substance obtained by heating the photosensitive resin composition at 230° C. for 3 hours satisfies Condition (2),
Condition (2): a change rate in film thickness before and after immersion is less than 20% after the cured substance is immersed at 75° C. for 15 minutes in a mixture of dimethyl sulfoxide and a 25% by mass aqueous tetramethylammonium hydroxide solution in 90:10 (mass ratio).

7. The photosensitive resin composition according to claim 1,
wherein a pH of the photosensitive resin composition is 6.0 to 9.0.

8. The photosensitive resin composition according to claim 1,
wherein a weight-average molecular weight of the resin is 5,000 to 25,000.

9. The photosensitive resin composition according to claim 1,
wherein a dispersity of a molecular weight of the resin is 1.8 to 3.0.

10. The photosensitive resin composition according to claim 1,
wherein a cured substance obtained by heating the resin composition at 230° C. for 3 hours satisfies Condition (3),
Condition (3): a coefficient of thermal expansion of the cured substance in a temperature range of 25° C. to 125° C. is more than 20 ppm/° C. and 75 ppm/° C. or less.

11. The photosensitive resin composition according to claim 1, further comprising:
a naphthoquinone diazide compound.

12. The photosensitive resin composition according to claim 4,
wherein the resin has a repeating unit represented by Formula (1-1), 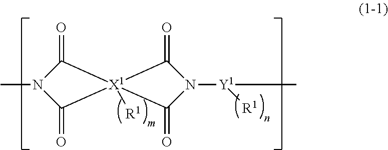
in Formula (1-1), X¹ represents an organic group including a structure obtained by removing two or more hydrogen atoms from a structure represented by any of Formula (V-1) to Formula (V-10), Y¹ represents an organic group including a structure obtained by removing two or more hydrogen atoms from a structure represented by any of Formula (V-1) to Formula (V-6) and Formula (V-8), R¹'s each independently represent an organic group having a polymerizable group, m represents an integer of 0 to 4, and n represents an integer of 1 or more, 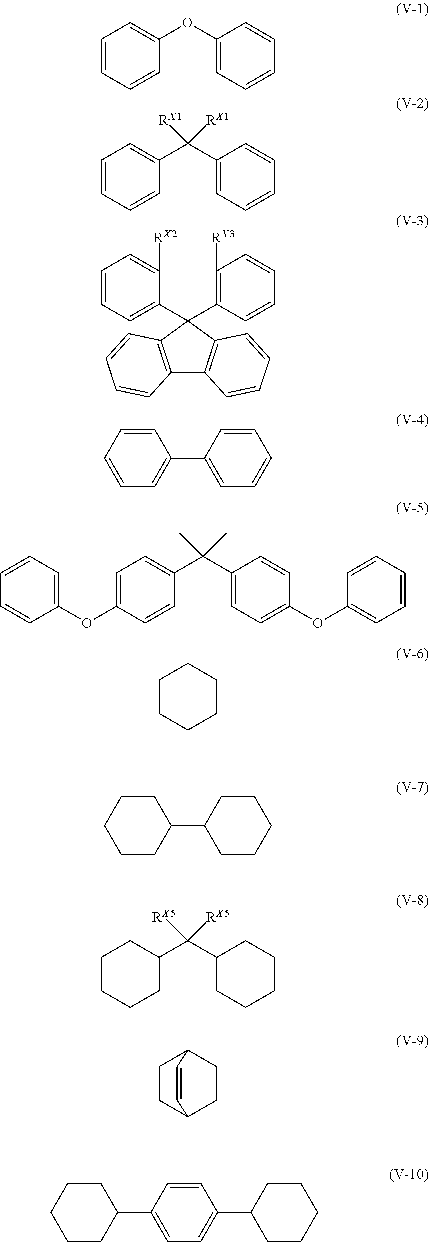
in Formula (V-2), R^{X1}'s each independently represent a hydrogen atom, an alkyl group, or a halogenated alkyl group,
in Formula (V-3), R^{X2} and R^{X3} each independently represent a hydrogen atom or a substituent, and R^{X2} and R^{X3} may be bonded to each other to form a ring structure,
in Formula (V-8), R^{X5}'s each independently represent a hydrogen atom, an alkyl group, or a halogenated alkyl group.

13. The photosensitive resin composition according to claim 12,
wherein R¹ in Formula (1-1) includes a ring structure with 5 or more ring members.

14. The photosensitive resin composition according to claim 1,
wherein a content of the resin with respect to a total solid content of the photosensitive resin composition is 60% by mass or more.

15. The photosensitive resin composition according to claim 1,
wherein the photosensitive resin composition contains a photopolymerization initiator as the photosensitizing agent, and
the photosensitive resin composition contains a polymerizable compound.

16. The photosensitive resin composition according to claim 15,
wherein a melting point of the polymerizable compound is 25° C. or lower.

17. The photosensitive resin composition according to claim 15,
wherein a content of the polymerizable compound with respect to a total solid content of the photosensitive resin composition is 10% by mass or more.

18. The photosensitive resin composition according to claim 1,
wherein the photosensitive resin composition is used for forming an insulating member.

19. The photosensitive resin composition according to claim 1,
wherein the photosensitive resin composition is used for forming an interlayer insulating film for a re-distribution layer.

20. A cured substance obtained by curing the photosensitive resin composition according to claim 1.

21. A laminate comprising:
two or more layers consisting of the cured substance according to claim 20; and
a metal layer provided between any of the layers consisting of the cured substance.

22. A manufacturing method for a cured substance, comprising:
a film forming step of applying the photosensitive resin composition according to claim 1 onto a base material to form a film.

23. The manufacturing method for a cured substance according to claim 22, further comprising:
an exposure step of selectively exposing the film; and
a development step of developing the film using a developer to form a pattern.

24. The manufacturing method for a cured substance according to claim 23, further comprising:
a heating step of heating the film at 50° C. to 450° C.

25. A manufacturing method for a laminate, comprising:
the manufacturing method for a cured substance according to claim 22.

26. A manufacturing method for a semiconductor device, comprising:
the manufacturing method for a cured substance according to claim 22.

27. A semiconductor device comprising:
the cured substance according to claim 20.
